(19) United States
(12) Patent Application Publication
(10) Pub. No.: US 2005/0101063 A1
(43) Pub. Date: May 12, 2005

(54) Three-terminal field-controlled molecular devices

(76) Inventors: James M. Tour, Bellaire, TX (US); Theresa Mayer, Port Matilda, PA (US)

Correspondence Address: MICHAEL BEST & FRIEDRICH LLC, 401 NORTH MICHIGAN AVENUE, SUITE 1900, CHICAGO, IL, 60611-4212, US

(21) Appl. No.: 10/399,806

(22) PCT Filed: Oct. 24, 2001
(86) PCT No.: PCT/US01/45588

(51) Int. Cl. H01L 21/335

(52) U.S. Cl. 438/142

(57) ABSTRACT

The present invention comprises three-terminal molecules devices that provide an electronic switching or modulation function in response to an electric field that is optimally directed normally to the length of the molecule or molecules which form the conductive path between tow electrodes. This invention also provides synthetic routes that can be implemented to realize these devices using top-down and bottom-up fabrication approaches that are compatible with ultra-high density integration onto substrates.

### FIELD OF THE INVENTION

The present invention relates generally to three-terminal, field-controlled molecular devices that will permit device scaling and circuit densities well beyond what can be achieved using any current or anticipated silicon metal-oxide-semiconductor (MOS) technologies. More particularly, this invention relates to new molecular scale electronic devices that we refer to below as molecular field effect transistors (“MFETs”), in which a monolayer comprised of a single molecule or a group of molecules is disposed between two electrodes, and means for supplying an externally applied electric field is provided to control or modulate the current flow through the molecule(s). These MFETs provide power gain in any electronic circuit application that would benefit from the rapid and flexible synthesis and ultra-high density integration that can be achieved with molecular scale electronic devices. In addition, because the active region of the devices is comprised of molecules rather than a semiconductor material, MFETs can be formed on appropriate substrates using conventional top-down fabrication processes or inserted into nanometer-scale components that can be arranged into complex circuits using bottom-up fabrication approaches.

### BACKGROUND OF THE INVENTION

With the miniaturization of transistors on silicon semiconductor chips has come faster processing speeds and more powerful computational systems. However, these progressions in size reduction are placing a heavy technical and financial burden on the silicon industry. Gordon Moore, one of the founders of Intel, predicted in 1968 that the minimum device feature size on a semiconductor chip would decrease by a factor of two every 18-24 months. Moore's prediction has held true over the past 32 years; the routine commercial feature size of microchips has dramatically declined to almost 0.1 μm. Although a further decrease is likely, once the line size on integrated circuits becomes <0.01 μm, several quantum limitations will likely limit the performance of such solid state devices. Moreover, the high cost of more complex semiconductor fabrication facilities, and the inability to create ever-smaller semiconductor devices due to inherent and fundamental physical constraints, could severely retard the industry in the future.

Therefore, new paradigms in the design of the transistors used in computing and computing technology should be considered. Molecular electronics, which uses single molecules or small groups of molecules to function as the active region of future electronic devices, represents such a paradigm shift. Electronic devices fabricated from molecules have the potential to overcome many of the roadblocks that arise in the silicon industry from fundamental physical constraints and monetary restrictions. In silicon transistor technology, the fundamental scientific barriers include oxide layers at the 3-atom thick level that are inadequately insulating, thereby resulting in charge leakage. Moreover, silicon no longer possesses its fundamental band structure when it is restricted to very small sizes. Molecules have the advantage of being about 10⁶ times smaller in area than the gate of current silicon transistors with comparatively large energy level separations at room temperature due to their discrete orbital levels, making electronic devices fabricated from molecules independent of broad band properties. Additionally, these molecular systems offer the advantage of ease of fabrication and the ability to create large varieties of structures by the use of facile chemical transformations. This flexibility provides the opportunity to dramatically modify the characteristics of such electronic devices through simple changes in the molecular structure.

From the monetary standpoint, a current semiconductor microchip fabrication line costs $2.5 billion to construct, and that cost is projected to rise to $15 billion by the year 2010, and to over $100 billion by 2015. These ever-increasing costs will soon exceed the means of even large industrial consortia. In essence, the cost arises because silicon device fabrication is a top-down approach entailing etching away at a silicon crystal to form micron-sized devices and circuitry, which are constantly being forced to become smaller and denser. Furthermore, maintaining the chip manufacturing process often requires the construction of new fabrication lines for each new generation of chips. By contrast, molecular construction is a bottom-up technology that uses atoms to build nanometer-sized molecules that could further self-assemble into a desired computational circuitry. This bottom-up approach gives rise to the prospect of manufacturing electronic circuits in rapid, cost-efficient, flow-through processes. These processes could be analogous to the production of photographic film, with overall enormous cost savings over traditional microchip fabrication.

Many in the scientific and engineering communities have already focused their attention on determining the electronic behavior of two-terminal molecular devices. Rapid progress has been achieved in developing test-beds for characterizing these systems, which has resulted in a more thorough scientific understanding of the molecular conduction properties.

The present invention, in contrast to these prior two-terminal molecular devices, is directed to field controlled molecular devices that function as molecular field effect transistors (“MFETs”), as well as their fabrication using top-down and bottom-up fabrication approaches, and their application where low power consumption along with high speed and scalability are important. The MFETs of the present invention have the advantage of providing power gain that is not readily accessible in two-terminal devices and thus may be used, for example, in digital, analog, optoelectronic and electromechanical, circuit applications.

Two-terminal molecular devices have been fashioned from several molecular systems. In 1997, Metzger and co-workers demonstrated a rectifying device from a multilayer film of hexadecylquinolinium tricyanoquinodimethanide molecules. Metzger, R. M.; Chen, B., Hopfner, U.; Lakshmikantham, M. V.; Vuillaume, D.; Kawai, T.; Wu, X.; Tachibana, H.; Hughes, T. V.; Sakurai, H.; Baldwin, J. W.; Hosch, C.; Cava, M. P.; Brehmer, L.; Ashwell, G. J. “Unimolecular Electrical Rectification in Hexadecylquinolinium Tricyanoquinodimethanide”. J. Am. Chem. Soc. 1977. 119. The groups of Heath, Williams and Stoddart used a monolayer film of a rotaxane to create a switchable molecular device structure, when sandwiched between aluminum and titanium electrodes. Collier, C. P.; Wong, E. W.; Belohradsky, M.; Raymo, F. M.; Stoddart, J. F.; Kuekes, P. J.; Williams, R. S.; Heath, J. R. “Electronically Configurable Molecular-based Logic Gates”. Science 1999. 285, 391-394. The groups of Reed and Tour recently showed that functionalization of oligo(phenylene ethynylene) permitted the formation of molecular devices that exhibit negative differential resistance (NDR). Chen, J.; Reed, M. A.; Rawlett, A. M.; Tour, J. M.; “Large On-Off Ratios and Negative Differential Resistance in a Molecular Electronic Device”, Science 1999, 186, 1550-1552.

### SUMMARY OF THE INVENTION

The present invention comprises three-terminal molecular devices that provide an electronic switching or modulation function in response to an electric field that is optimally directed normally to the length of the molecule or molecules which form the conductive path between two electrodes. When we say “monolayer”, we do not intend to exclude a bilayer, a trilayer, or further multi-layered structures which indeed are intended to be included in this invention. This invention also provides synthetic routes that can be implemented to realize these devices using top-down and bottom-up fabrication approaches that are compatible with ultra-high density integration onto substrates.

The foregoing objectives are realized through a process of fabricating MFETs from any class of molecules that undergo an increase or decrease in conductance due to changes in the conformation or charge state of the molecule. The process comprises embedding a single molecule or group of molecules between two electrodes and applying a electric field optimally normal to the length of the molecule with a third electrically isolated electrode. The molecules can be embedded between the electrodes using any procedure that produces a molecular monolayer sufficiently free of defects to produce reliable device function, with a defect-free molecular layer being preferred. The electrodes and device structure can be realized using any (a) top-down fabrication technique where the electrodes and dielectrics comprising the device are deposited, patterned, and integrated on a substrate using conventional semiconductor manufacturing procedures or (b) bottom-up fabrication technique where the electrodes and dielectrics are synthesized using template replication and/or self-assembly of nanometer-scale particles and integrated using directed assembly procedures.

Other objectives features and advantages of the present invention will be apparent from the following detailed written description of the invention, as well as from the claims and the attached figures.

### BRIEF DESCRIPTION OF THE DRAWINGS

FIG. 1 is a schematic representation of a field controlled molecular electronic device in accordance with the present invention that contains a monolayer of molecule(s) that change their conductivity due to changes in their conformational state in response to the application of an electric field;

FIG. 1B shows an alternative disposition of the control electrode of the device of FIG. 1A;

FIG. 1C depicts a single molecule which may be used in the device of FIG. 1, in its conducting and non-conducting states;

FIG. 2 is a schematic representation of a field controlled molecular electronic device in accordance with the present invention in which molecule end groups, or alligator clips —X —, are present to form the electrode-molecule electrical contact;

FIG. 3 is a schematic representation of a field controlled molecular electronic device in accordance with the present invention showing a monolayer of molecule(s) that have changed their conductivity due to a change in their charge state under the application of an electric field;

FIG. 4 is a non-exhaustive list of molecules that have been synthesized and are available for use in the present invention that change their conformation and hence their conductivity under the application of an applied electric field;

FIG. 5(a) is a schematic representation of the MFET circuit diagram showing the drain, control, and source electrode connections;

FIG. 5(b) is a plot of the input current-voltage (I-V) characteristics of a field controlled molecular electronic device in accordance with the present invention demonstrating the increase in conductivity achieved under the application of a normally directed field induced by a control electrode;

FIG. 5(c) is a plot of the output current-voltage (I-V) characteristics of a field controlled molecular electronic device in accordance with the present invention demonstrating the increase in conductivity achieved under the application of a normally directed field induced by a control electrode;

FIG. 6 is a diagrammatic representation of a top-down process flow used to fabricate a field controlled molecular electronic device in accordance with the present invention in which the process flow utilizes a self-aligned control electrode to introduce an electric field oriented normal by to the length of the molecule; and

FIG. 7 is a diagrammatic representation of a bottom-up process flow to fabricate a field controlled molecular device in accordance with the present invention using template replication techniques.

### DETAILED DESCRIPTION

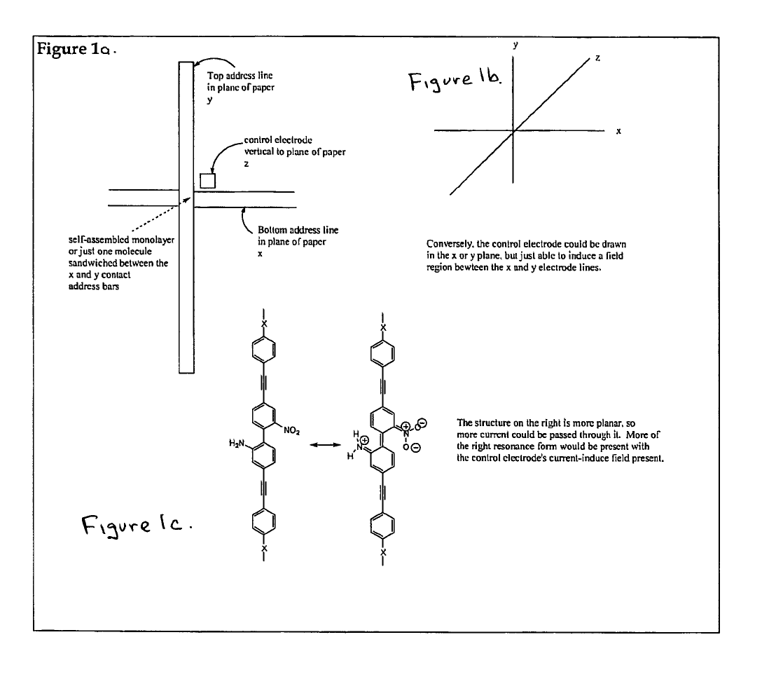

This invention comprises, in part, molecular field effect transistors (MFETs) 2, as illustrated in FIGS. 1-3, in which a monolayer comprising a single molecule 4 (or a group of molecules) is disposed between two electrodes, a source electrode 6 and a drain electrode 8. Current flow 10 in the device is controlled by applying current to a third electrically isolated control (or grate) electrode 12 to produce an electric field 14 that is oriented normally to the length of the molecule or molecules disposed between the source and drain electrodes. Although it is preferred that electric field 14 is oriented normally to the length of the molecule or molecules, any orientation that is not parallel to the length of the molecule or molecules will produce some degree of modulation of current flow through device 2.

MFET 2 may be made by embedding a monolayer of molecules, or even a single molecule, between a pair of overlapping electrodes, a source electrode 6, and a drain electrode 8, to which the molecules are connected electrically, preferably at the molecule ends. In this configuration, a third electrically isolated electrode (control electrode 12) is provided to induce an electric field oriented non-parallel and preferably normally or perpendicular to the molecules disposed between the electrodes as shown in FIGS. 1-3.

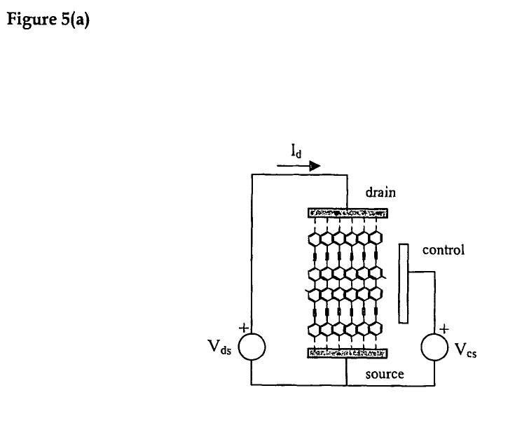

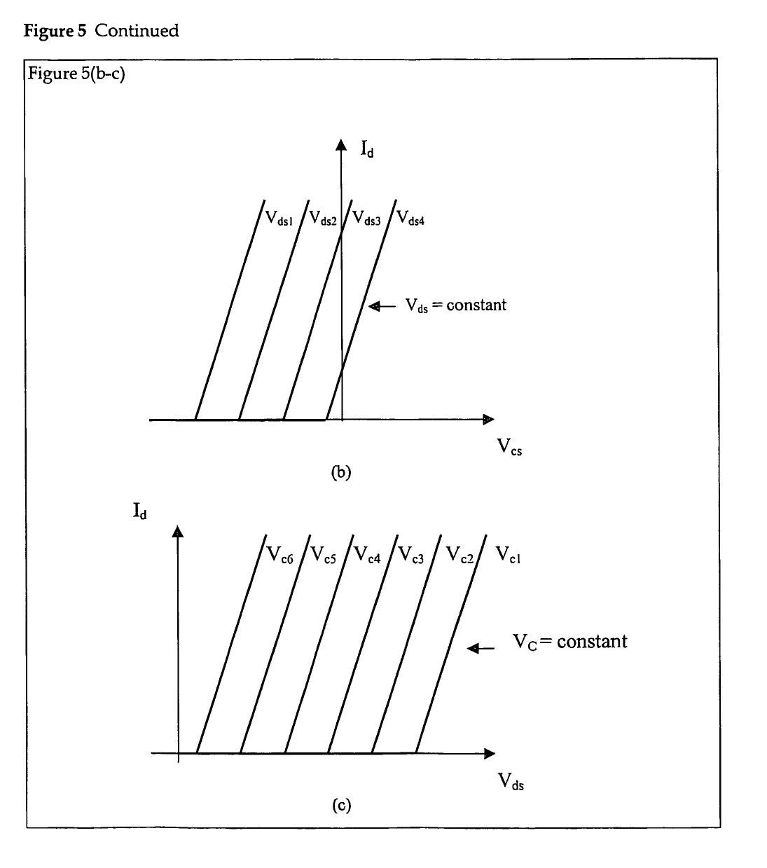

The molecules used in making the MFET of this invention must provide a conductive path and exhibit a change in their conductivity state under the application of an electric field of from as low as 2:1 to as high as 10⁶:1 or more. Although as large a change in conductivity as possible is generally preferred, conductivity gains at the low end of the above range will be useful in some applications. Exemplary input characteristics are shown in FIG. 5b where we seek to maximize the transconductance f the MFET, with the transconductance taken as the partial derivative of the drain-to-source current IDS, with respect to the control-to-source voltage, VCS, for a constant drain-to-source voltage, VDS. Typical values for MOSFETs are in the 1 mA/V range. Corresponding output characteristics are shown in FIG. 5c, where the output resistance of the MFET is maximized, with the output resistance taken as the partial derivative of VDS with respect to IDS for a constant VCS. Typical values for Rout in this context are greater than 50 kΩ. Taken together, the gain factor is the product of the output resistance times the transconductance.

Molecules which provide a conductive path as well as a change in their conductivity state under the application of an electric field (and their synthesis) are described in U.S. patent application Ser. No. 09/527,885, filed Mar. 20, 2000, the pertinent disclosure of which is incorporated herein by reference.

Monolayer 4 is desirably arranged as an assembly of molecules occupying the surface of a contact. The assembly can range from millions of molecules, to the limit of a single molecule. Presently we are limited to using lithography which can make address lines that are approximately 0.1 μm in width. This constraint on our ability to fabricate address lines to control the molecules means that, currently, a cross-section of such address lines would contain hundreds of thousands of molecules. However, as methods improve for fabricating finer address lines, this technique will be able to scale ultimately to the single molecule level.

Single molecules have been demonstrated to act as conformational-based molecular switches. The contact surface area covered by such assemblies are in the nanoscale to micron size range, that is, from about 1 nm to 5 microns in diameter or 1 nm² to 5 μm². Preferably, the assemblies cover a contact surface with a diameter from about 1 nm to about 1 micron, or 1 nm² to 1 μm². The assemblies can be present in a regular array or in an irregular arrangement on the contact surface. For example, assemblies can be arranged every few hundred nanometers, or every few microns, up to every few millimeters. Preferably, the space between assemblies will be as small as possible to maximize the use of space on the contact or substrate surface.

Contacts are provided at each end of the molecule, either by a covalent bond, by an ionic bond, or by through-space interaction with the conductive path. The contacts are made of any highly conductive material or a conductive material with a thin (less than about 10 Angstroms) insulation, that is, an oxide layer. Metal contacts can be used, and any metal is suitable, particularly those commonly used in electronics, such as copper, gold, palladium, titanium silver, and the like. The metal is preferably of moderate smoothness, but can otherwise be of any useful topology or surface geometry. The contacts need not be pure metal. For example, the contacts can be surfaces of highly conductive material deposited across at least a portion of a material of lesser conductivity.

In the fabrication of such contacts, any suitable conventional method can be used to create metal contacts that can readily be equipped with electrical contacts. For example, metal can be deposited on a substrate such as a silicon wafer, for example, by a method such as thermal evaporation, sputtering, laser-assisted deposition techniques, or chemical deposition techniques. Typically, an insulating layer such as silicon nitride or silicon oxide is then deposited on the metal surface by methods known in the art such as low pressure chemical vapor deposition, plasma enhanced chemical vapor deposition, etc. The insulating layer can then be selectively removed in locations in which it is desired to establish MFETs. The removal of insulating material can be carried out, for example, by wet chemical etching, by dry plasma etching, or by other known methods. Such a prepared contract is then ready for self assembled monolayer formation, Langmuir Blodgett film formation, or other methods of establishing a monolayer of conductive material.

The conductive molecules are disposed on the contact in the form of an ordered monolayer. Preferably, the density of the monolayer is comparatively high. That is, given the possible number of sites on the contact available for conductive path molecules to bind, as many of such sites as possible will be occupied by the molecules. One method of providing such an ordered monolayer is by a self-assembled monolayer (SAM) method. Such methods for providing well-defined, stable and reproducible metallic contacts for self assembled monolayers of conductive paths are demonstrated, for example, in Zhou et al., Appl Phys. Lett. 71 (1997) 611-613.

Another way of providing monolayers of conductive paths is by formation of a Langmuir Blodgett (L-B) film. Such a film can be constructed by transferring monolayers of conductive paths floating on a liquid surface to a solid substrate. In such films, the thickness and molecular arrangement of the film can be controlled at the molecular level. Such films generally require conductive paths having hydrophilic and hydrophobic ends. For example, a molecule with a hydrophilic group such as a carboxylic acid, and a hydrophobic group such as a C5-C5 alkyl group can be synthesized.

After deposition of the SAM or L-B film, a layer of contact material is deposited on the top of the SAM. The methods of Zhou et al. are designed to ensure that the deposition of metal atoms accumulate at the SAM surface, and do not penetrate into the organic layer. The material constituting the contact layer on top of the SAM can be the same or different than that on which the SAM is deposited.

### EXAMPLES

The following examples illustrate certain advantages and properties of particular embodiments of molecular devices and methods of making them.

I. Synthesis of Molecular Scale Wires

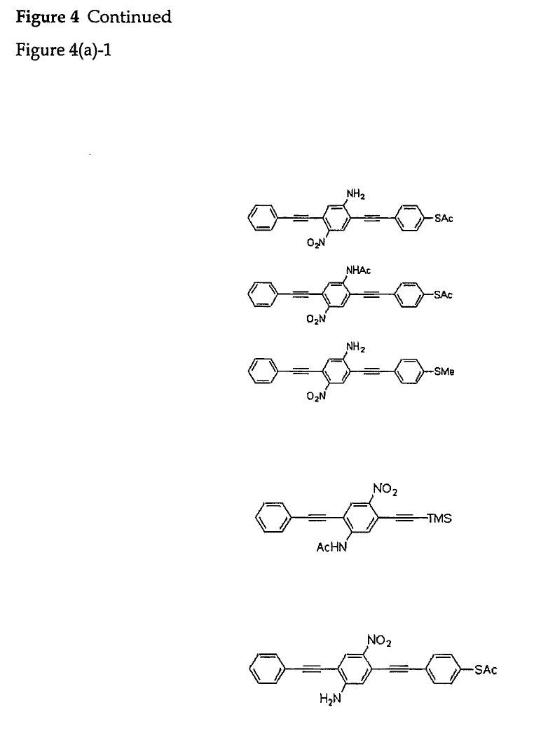

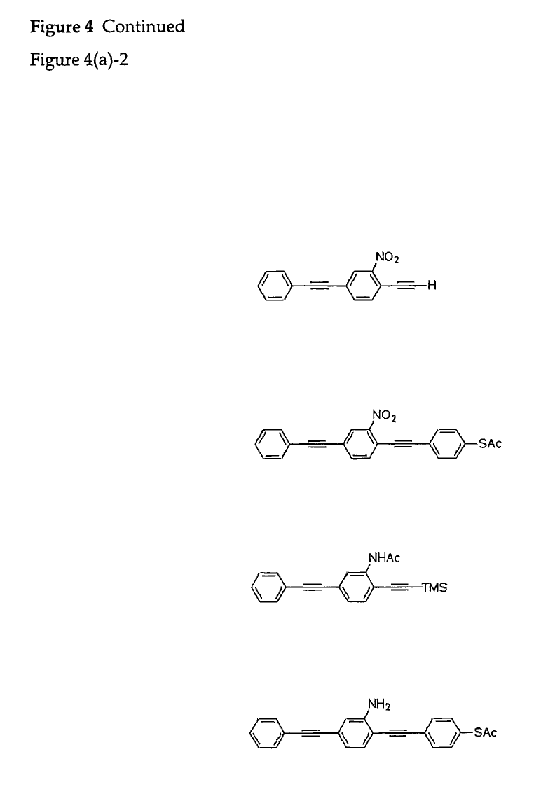

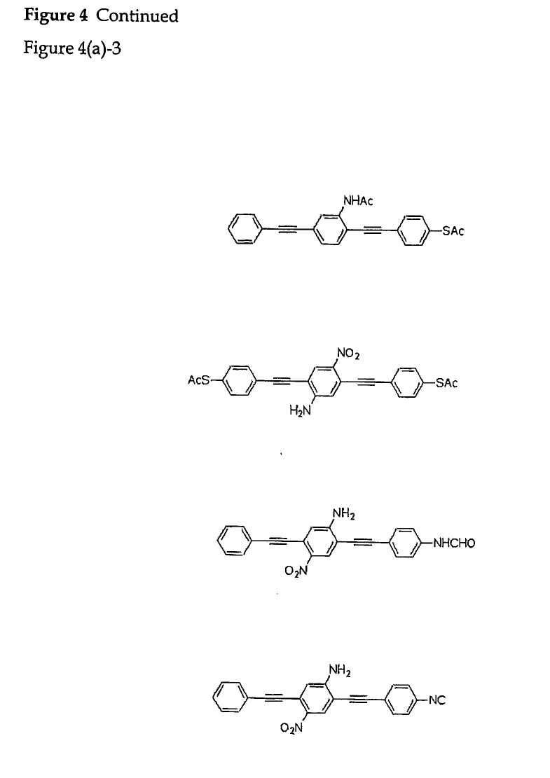

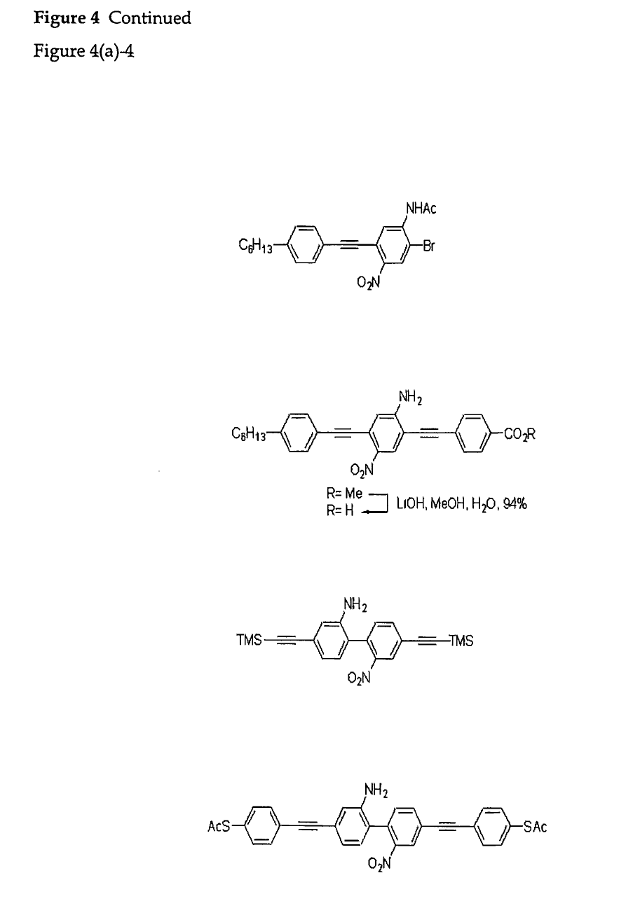

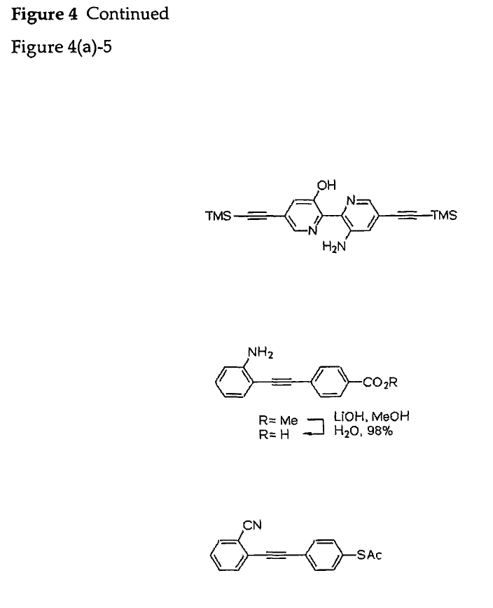

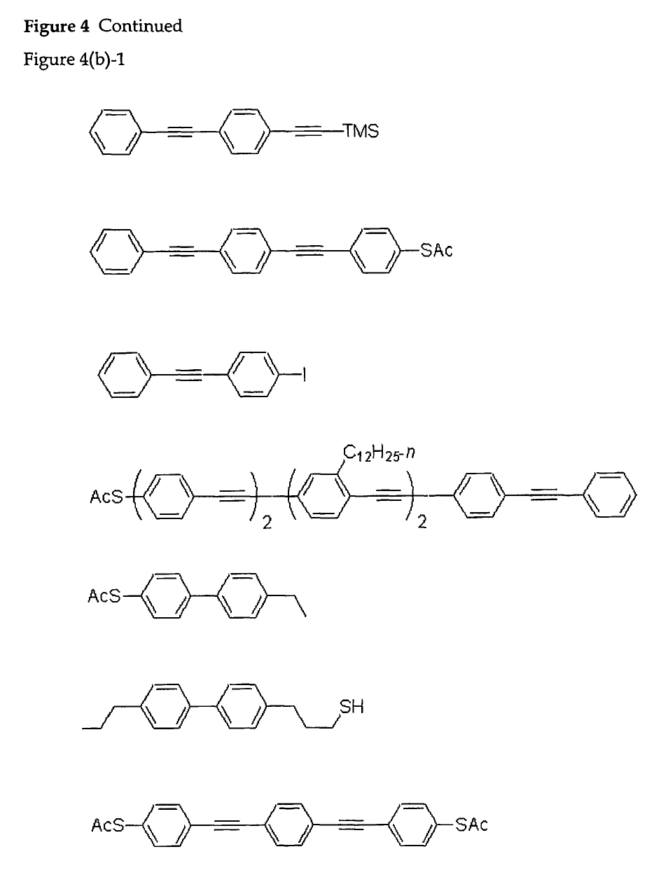

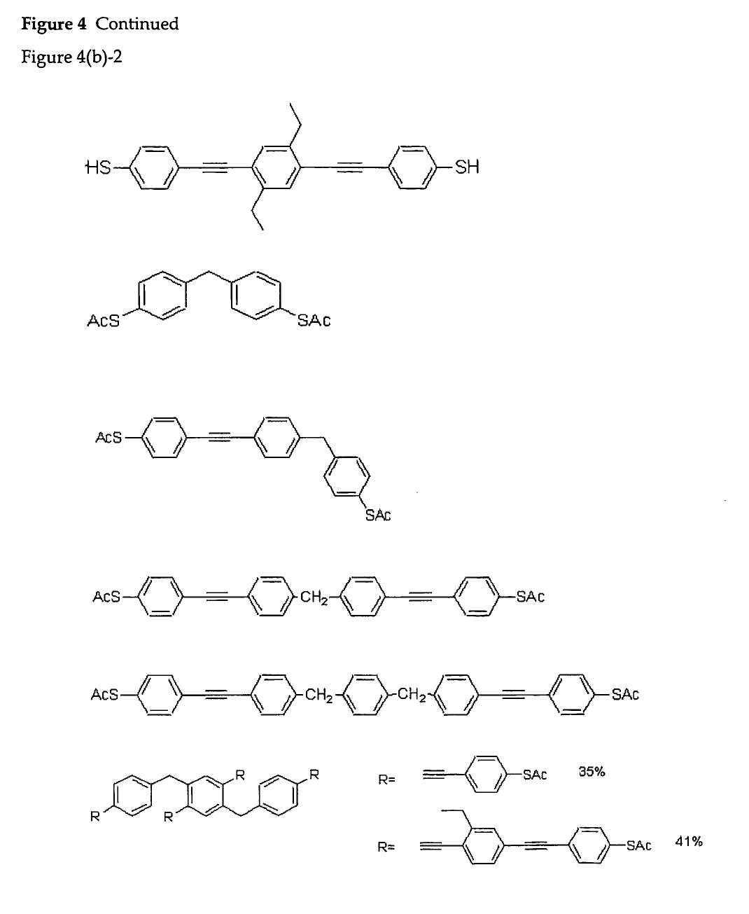

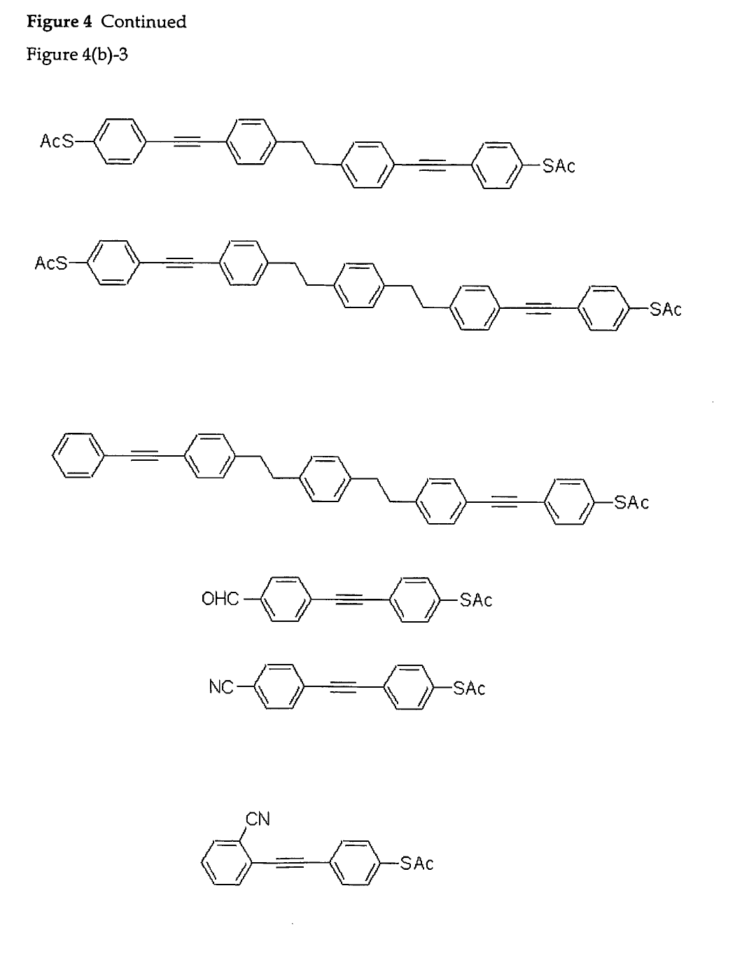

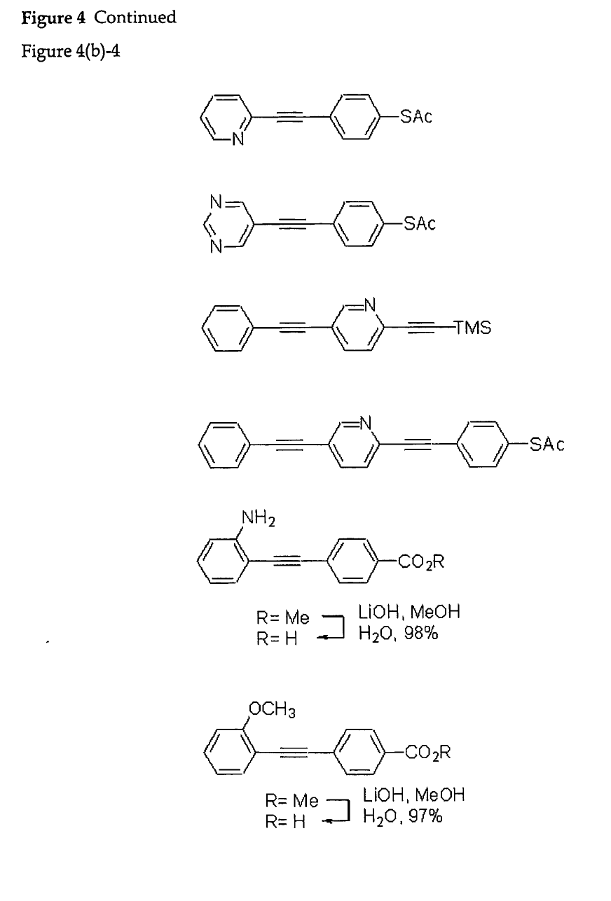

The syntheses of the molecules of FIGS. 4(a) and 4(b) are set forth below.

Synthesis of One-Terminal Oligo(Phenylene Ethynylene) Molecular Wires

The synthesis of a simple wire, 4, from readily available 1-bromo-4-iodobenzene (1) is shown (Scheme 1). The starting material was monocoupled to trimethylsilylacetylene using typical Sonogashira coupling procedures.^{[15]} The reaction proceeded with good chemoselectivity due to the greater reactivity of the aryl iodide. The resulting aryl bromide was then coupled to phenylacetylene using similar conditions yet higher temperatures to enhance coupling to the aryl bromide. The terminal alkyne 2 was deprotected using potassium carbonate and methanol and then coupled to 1-iodo-4-thioacetylbenzene^{[16]} (3) to form molecular wire 4.

X-ray diffraction crystallography of thiol derived from 4 attached to an Os cluster has shown that this oligo(phenylene ethynylene) exists predominantly in a planarized form; the phenyl rings being nearly parallel.^{[17]} It is hypothesized that the conductivity of these systems arise through the extended π-orbital overlap which is maximized while the molecule is planar. If the phenyl rings are skewed from planarity, the π-orbital overlap is diminished, and then conduction is decreased.^{[18]}

The solubility of unsubstituted 4 is moderately low in most organic solvents; therefore, it was necessary to place n-alkyl side chain moieties on the phenylene ethynylene oligomers when there are more than three phenyl units. Although a long alkyl chain is important to retain solubility of a molecular wire in common organic solvents, it could sterically retard self-assembly or inhibit formation of a well-ordered and densely packed monolayer.

In order to make more soluble systems, we prepared molecular wire 16 by Pd/Cu-catalyzed coupling reactions of 8, 12, and 13 (Scheme 2). 8 was synthesized by the coupling reaction of 6^{[19]} with phenylacetylene followed by an iodination with iodomethane. 9^{[16]} was coupled with 10 to afford dimer 11. Deprotection of the terminal alkyne with TBAF provided intermediate 12 that was coupled with 13^{[20]} to afford tetramer 14 which, upon deprotection and coupling with aryl iodide 8, afforded 16. 16 has dodecyl chains on the two central units that allow this system to be soluble in many organic solvents but the chains point in the opposite direction of thiol group that serves as a molecular alligator clip; therefore, it does not impede the formation of the SAM.^{[21]}

The synthesis of wires with central conduction units and terminal conducting barrier units are shown in Scheme 3. These were prepared to study the effects of imbedding the molecular system in a mildly insulation terminal framework. Monolithiation on 4,4′-dibromobiphenyl (17) followed by treatment with iodoethane afforded 18 that was then converted to the alligator clip-bearing molecular scale wire 19 with one ethyl end group barrier. The two-barrier system 22 was synthesized by conversion of 4-bromo-4′-propylbiphenyl (20) to 4-allyl-4′-propylbiphenyl (21). Radical thioacetyl formation^{[22]} afforded the thiol-protected molecular scale wire with an imbedded conductive portion that could be further converted to the alkylthiol 22.

Synthesis of Two-Terminal Oligo(Phenylene Ethynylene) Molecular Wires

Several syntheses of oligo(phenylene ethynylene)s with α,ω-dithioacetyl moieties, used as protected alligator clips, have been executed. These compounds will permit molecular scale wires to perform as interconnects between metallic probes (Scheme 4). Specifically, Pd/Cu-catalyzed cross couplings of 1,4-diiodobenzene (23) with two equivalents of alligator clip 9^{[16]} afforded the rigid rod molecular scale wire 24. Due to the poor solubility of the deprotected dithiol made from 24, the more soluble diethyl-containing wire, 28, was synthesized. Iodination of 1,4-diethylbenzene followed by a series of Pd/Cu-catalyzed couplings led to the formation of 27. Removal of the acetyl protecting groups with sodium hydroxide in THF/H₂O and rapid workup produced soluble 28 with free thiol end groups. However, it is recommended that the end groups remain protected until the SAM formation step. In this way, oligomerization via oxidative disulfide formation is inhibited.

Synthesis of Three-Terminal Molecular Scale Wires

Three-terminal interconnects were prepared for branched interconnect locations (eq 6).^{[23]} Alligator clip 9^{[16]} was cross-coupled with 29^{[20]} followed by subsequent deprotection of the terminal alkyne to afford 30. Three equivalents of intermediate 30 were coupled with 1,3,5-triiodobenzene (31) to afford the desired 32.

Molecular Wires with Internal Methylene and Ethylene Transport Barriers

Molecular scale wires with internal methylene and ethylene conduction barriers have been synthesized. These alkyl conduction barriers are positioned in the rigid rod phenylene ethynylene backbone to disrupt the electronic characteristics of the wires. It was hoped that the use of these methylene and ethylene conduction barriers in molecular wires might allow for the development of nanoscale molecular devices, i.e. resonant tunneling diodes (RTDs). Monolithiation of 1,4-dibromobenzene and subsequent quenching with p-bromobenzaldehyde gave diarylmethanol 34 that was subsequently converted to the diarylmethane 35 by reduction with sodium borohydride.^{[24]} 36, with one central methylene conduction barrier, was easily synthesized from 35 by lithium-halogen exchange followed by quenching with sulfur and subsequent addition of acetyl chloride (Scheme 6).

Compounds 41 and 45 are molecular wires with a tunnel barrier to study the effects of asymmetric and symmetric barrier placement on the electronic properties. The synthesis of 41, a 3-phenyl ring molecular scale wire with a methylene conduction barrier, is described in Scheme 7. 1,4-Diiodobenzene was monolithiated and quenched with 4-bromobenzaldehyde to form intermediate 38 followed by reduction of the secondary alcohol to form 39 in high yield. Coupling to the more labile aryl iodide gave compound 40. Lithium-halogen exchange followed by quenching with sulfur and subsequent addition of acetyl chloride afforded the molecular scale wire 41 containing a methylene conduction barrier.

The synthesis of a symmetric molecular wire with a methylene conduction barrier is described in Scheme 8. Conversion of 4,4′-diaminodiphenylmethane (42) to the diiodide 44 through the formation of the bistriazene 43 proceeded in moderate yields. Intermediate 44 was coupled with the molecular alligator clip 9^{[16]} to afforded molecular wire 45 with the desired central methylene transport barrier.^{[23]}

Compound 48 is a more sophisticated device with two barriers that resembles a linear quantum dot or a RTD.^{[23]} 46 was synthesized from terephthaldehyde and 1-iodo-4-lithiobenzene (Scheme 9). Reduction of the two hydroxyl moieties on 46 afforded 47 that was further coupled with two equivalents of alligator clip 9 to afford the desired 48. This compound did indeed respond as a room temperature RTD when placed in the nanopore configuration.^{[25]}

A three-terminal system with one barrier could be reminiscent of a molecular-sized field effect transistor (FET) or switch in which there is a source, drain and gate (Scheme 10).^{[23]} 4-Iodobenzaldehyde was treaded with 1,3-diiodo-5-lithiobenzene to afford the alcohol 49. Reduction and Pd/Cu-catalyzed coupling with 30 yielded 50, the desired three-terminal system with one methylene transport barrier.

Four terminal systems were synthesized according to Scheme 11. 4,4′-Diaminodiphenylmethane was treated with bromine followed by removal of the amino groups to afford 3,3′,5,5′-tetrabromodiphenylmethane (51). Compound 51 proved to be too unreactive toward Pd/Cu-coupling; therefore, conversion of the bromides to the iodides was necessary. Lithium-halogen exchanges on 51 followed by quenching with molecular iodine resulted in mono-iodination on each ring. Complete halogen exchange reaction on 51 was achieved via conversion to the tetra(trimethylsilyl) system by addition of n-butyllithium and chlorotrimethylsilane followed by treatment with iodine monochloride. The Pd/Cu-catalyzed coupling reaction of 9 or 30 with the tetraiodide intermediate afforded the four terminal systems 52 and 53, respectively. Compounds 52 and 53 could be viewed molecular logic devices as described previously.^{[23]}

The synthesis of two four-terminus systems with two methylene conduction barriers is shown in Scheme 12. The dibromoxylene was oxidized and converted to the di(acid chloride) 54. Friedel-Crafts acylation of 54 with bromobenzene was sluggish and low yielding. However, the tetrabromobis(arylketone) 56 was conveniently prepared by treatment of 54 with 1-bromo-4-trimethylsilylbenzene.^{[26]} The reduction of the tetrabromobis(arylketone) was successfully carried out using triethylsilane and trifluoromethanesulfonic acid.^{[27]} Conversion of the bromides to the iodides was achieved by lithium-halogen exchange with tert-BuLi followed by quenching with iodine. Pd/Cu-couplings of 57 with the alligator clip 9 or 30 afforded the four terminal systems 58 and 59, respectively.

A two-terminal system with a lengthened resistive section was sought. Conversion of 1,2-(4,4′-dinitrodiphenyl)ethane (60) to the diiodide 62 followed by Pd/Cu-catalyzed coupling with alligator clip 9 afforded 63 with the desired central ethylene transport barrier (Scheme 13).

The syntheses of two ethylene-barrier containing systems, 66 and 67, are described in Scheme 14. 64 was synthesized in three steps from 1,4-diiodobenzene. Hydrogenation of 64 was achieved over Pd/C in the presence of a small amount of hydrochloric acid. Without an acid additive, no reduced products were isolated in a range of solvents and temperatures. The intermediate was then converted to 65 by treating with ICl in carbon tetrachloride. Pd/Cu couplings of 65 with two equivalents of the alligator clip 9 produced wire 66. Alternatively, coupling with one equivalent of phenylacetylene followed by one equivalent of the alligator clip 9 afforded 67 with one thioacetyl terminal group.

II. Synthesis of Molecular Scale Devices with Heteroatomic Functionalities

Described here are the syntheses of functionalized molecular scale devices which are designed to have nonlinear I(V) responses by adding heterofunctionalities to modulate the π-electron system. Some of the systems have been shown to possess NDR and memory properties. The majority of these molecules are based on functionalized oligo(phenylene ethynylene)s which are substituted with electron withdrawing and donating groups and are terminated with thioacetyl alligator clips.^{[16,20]}

The synthesis of a molecular scale device with amino and nitro moieties is described in Scheme 15. The formation of 2,5-dibromo-4-nitroacetanilide (68) proceeded according to a literature procedure.^{[26b, 28]} Caution must be used during the synthesis of 68 due to the possibility of multiple nitrations on the phenyl ring which could generate polynitrated compounds; on one occasion the compound exploded violently upon drying.^{[26b]} The Pd/Cu-catalyzed coupling of phenylacetylene to the substituted dibromobenzene gave a moderate yield of the product due to the expected mixture of the mono and dicoupled products. The coupling of 68 was expected to proceed faster at the bromide ortho to the nitro (electron withdrawing) moiety since it is more active toward the electron rich late-transition metal catalyst system. X-ray analysis confirmed the assigned regiochemistry. The acetyl-protecting group was removed during the deprotection of the terminal alkynes in the presence of potassium carbonate and methanol. The electron withdrawing ability of the nitro moiety allowed for the removal of the acetyl-protecting group under such mild conditions. Finally, intermediate 69 was coupled by Pd/Cu-catalysis to alligator clip 9^{[16]} to afford molecular scale device 70. An additional method for the synthesis of 70 has been developed. Intermediate 69 was coupled with trimethylsilylacetylene, then deprotection of the terminal acetylene and the amine with potassium carbonate, and finally coupling with 3 afforded 70 in slightly lower yields than described in Scheme 15. The dipole moment of the interior phenyl ring in 70, which is directed away from the thioacetyl group, was calculated to be 5.8 Debye.^{[29]} I(V) measurements on compound 70 will be discussed in the next section.

Compound 71 differs from 70 in that it possesses an acetamide rather than an amine moiety. The Pd/Cu-catalyzed coupling reaction to form 71 proceeded at a faster rate than the coupling to the amine/nitro compound due to the diminished electron donating potential of the acetamide allowing for faster Pd oxidative addition across the aryl bromide bond. The overall net dipole moment of this compound has been calculated to be 2.7 Debye, substantially lower than that for 70.^{[29]}

The cyclic voltammetry characteristics of the nitroaniline-containing molecular scale devices were determined to help elucidate the transport mechanism. It was therefore necessary to synthesize thioether 73 that is more stable to hydrolysis and subsequent oxidation than the thioacetate-terminated system (Scheme 15). For the synthesis of thioether 73, intermediate 69 was deprotected and Pd/Cu-catalyzed coupled to 72 to form thioether terminated 73. This compound was subjected to cyclic voltammetry that confirmed that the compound was being reduced at −1.7 V and again reduced at −2.3 V (Ag/AgNO₃ reference electrode, 1.0 M n-tetrabutylammonium tetrafluoroborate in DMF at a scan rate of 100 mV/sec). Of course, there can be no correlation of absolute reduction potentials between the solution-phase and SAM experiments since the environments are grossly different. However, that 73 could undergo a reversible 2-electron reduction was useful in the development of a hypothesis of a mechanism of the transport effect.^{[29]}

To determine the effect of the direction, if any, of the dipole moment on I(V) properties, compound 75 was synthesized, according to Scheme 16. It possesses a dipole that is directed toward the thioacetyl terminus, a direction opposite that of the dipole in 70. With a deficient amount of trimethylsilylacetylene, the coupling with intermediate 68 proceeded at the more labile bromide alpha to the nitro group (vide supra). Subsequent coupling to phenylacetylene provided 74. Deprotection of the amine and the terminal alkyne, followed by coupling to 3 afforded 75.

To determine the effects of an electron withdrawing or donating moiety on the electrical properties of these compounds, materials with solely an amine, nitro, or acetamide moiety have been synthesized. 2,5-Dibromonitrobenzene was coupled with trimethylsilylacetylene at the more reactive bromide, a to the nitro moiety, followed by coupling with phenylacetylene. Deprotection of the terminal alkyne afforded intermediate 77. Coupling of 77 with 3 afforded product 78 (Scheme 17).

The system, which possessed a amino moiety, was synthesized according to Scheme 18 allowing the couplings of phenylacetylene and trimethlylsilylacetylene to 79, the deprotection of compound 80 with 3 M HCl afforded two compounds: the desired amine product and the amine cyclized bicyclic indole product.^{[30]} The separation of these compounds was not attempted due to similar retention factors on silica gel in most eluents. The terminal alkyne was revealed using potassium carbonate and methanol followed by Pd/Cu-catalyzed coupling to 3 to form 81 which, at this stage, could be separated from the other products. The sequence of couplings to the bromo moieties oil 79 was inferred based upon the electron donation of the acetamide; however, no crystallographic confirmation of the regioselectivity was obtained.

Similar to 81, the acetamide adduct was synthesized according to Scheme 18. In this case, the deprotection of the terminal alkyne with potassium carbonate and methanol did not remove the acetyl-protecting group.

A two terminal molecular scale device that is similar to compound 70 has been synthesized according to Scheme 19 although this bears α, ω-alligator clips.

To study the effects of other alligator clips on the impedance of molecular/metal junctions,^{[1]} compounds with isonitrile end groups were synthesized. The nitroaniline with an isonitrile terminus, 86, was synthesized according to Scheme 20. The amine moiety in intermediate 69 was unmasked with potassium carbonate and methanol followed by Pd/Cu-catalyzed cross coupling with the formanilide-bearing end-group, 84, to afford compound 85. Although 85 had limited solubility, it was dehydrated in the presence of triphenylphosphine and triethylamine to afford the isonitrile 86.^{[31]}

Currently, these molecular systems are studies as SAMs on a metal surface. An additional method of preparing ordered monolayers of molecular devices is the use of Langmuir-Blodgett (LB) films.^{[32]} Therefore, a compound with hydrophilic and hydrophobic subunits with the central nitroaniline core similar to 70 was synthesized as in Scheme 21.^{[32]} n-Hexylbenzene was easily brominated on neutral alumina^{[33]} and coupled to trimethylsilylacetylene followed by silyl removal and coupling to the nitroacetanilide core intermediate, 68, to afford 88. The methyl ester, intermediate 90, was synthesized by the coupling of methyl 4-ethynylbenzoate (89) to 88. The amine was unmasked and the methyl ester was saponified with lithium hydroxide to afford molecular scale device 91.^{[34]} Compound 91 is suitable for the formation of a LB film due to its hydrophilic carboxylic acid end-group and the hydrophobic n-hexyl end-group.

Other compounds with substituted biphenyl and bipyridyl core units have been sought (Schemes 22 and 23). 2,2′-Dinitrobiphenyl (92) was brominated at the 4 and 4′-positions on the biphenyl core using bromine, silver acetate, and acid.^{[35]} The brominated biphenyl was coupled to trimethylsilylacetylene to afford 93 that was then mono-reduced to the nitroamine 94 in the presence of iron and acetic acid.^{[36]} Finally, the terminal alkynes were revealed and coupled to two equivalents of alligator clip 3 to afford compound 95.

A similar compound with a bipyridyl central core was sought according to Scheme 23. In this manner, a greater degree of planarity could be achieved due to reduced interactions in the absence of 2- and 2′-steric interactions. To that end, 2-chloro-3-nitropyridine was homocoupled in the presence of copper/bronze and dimethylformamide.^{[37]} The bipyridine ring system was brominated at the 5- and 5′-position under harsh conditions^{[38]} (due to its electrophilicity) to afford intermediate 98 that was then coupled with two equivalents of trimethylsilylacetylene. These coupling conditions unfortunately afforded the hydroxyamine and a very small amount of the dinitro-coupled product. The electron deficient 98 presumably underwent nitro loss and Pd-catalyzed reduction by the hydridopalladium species that are present in the coupling catalytic cycle to afford the undesired 99 (Scheme 23).^{[38b]}

Porphyrin Containing Molecular Scale Wires

Initial efforts directed toward the porphyrin targets involved the preparation of dipyrromethane or aryl-substituted-dipyrromethanes with the intent of subsequent Pd/Cu-catalyzed coupling^{[39]} to the aryl halides for preparation of the final compounds.^{[40]} The porphyrin syntheses are shown in Scheme 24.

The dipyrromethanes could be prepared in reasonable yield, and further condensed with the complementary benzaldehyde component to generate the trans-(halophenyl)porphyrins.^{[41]} Unfortunately, further attempts to elaborate the halogenated positions via Pd/Cu-catalyzed cross coupling or lithium-halogen exchange and subsequent conversion directly to thioacetyl moieties (excess BuLi, sequential quenching with S₈ and AcCl)^{[16]} were unsuccessful; all reactions afforded only small amounts of mono-substituted products, if any. Additionally, complexing the porphyrin with zinc did not change the unsuccessful course of the subsequent derivatizations of 106-109.

The strategy was therefore modified by preparing the aldehyde-bearing protected thiol using Pd/Cu-catalyzed coupling of 4-iodobenzaldehyde with trimethylsilylacetylene, subsequent deprotection, and another Pd/Cu-catalyzed coupling with 4-iodo-1-thioacetylbenzene (8) to afford aldehyde 110 (Scheme 25).^{[42]} Protected thiol 110 was then condensed with the substituted dipyrromethanes (102-105) and oxidized to form porphyrins 111-114, respectively (Scheme 25). Likewise, 110 was condensed with pyrrole to form 115 and then further condensed with benzaldehyde and oxidized to form 111. Accordingly, no further functionalization of the porphyrin was needed. Furthermore, the thioacetyl moieties did not inhibit the reaction neither were they affected to a significant extent; the yields were similar to those obtained in reactions that did not have these thioacetyl functionalities. In a less controlled manner, the three component system involving pyrrole, benzaldehyde, and 110 could be used to prepare 111 in 8% yield after oxidation with p-chloranil. Similarly, the tetra(alligator clip) substituted system 116 could be prepared from 110 and pyrrole (Scheme 26).^{[39-41]}

Finally, we have demonstrated efficient removal of the acetyl groups in 111 using ammonium hydroxide.^{[43]} Metal incorporation into 111, specifically Zn (91%), Cu (95%), and Co (90%), using the corresponding hydrated metal acetates, followed by ammonium hydroxide-promoted thiol generation,^{[43]} proceeded without metal loss as indicated by ¹H NMR analysis.

III. Synthesis of Dipole-Possessing Molecular Wire SAMs to Control Schottky Barriers in Organic Electronic Devices

Concurrent with our efforts to build molecules for SAMs that will be used for molecular electronic devices, we are considering compounds that would form SAMs at metal interfaces in organic polymer-based LEDs. Similar issues that affect the efficiency of the metal's Fermi level overlap with the molecule's LUMO in molecular electronics¹ will affect the electron injection at LED interfaces. Therefore, we are currently synthesizing molecules to act as SAM interfaces between the metal contacts and the organic substrates in LEDs. By tailoring the Schottky barrier of the metal/organic interface, we are hoping to improve the efficiency of the LEDs. The Cu/SAM injection of holes at low voltage could also improve ohmic contact.

We envisioned conjugated phenylene-ethynylene compounds that possess electron deficient units or electron rich units to be good candidates for lowering or raising the LUMO energies, respectively, as needed for the electron or hole injecting interfaces. Again, these compounds need alligator clips to provide the SAM formation.

Compounds 118 and 120 were synthesized by Pd/Cu-catalyzed cross couplings reactions (Scheme 27). Surprisingly, each of these compounds were extremely difficult to separate by column chromatography and recrystallizations. They were finally purified by multiple cold hexanes washes.

Likewise, compounds 122 and 124 were synthesized (Scheme 28). Again, these compounds were produced in a straightforward fashion by Pd/Cu-catalyzed cross couplings.

A three-aryl system with a pyridine interior was synthesized for the LED interfaces (Scheme 29). 2,5-Dibromopyridine was coupled to trimethylsilylacetylene followed by phenylacetylene under Pd/Cu-catalyzed conditions. The first coupling reaction occurred at the more labile bromide at the 2-position in the pyridine ring. The alkyne in intermediate 126 was unmasked and then was coupled to alligator clip 3 to form the desired 127.

To decrease to the Schottky barrier for electron injection in LEDs, compounds with electron donating moieties and carboxylic acid alligator clips were synthesized for the formation of SAMs on aluminum oxide contacts.^{[44]}

In separate reactions, compounds 128 and 131 were coupled to 89 to afford methyl ester intermediates, 129 and 132, respectively. The methyl ester moieties were saponified in the presence of lithium hydroxide to afford compounds 130 and 133 (Scheme 30).^{[34]} These compounds are currently being tested for their ability to lower the electron injection barrier between the aluminum oxide contact and the organic polymer in organic LEDs and provide corroborating evidence for impedance lowering in molecular electronic devices.

IV. Testing of Molecular Scale Wires and Devices

Electronic measurements on molecular scale wires and devices were performed in the nanopore testing assembly. The nanopore system consists of a small (30-50 nm diameter) surface of evaporated metal (which can vary, but most often gold or palladium) on which a SAM of the molecular wires or devices is permitted to form. An upper metal (usually gold or titanium) contact is then evaporated onto the top of the SAM layer making a sandwich of metal-SAM-metal through which I(V) measurements are recorded.^{[45]} By using such a small area for the SAM (˜1000 molecules), we can probably achieve SAMs that are defect-free since the entire areas are smaller than the typical defect density of a SAM, thereby eliminating electrical shorts that can occur if one evaporates metal atop a SAM that is larger, for example, micron-sized. Note that metals have been deposited by evaporation atop micron-sized LB monolayers when the lower metal was an oxide, specifically aluminum oxide. The oxide inhibits the short circuits of the system.^{[32]}

The first device curve we recorded from a molecular system was one that is reminiscent of a RTD. A classical solid state RTD device has a two-barrier system between conducting segments. An RTD shows NDR, which is a deflection in the I(V) curve. Indeed, the two-barrier compound, 48, when assembled in the nanopore, exhibited the RTD-like NDR response shown in FIG. 1.^{[25]}

Conductivity of these oligo(phenylene ethynylene) molecular scale wires and devices is hypothesized to arise from transfer of electrons through the π-orbital backbone that extends over the entire molecule. When the phenyl rings of the phenylene ethynylenes oligomers are planar, the π-orbital overlap of the molecule is continuous. Thus transfer over the entire molecule is achieved; electrons can freely flow between the two metal contacts, and conductivity is maximized. But if the phenyl rings become perpendicular with respect to each other, the π-orbitals between the phenyl rings become orthogonal. The discontinuity of the π-orbital network in the perpendicular arrangement minimizes free flow of electrons through the molecular systems, thus conductivity is greatly decreased.^{[18, 46]}

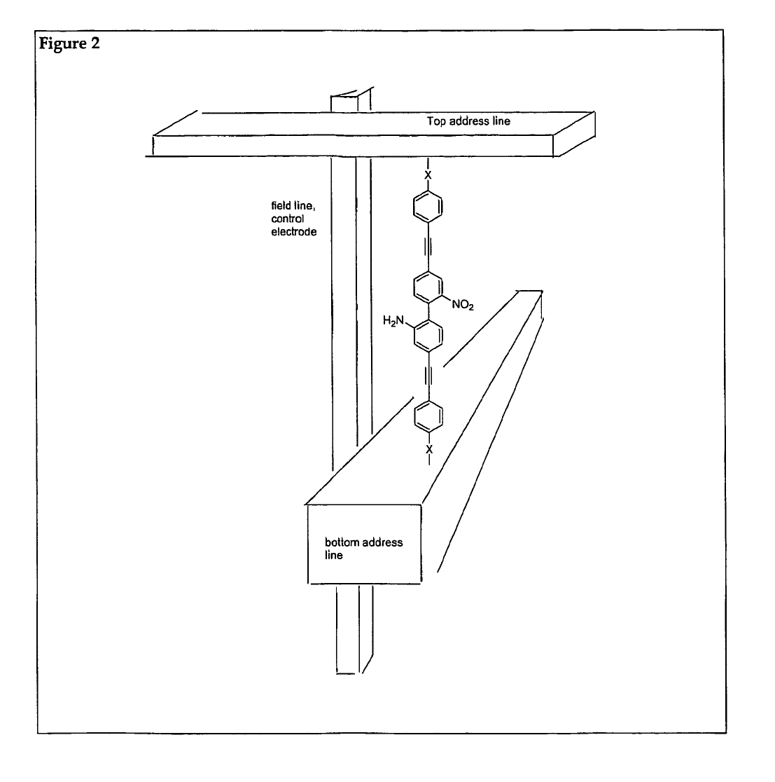

There is experimental evidence for this result as well. As seen in FIG. 2, 134 and 135 show a sharp decrease in conductance between 20 and 40 K in the temperature-current plots.^{[47]} At these lower temperatures, phenylene ethynylenes have the tendency to fishbone pack on crystallization in the SAM.^{[46]} The phenyl rings are therefore in perpendicular arrangements with respect to each other along each molecule, causing a decrease in the π-orbital overlap. This results in the sudden decline in current at lower temperatures whereupon crystallization in the SAM restricts conformational rotation.^{[46]} As the SAM is permitted to warm above 40 K, the system has enough energy to permit conformational rotation. This rotational movement permits the phenyl subunits to attain some conformations with near planarity, and conduction thus occurs.

Since modulation of temperature is an inefficient and impractical way to modulate a structure's conformation and hence conductance, we sought another structural element that would permit altering the degree of a molecule's π-orbital overlap through the use of a third electrode (gate). Thus molecules that have net dipoles that are orthogonal (or simply out of plane from the long molecular axis), could be controlled by use of a third electrode in the nanopore to modulate the conformation, and hence the current through the system.

However, since nanopore devices with an electrode perpendicular to the SAM axis had not yet been fabricated, we simply began with the control experiments. Namely, to study the two-electrode nanopore made with molecules bearing dipolar groups.

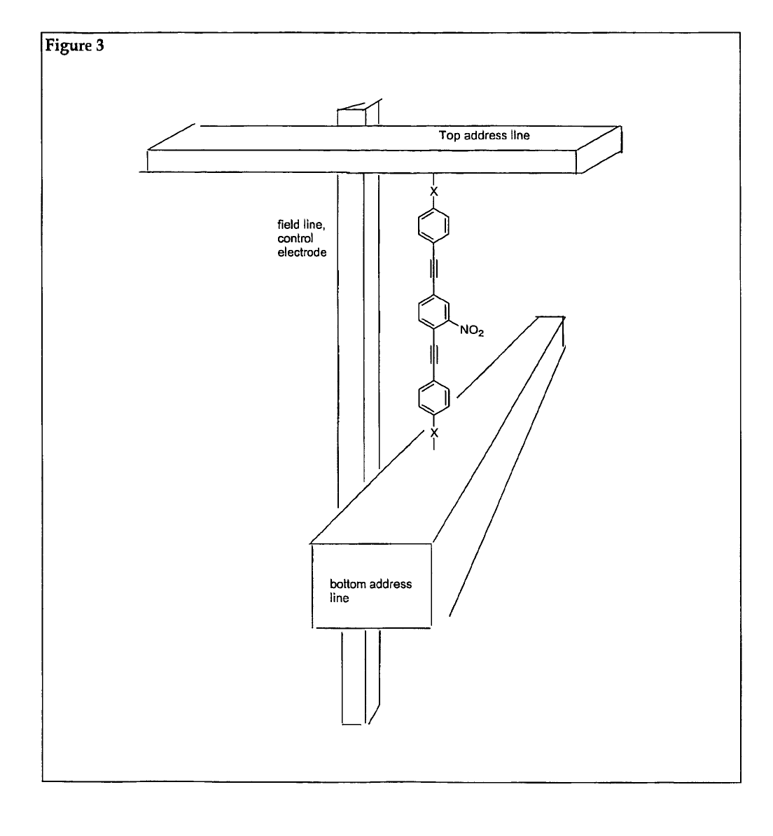

Accordingly, 70 was tested in the nanopore, in the absence of an orthogonal external electric field, to determine its electronic characteristics. A series of control experiments were performed with alkanethiol-derived SAMs and systems containing no molecules. Both the Au-alkanethiolate-Au junctions and the Au-silicon nitride membrane-Au junctions showed current levels at the noise limit of the apparatus (<1 pA) for both bias polarities at both room and low temperatures. The Au-Au junctions gave ohmic I(V) characteristics with very low resistances. A device containing a SAM of conjugated molecules similar to 70 but not bearing the nitroaniline functionalities, namely 134, was fabricated and measured in nearly identical conditions^{[47]} and it exhibited essentially linear I(V) behavior (FIG. 3) within its non-crystalline temperature range (vide supra).

Remarkably, typical I(V) characteristics of an Au-(70)-Au device at 60 K are shown in FIG. 3.^{[13]} Positive bias corresponds to hole injection from the chemisorbed thiol-Au contact and electron injection from the evaporated contact. Unlike previous devices that also used molecules to form the active region, this device exhibits a robust and large negative differential resistance (NDR) with a valley-to-peak ratio (PVR) of 1030:1.^{[13]} The NDR effect from the system containing 70 was observed up to 260 K. Beyond that temperature, however, no NDR was observed. More recently room temperature NDR has been seen in the nanopores containing 78.^{[48]}

Additionally, we demonstrated charge storage in a self-assembled nanoscale molecular device that operated as a molecular dynamic random access memory (mDRAM) with practical thresholds and output under ambient operation.^{[14]} The memory device operates by the storage of a high or low conductivity state. Hence, we need not address the nanopore and attempt detection of a small number of additional electrons; a problematic feature of typical solid state single electron devices. Conversely, the added electrons dramatically affect the conductivity of the molecular system thus a conductivity check notes the presence of the information state. FIG. 4 shows the write, read, and erase sequence for 70. An initially low conductivity state (low σ) is changed (written) into a high conductivity state (high σ) upon application of a voltage pulse. The direction of current that flows during this “write” pulse is diagrammed. The high a state persists as a stored “bit”, which is read in the low voltage region. Again, this effect persisted up to 260 K.^{[13]}

To further explore the mechanism of this mNDR and mDRAM phenomenon, several related compounds have been synthesized. Compound 71 differs from NDR molecule 70 in that it possesses an acetamide rather than a free amine moiety. After testing in the nanopore, compound 71 exhibited the NDR effect, however, with a smaller peak-to-valley ratio of 200:1 was observed at 60 K.

To determine if the orientation of the dipole moment relative to the SAM surface affected the electronic characteristics, 75 was synthesized. This compound possesses a dipole that is directed towards the thioacetyl terminus that is opposite of the dipole in compound 70. To date, however, no comparative nanopore tests have been performed on 75.

Several other compounds were tested that had either neutral, electron donating or electron withdrawing groups. The amine only compound 81 and an unfunctionalized oligo(phenylene ethynylene) 4 do not exhibit storage; the latter two systems possess nearly linear I(V) curves with no switching states. The nitro only containing compound 78 remarkably showed both NDR (4:1 PVR at 300 K)^{[48]} and mDRAM capabilities even at 300 K. [14]

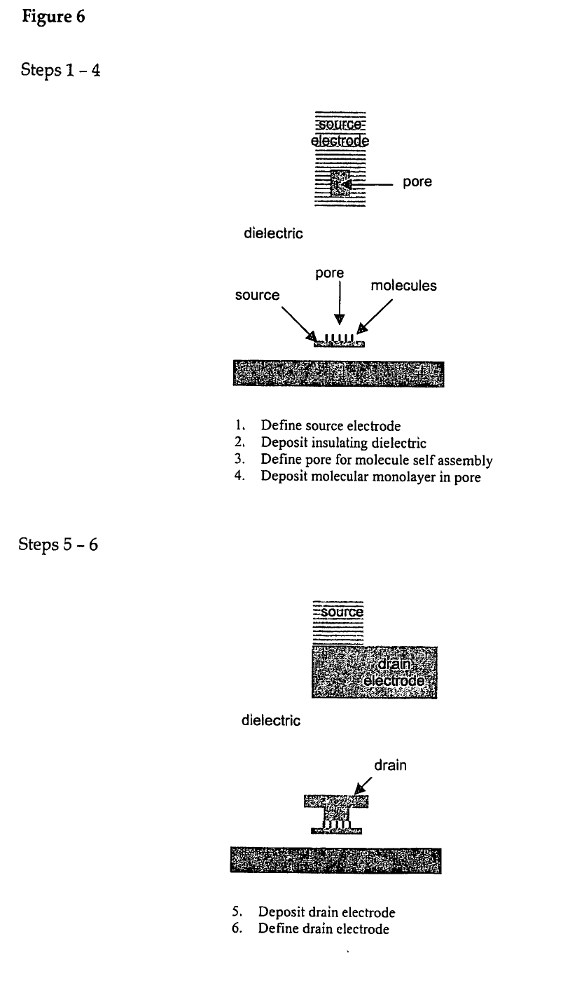

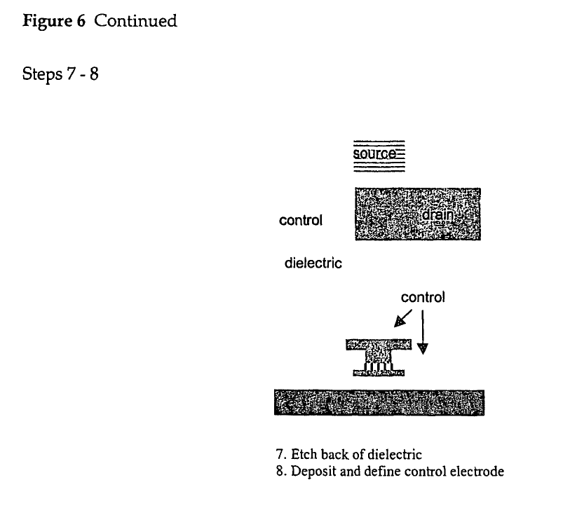

FIG. 5 is a measured logic diagram demonstrating the mDRAM cell using 78 in the nanopore. To convert the stored conductivity to standard voltage conventions, the output of the device was dropped across a resistor, sent to a comparator and inverted and gated with the “read” pulse. The upper trace shown in FIG. 5 is an input waveform applied to the device, and the lower is the mDRAM cell output. The first positive pulse configures the state of the cell by writing a bit, and the second and third positive pulses read the cell. The third pulse (and subsequent read pulses, not shown here for simplicity) demonstrates that the cell is robust and continues to hold the state (up to the limit of the bit retention time). The negative pulse erases the bit, resetting the cell. The second set of four pulses repeats this pattern, and many hours of continuous operation have been observed with no degradation in performance. This effect can be rationalized based upon conduction channels that change upon charge injection as studied by density functional theory (DFT).^{[29,49]} These DFT studies further corroborate with the experimental results in that compounds 4 and 81 would be inactive as devices (having linear I(V) curves) while 70 and 78 would both have switching states (exhibited by sharp nonlinear I(V) characteristics) due to the accepting of electrons during voltage application. Furthermore, the DFT calculations showed that 70 would need to receive one electron in order to become conductive whereas 78 would be initially conductive (“on” in the mDRAM) and then become less conductive, “off”, upon receipt of one electron.^{[49]} This is precisely the effect observed in the experiment. The four compounds on which we have mNDR and mDRAM experimental results are summarized in FIG. 6.

A two terminal molecular scale device 83 that is similar to mNDR compound 70 has been synthesized, however, no device tests have yet been performed on this compound.

A problem that persists in molecular electronics is the impedance mismatch between the molecule and the metal contact and we have been studying this resistance barrier over the last few years.^{[1,50]} To reduce this impedance mismatch, the sulfur in our alligator clips has been replaced with more metallic Se and Te termini to allow for greater overlap of the compound's LUMO and the gold's Fermi levels. Nonetheless, it was determined that neither the selenium nor tellurium alligator clip significantly reduced the barrier height.^{[51, 52]}

Recently it has been discovered that the use of an isonitrile as the contact between the organic molecular scale wire and a palladium probe would significantly reduce the conduction barrier,^{[53]} and would allow an increase in the conductivity of the molecular scale wires. Therefore molecular scale device 86 with an isonitrile attachment moiety was synthesized. Compound 86 is currently being tested for mNDR and mDRAM properties as well.

We have primarily used self-assembly as the initial attachment method to affix these molecular scale wires to the metal probe and devices. An additional method of preparing ordered monolayers of molecular devices is the use of LB films.^{[32]} Therefore, 91 was synthesized, which is a compound with hydrophilic and hydrophobic subunits with the central core similar to that in 70. Electrical conductivity tests are currently being performed on 91.

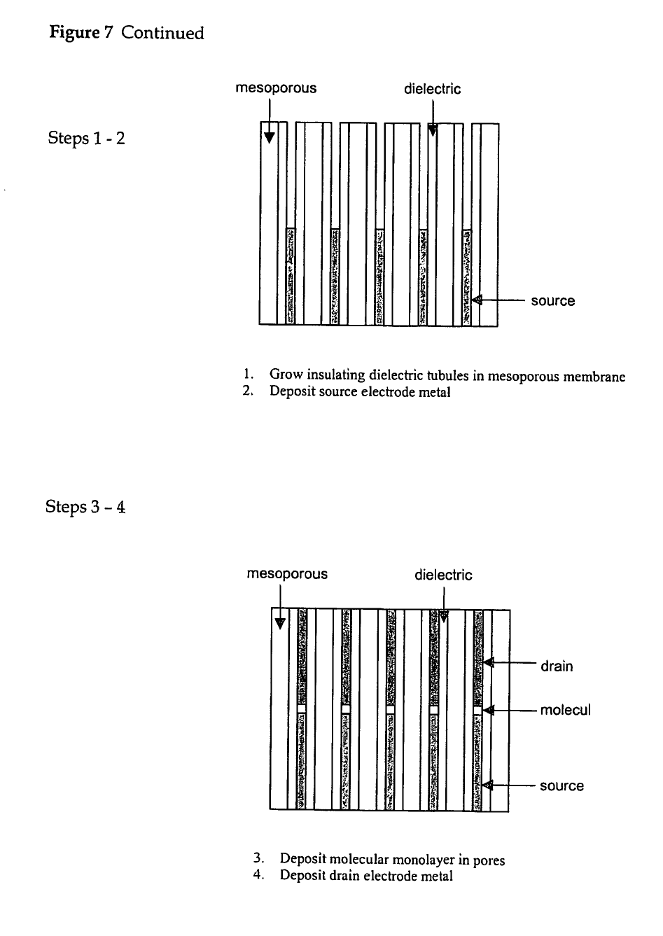

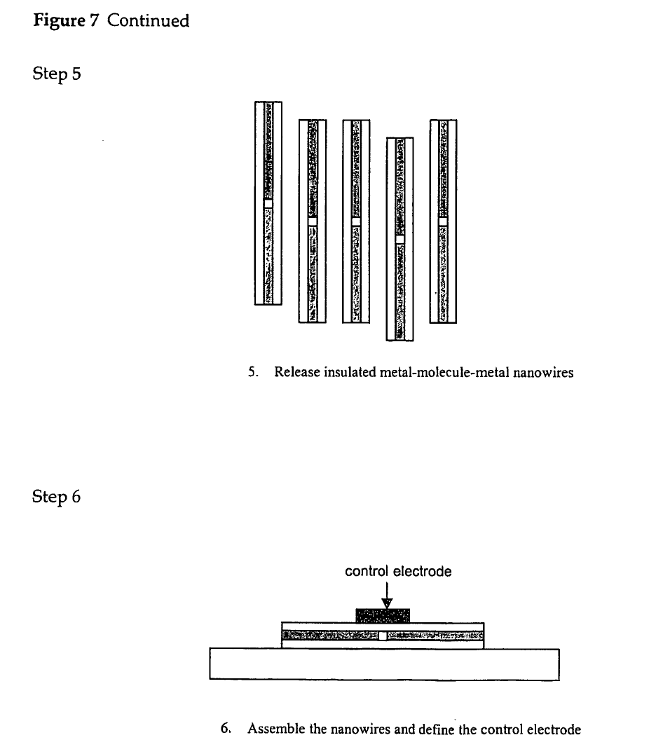

Furthermore, we envisioned a nanopore cell containing 95 could act as a molecular controller wherein the molecular system would have greater contiguous overlap in the presence of an applied orthogonal (gate) field as described in the FIG. 7. In the ground state, the biphenyl ring system will be non-planar due to steric interactions. This will cause the π-overlap of the molecular device to be non-contiguous thus decreasing the electrical conductivity. In an applied electric field that is perpendicular to the molecular axis gate, the more planar zwitterionic resonance form will be a greater contributor to the overall structure. Hence, gated control of the current through the system might be permitted. It is not essential that the molecule be entirely planar when the gate electrode is activated. It is simply necessary that the applied field lessens the twist angle between the two central rings; hence, current modulation between the top and bottom electrodes could be maintained. The increased conductivity in the perturbed state (gate voltage applied), compared to the ground state, will allow this material to function as a molecular scale switch. Therefore, compound 95 was synthesized.

As described previously, we also sought to prepare the bipyridyl-containing version rather than the biphenyl version, so as to permit a greater degree of planarity in the zwitterionic form. However, this target has proven to be elusive (Scheme 23).

Due to the difficulties in fabrication of the nanopore with an electrical field line perpendicular to upper and lower address electrodes, conductivity and switching studies on compound 95 have not yet been performed. If the gate-control effects in 95 are realized, we will revisit the synthesis of related systems (vide supra).

Several of the porphyrin-containing systems bearing alligator clips did not possess significantly non-linear I(V) characteristics in both the forward and reverse bias modes. But we have yet to test the metal-containing porphyrins. Although our device studies on the porphyrins have not afforded positive results, these observations were specifically found in the nanopore using a specific set of symmetric structures and should not be used to exclude the search for other porphyrin-based molecular electronic devices.^{[54]}

V. The Use of Dipole-Possessing Molecular Scale Systems to Control Schottky Barriers in Organic Electronic Devices

Recently, the use of organic molecules in electronic devices has found great utility. Conductive organic compounds have several advantages over traditional inorganic materials including ease of fabrication, mechanical flexibility, and cost effectiveness.^{[55]} A few of the areas of promise include LEDs,^{[56-58]} transistors,^{[59]} and photodetectors.^{[60]} Large electronic energy barriers have been evident at the contact point between metal and organic materials and they have been a source of limitation and instability in these systems.^{[60]} The metal/organic interface in LEDs have been shown to follow ideal Schottky behavior, that is, the electron Schottky barrier is determined by the energy difference between the metal work function and the electron affinity of the organic material.^{[61]} These effects are also apparent in the metal/organic interface of molecular electronic systems, hence the studies here shed light on some of the key parameters in question for our molecular electronic research.

We have been experimenting with SAMs as a controlled method to modify the metal surface and produce ordered dipole layers that change the effective work function of the metals. The useful range of metal work functions is from Ca and Sm (about 3 eV) to Pt (about 5.6 eV). It would be desirable to make useful metal contacts with both larger and smaller work functions (i.e. <3 eV or >5.6 eV) by attaching stable, ordered dipole layers to metals for example. The larger the dipole moment and surface potential shift, the better. In some monolayers, surface potential shifts of about 0.7 V have been observed.^{[62]}

The lowering of the Schottky barrier, with functionalized molecular scale systems assembled as a SAM on the metallic interface, would permit better transport of an electron or hole from the metal contact to the organic LED (FIG. 8). It has been demonstrated that electronically conductive SAMs, i.e. oligo(phenylene ethynylene)s, lower the barrier for injection of an electron from a metal contact to the organic substrate and therefore tune the Schottky energy barrier between metal and organic surfaces.^{[63]} We synthesized electron deficient compounds to act as interfaces between the metal contacts and the organic substrates in LEDs by enhancing hole injection from the metal, through the SAM (the HOMO of the molecules), and into the polymer layer. The Cu/SAM injection of holes at low voltage could also improve the contact. We envisioned electron deficient conjugated phenylene ethynylenes, such as 118, 120, 122, 124, 127 and 136^{[64]} as good candidates which also bear thiol end groups, after deprotection, for attachment to the Cu surface. FIG. 9 illustrates the efficiency of these approaches in a SAM of 136 on Cu that was further coated by the standard MEH-PPV system.

The Kelvin probe results of Au compared to Au/SAMs of 118, 122, 124, and 136 are shown in FIG. 10. Kelvin probe is a standard surface potential measurement technique.^{[61]} These results show that the SAMs increase the work function and thus make the contact a better hole injector, as expected.

To decrease the Schottky barrier for electron injection in a LED, compounds with electron donating moieties and carboxylic groups, 130 and 133 were synthesized for the formation of SAMs to aluminum oxide contact.^{[44]} These remain to be tested for their ability to lower the electron injection barrier between the aluminum oxide contact and organic LEDs. Hence these studies on metal/organic/polymer interfaces will also feed information to our molecular electronics program wherein we are seeking methods to lower the metal/organic interface barrier.

### SUMMARY

In an effort to extend the continued pace of electronic chip capacity and performance, new paradigms of computer architecture are being considered that are based upon molecules acting as discrete wires and devices.^{[1-9]} We described several synthetic routes to conjugated oligo(phenylene ethynylene)s with and without functionalities such as donor groups, acceptor groups, porphyrin interiors, and heterocycle interiors for various potential wire and digital device applications. Additionally, we discussed the synthesis of functionalized oligomers with a variety of end groups for attachment to numerous metal probes and surfaces. Some of the functionalized molecular systems showed non-linear current voltage characteristics, such as NDR and molecular DRAM properties. Additionally, the synthesis of functionalized systems were described that can be used in hybrid SAM/polymer systems to reduced Schottky barriers.

Experimental

General. All reactions were performed under an atmosphere of nitrogen unless stated otherwise. Alkyllithium reagents were obtained from FMC. Pyridine, methyl iodide, triethylamine, and N,N-dimethylformamide (DMF) were distilled over calcium hydride, and stored over 4 Å molecular sieves. Toluene and benzene were distilled over CaH₂. Methylene chloride and hexanes were distilled. Ethyl ether and tetrahydrofuran (THF) were distilled from sodium benzophenone ketyl. Triethylamine and diisopropylethylamine (Hünig's base) were distilled over CaH₂. MeOH was dried over oven dried 3 Å molecular sieves. Gravity column chromatography, silica gel plugs, and flash chromatography were performed using 230-400 mesh silica gel from EM Science. Thin layer chromatography was preformed using glass plates precoated with silica gel 60 F₂₅₄ with a layer thickness of 0.25 mm purchased from EM Science. Combustion analyses were obtained from Atlantic Microlab, Inc., P.O. Box 2288, Norcross, Ga. 30091.

General Procedure for the Coupling of a Terminal Alkyne with an Aryl Halide Using the Palladium-Copper Cross-Coupling (Castro-Stephens/Sonogashira Protocol).^{[15]} To an oven-dried round bottom flask equipped with a water cooled West condenser and magnetic stir bar or to a screw cap pressure tube with a magnetic stir bar were added the aryl halide, a palladium catalyst such as bis(triphenylphosphine)palladium(II) dichloride (3-5 mol % per halide), and copper(I) iodide (6-10 mol % per halide). Triphenylphosphine was used in some reactions to keep the palladium in solution. The vessel was then sealed with a rubber septum (flask) or capped (tube) under a N₂ atmosphere. A solvent system of THF and/or benzene and/or methylene chloride was added depending on the solubility of the aryl halide. Then base, triethylamine or diisopropylethylamine, was added. Finally, the terminal alkyne (1-1.5 mol % per halide) was added and the reaction was heated until complete. Upon completion of the reaction, the reaction mixture was quenched with water, a saturated solution of NH₄Cl, or brine. The organic layer was diluted with methylene chloride or Et₂O and washed with water, a saturated solution of NH₄Cl, or brine (3×). The combined aqueous layers were extracted with methylene chloride or Et₂O (2×). The combined organic layers were dried over MgSO₄ and the solvent removed in vacuo to afford the crude product that was purified by column chromatography (silica gel). Eluents and other slight modifications are described below for each material.

General Procedure for the Iodination of Triazenes.^{[65]} To an oven-dried screw cap tube was added the corresponding triazene and iodomethane. The mixture was degassed by slowly bubbling nitrogen for more than 15 min. After flushing with nitrogen, the tube was capped and heated at 120° C. overnight. The reaction mixture was cooled and diluted with hexane. The mixture was passed through a plug of silica gel. After evaporation of the solvent in vacuo, purified product was obtained by chromatography. Eluents and other slight modifications are described below for each material.

General Procedure for the Deprotection of Trimethylsilyl-Protected Alkynes. (Method A) The silylated alkyne was dissolved in methanol and often a co-solvent, and potassium carbonate was added. The mixture was stirred at room temperature before being poured into water. The solution was extracted with ether or ethyl acetate and washed with brine. After drying over magnesium sulfate, the solvent was evaporated in vacuo to afford the products that generally required no purification. (Method B) The silylated alkyne was dissolved in pyridine in a plastic vessel. A mixed solution of 49% hydrofluoric acid and 1.0 M tetrabutylammonium fluoride (TBAF) in THF was added at room temperature. The solution was stirred for 15 min and quenched with silica gel. The mixture was poured into water and extracted with ether. The extract was washed with brine and dried over magnesium sulfate. After filtration the solvent was evaporated in vacuo. The crude product was purified by a flash chromatography on silica gel. Eluents and other slight modifications are described below for each material.

General Procedure for the Conversion of Aryl Halides to Arylthioacetates. To tert-BuLi (2 equiv per halide) in ether or THF at −78° C. was added a solution of the aryl halide in THF. After stirring for 40 min, sulfur powder was added as a solid or via cannula as a slurry in THF. The resulting green slurry was stirred for 1 h and then warmed to 0° C. The mixture was re-cooled to −78° C. and acetyl chloride (1.2 equiv per halide) was added. The resultant yellow solution was allowed to warm to room temperature and stirred for 1 h before quenching with water. The mixture was extracted with ether (3×). The combined organic fractions were washed with water (2×) and dried over magnesium sulfate. Removal of solvents in vacuo followed by flash chromatography afforded the desired material. Eluents and other slight modifications are described below for each material.

1-Bromo-4-(trimethysilylethynyl)benzene.^{[16]} See the general procedure for the Pd/Cu coupling reaction except that amine was added at 0° C. The compounds used were 1-bromo-4-iodobenzene (2.83 g, 10.0 mmol), trimethylsilylacetylene (1.47 mL, 10.4 mmol), bis(triphenylphosphine)palladium(II) chloride (0.21 g, 0.30 mmol), copper(I) iodide (0.11 g, 0.60 mmol), benzene (13 mL), and triethylamine (5.6 mL, 40 mmol). The mixture was stirred at room temperature for 10 h. Flash chromatography (silica gel, hexane) afforded 2.37 g (95%) of the title compound as a yellow oil with slight impurities. The compound was used for the next step without further purification. Spectral data were identical to that reported earlier.^{[16]}

1-Ethynylphenyl-4-(trimethylsilylethynyl)benzene (2). See the general procedure for the Pd/Cu coupling reaction. The compounds used were copper(I) iodide (78 mg, 0.41 mmol), bis(triphenylphosphine)palladium(II) chloride (0.14 g, 0.20 mmol), 1-bromo-4-(trimethysilylethynyl)benzene (1.0 g, 4.0 mmol), phenylacetylene (0.60 mL, 5.5 mmol), triethylamine (2.0 mL, 14 mmol), and benzene (2 mL) at 80° C. overnight. The resulting brown solid was eluted 2× through a 4×20-cm column of silica gel using hexanes as the eluent. The product was obtained as a crystalline white solid (1.08 g, 99%). TLC R_{f}=0.28 (hexanes). IR (KBr) 3053, 2957, 2897, 2153, 1602, 1509, 1441, 1406, 1249, 866, 844, 757, 692, 628, 550, 529 cm⁻¹. ¹H NMR (CDCl₃) δ 7.512 (m, 2H), 7.441 (m, 4H), 7.336 (m, 3H), 0.253 (s, 9H), ¹³C NMR (CDCl₃) δ 131.87, 131.60, 131.37, 128.45, 128.36, 123.34, 122.99, 122.89, 104.64, 96.21, 91.28, 89.01, −0.07. LRMS calcd for C₁₉H₁₈Si: 274 m/e. Found 274 (M⁺), 259 [(M-CH₃)⁺], 202 [(M-C₃ H₁₀Si)⁺].

1-Ethynyl-4-(ethynylphenyl)benzene. See the general procedure for the deprotection of a trimethylsilyl-protected alkyne. The compounds used were 2 (0.94 g, 3.4 mmol), K₂ CO₃ (1.9 g, 14 mmol), methanol (2.5 mL), and methylene chloride (4 mL). The product was obtained as a pale yellow solid (0.63 g, 91%). IR (KBr) 3278, 3079, 3062, 3053, 3033, 3017, 1602, 1500, 1440, 1406, 1265, 1249, 1181, 1111, 1101, 1070, 1025, 922, 842, 834, 759, 690, 666, 629, 548, 527, 460 cm⁻¹. ¹H NMR (CDCl₃) δ 7.515 (m, 2 H), 7.462 (m, 4 H), 7.341 (m, 3H), 3.159 (s, 1H). ¹³C NMR (CDCl₃) δ 132.06, 131.64, 131.46, 128.52, 128.38, 123.79, 122.94, 121.86, 91.36, 88.82, 83.28, 78.85. LRMS calcd for C₁₆H₁₀: 202 m/e. Found 202 (M⁺), 176 [(M-C₂H₂)⁺], 150 [(M-2C₂H₂)⁺], 101 [(M-C₈H₅)⁺].

4,4′-Di(ethynylphenyl)-1-(thioacetyl)benzene (4). See the general procedure for the Pd/Cu coupling reaction. The compounds used were copper(I) iodide (0.042 g, 0.22 mmol), bis(dibenzylideneacetone)palladium(0) (0.063 g, 0.11 mmol), triphenylphosphine (0.115 g, 0.44 mmol), 3 (0.64 g, 2.3 mmol) 1-ethynyl-4-(ethynylphenyl)benzene (0.44 g, 2.2 mmol), diisopropylethylamine (1.7 mL, 10.0 mmol), and THF (10 mL) at 50° C. for 3 h. The residue purified by flash liquid chromatography using silica gel (1:1 hexanes: methylene chloride) yielding 0.57 g (74%) of the titled compound. IR (KBr) 3435.9, 3138.5, 2215.4, 1697.4, 1656.4, 1507.7, 1379.5, 1353.8, 1128.2, 1107.7, 1015.4, 943.6, 838.6, 828.1, 759.0, 756.7, 692.0, 620.5 cm⁻¹. ¹H NMR (300 MHz, C₆D₆) δ 7.54-7.50 (m, 2H), 7.39 (d, J=8.5 Hz, 2H), 7.34 (d, J=2 Hz, 3H), 7.24 (d, J=8.5 Hz, 2H), 7.16 (br s, 1H), 7.03-6.98 (m, 3H), 1.81 (s, 3 H). ¹³C NMR (400 MHz, C₆D₆) δ 190.94, 134.24, 132.01, 131.62, 131.58, 128.91, 128.35, 127.21, 126.96, 124.12, 123.60, 123.28, 122.93, 91.87, 91.01, 90.90, 89.52, 29.55. HRMS calcd for C₂₃H₁₆SO: 352.0922. Found 352.0921.

1-Diethyltriazenyl-4-ethynylphenylbenzene (7). See the general procedure for the Pd/Cu coupling reaction. 6 (2.56 g, 10.0 mmol), phenylacetylene (1.21 mL, 11.0 mmol), bis(dibenzylideneacetone)palladium(0) (0.26 g, 0.280 mmol), copper(I) iodide (0.21 g, 11.0 mmol), triphenylphosphine (0.83 g, 2.75 mmol), and diisopropylethylamine (7.65 mL, 44.0 mmol) were reacted in THF (10 mL) at room temperature for 2 d and 70° C. for 3 d. An additional portion of phenylacetylene (0.60 mL, 5.5 mmol) was added and the mixture was stirred at 70° C. for 1 d. The crude product was purified by flash chromatography on silica gel (hexane-ether 19:1) to afford desired product (2.64 g, 95%) as a yellow oil. FTIR (neat) 2976, 2359, 2213, 1594, 1393, 1237, 1201, 1162, 1097, 841, 756, 690 cm⁻¹. ¹H NMR (CDCl₃) δ 7.51 (dd, J=7.7, 1.7 Hz, 2H), 7.48 (dt, J=8.5, 1.6 Hz, 2H), 7.38 (dt, J=8.5, 1.6 Hz, 2H), 7.36-7.26 (m, 3H), 3.76 (q, J=7.2 Hz, 2H), 1.26 (br t, 3H). ¹³C NMR (CDCl₃) δ 151.1, 132.3, 131.5, 128.3, 128.0, 123.6, 120.4, 119.4, 90.1, 89.1. (Two carbons are missing due to the quadropolar effect of nitrogen.) HRMS calcd for C₁₈H₁₉N₃: 277.1579. Found: 277.1582.

1-(Ethynylphenyl)-4-iodobenzene (8). See the general procedure for the iodination of triazenes. 7 (2.51 g, 9.06 mmol) was stirred in iodomethane (10 mL) to afford 8 (2.46 g, 90%) as a white solid. The solid was recrystallized from ethanol to afford purified product (2.06 g, 75%) as white crystals. Mp 104-105° C. FTIR (KBr) 1493, 1385, 1004, 821, 758, 750, 690 cm⁻¹. ¹H NMR (CDCl₃) δ 7.67 (dt, J=8.5, 1.9 Hz, 2H), 7.52-7.47 (m, 2H), 7.36-7.30 (m, 3H), 7.23 (dt, J=8.5, 1.9 Hz, 2H). ¹³C NMR (CDCl₃) δ 137.5, 133.1, 131.6, 128.5, 128.4, 122.9, 122.8, 94.1, 90.8, 88.5. HRMS calcd for C₁₄H₉I: 303.9749. Found: 303.9738.

11. See the general procedure for the Pd/Cu coupling reaction. 10^{[20]} (528 mg, 3.0 mmol), 9^{[16]} (990 mg, 3.3 mmol), bis(dibenzylideneacetone)palladium(0) (73 mg, 0.080 mmol), copper(I) iodide (63 mg, 0.33 mmol), triphenylphosphine (256 mg, 0.85 mmol), and diisopropylethylamine (2.29 mL, 13.2 mmol) were reacted in THF (10 mL) at room temperature for 2.5 d. The crude product was purified by flash chromatography on silica gel (hexane-dichloromethane 7:3) to afford desired product (841 mg, 81%) as a white solid. Mp 114° C. FTIR (KBr) 2150, 1694, 1504, 1384, 1248, 841 cm⁻¹. ¹H NMR (CDCl₃) δ 7.52 (d, J=8.3 Hz, 2H), 7.43 (s, 4H), 7.38 (d, J=8.3 Hz, 2H), 2.42 (s, 3H), 0.24 (s, 9 M. ¹³C NMR (CDCl₃) δ 193.2, 134.2, 132.2, 131.9, 131.5, 128.4, 124.2, 123.2, 123.0, 104.6, 96.5, 90.7, 90.5, 30.3, −0.1. HRMS calcd for C₂₁H₂₀OSSi: 348.1004. Found: 348.1004.

12. See the general procedure for the deprotection of a trimethylsilyl-protected alkyne. 11 (230 mg, 0.65 mmol) was desilylated with TBAF (1.0 M solution in THF, 0.72 mL, 0.72 mmol) and 48% hydrofluoric acid (0.045 mL, 1.40 mmol) in pyridine (4.0 mL) for 10 min according to Method B. The crude product was purified by flash chromatography on silica gel (hexane-ethyl acetate 9:1) to afford desired product (157 mg, 88%) as a pale yellow solid. Mp 113-115° C. FTIR (KBr) 3272, 1670, 1508, 1384, 1125, 833 cm⁻¹. ¹H NMR (CDCl₃) δ 7.53 (dt, J=8.5, 1.9 Hz, 2H), 7.46 (s, 4H), 7.38 (dt, J=8.5, 1.9 Hz, 1H), 3.17 (s, 1H), 2.42 (s, 3H). ¹³C NMR (CDCl₃) δ 193.4, 134.2, 132.2, 132.1, 131.5, 128.4, 124.2, 123.4, 122.2, 90.5, 90.4, 83.2, 79.1, 30.3. HRMS calcd for C₁₈H₁₂OS: 276.0609. Found: 276.0615.

14. See the general procedure for the Pd/Cu coupling reaction. 12 (319 mg, 0.43 mmol), 13^{[20]} (144 mg, 0.52 mmol), bis(dibenzylideneacetone)palladium(0) (13 mg, 0.023 mmol), copper(I) iodide (8 mg, 0.042 mmol), triphenylphosphine (33 mg, 0.11 mmol), and diisopropylethylamine (0.30 mL, 1.73 mmol) were stirred in THF (2.0 mL) at room temperature for 2 d. An additional portion of bis(dibenzylideneacetone)palladium(0) (13 mg, 0.023 mmol), copper(I) iodide (8 mg, 0.042 mmol) and triphenylphosphine (33 mg, 0.11 mmol) were then added. The mixture was stirred at room temperature another 2.5 d. The crude product was purified by flash chromatography on silica gel (hexane-ethyl acetate 8:2) to afford titled compound (307 mg, 81%) as a yellow solid. Mp 98-101° C. FTIR (KBr) 2922, 2852, 2150, 1700, 151.1, 1249, 1119, 862, 839 cm⁻¹. ¹H NMR (CDCl₃) δ 7.54 (dt, J=8.4, 1.6 Hz, 2H), 7.50 (s, 4H), 7.45 (d, J=7.9 Hz, 1H), 7.42-7.37 (m, 4H), 7.32 (dd, J=7.9, 1.6, Hz, 1H), 7.32 (d, J=1.5 Hz, 1H), 7.26 (dd, J=7.9, 1.5 Hz, 1H), 2.82 (t, J=7.8, 2H), 2.75 (t, J=7.8, 2H), 2.42 (s, 3H), 1.70 (pent, J=7.9 Hz, 2H), 1.64 (pent, J=8.0 Hz, 2H), 1.45-1.13 (m, 36H), 0.86 (t, J=6.5 Hz, 6H), 0.25 (s, 9H). ¹³C NMR (CDCl₃) δ 193.3, 145.7, 145.2, 134.2, 132.4, 132.2, 132.1, 131.9, 131.7, 131.6, 128.9, 128.6, 128.3, 124.3, 123.3, 123.3, 122.8, 122.8, 122.6, 103.6, 99.7, 94.7, 91.5, 90.8, 90.6, 90.5, 89.5, 34.7, 34.6, 32.0, 30.6, 30.6, 30.3, 29.7, 29.7, 29.6, 29.6, 29.4, 22.7, 14. 2, −0.01. HRMS calcd for C₆₁H₇₆OSSi: 884.5386. Found: 884.5386.

15. See the general procedure for the deprotection of a trimethylsilyl-protected alkyne. 14 (119 mg, 0.13 mmol) was desilylated with TBAF (1.0 M solution in THF, 0.14 mL, 0.14 mmol) and 48% hydrofluoric acid (0.009 mL, 0.29 mmol) in pyridine (1.5 mL) for 10 min according to Method B described above. The crude product was purified by flash chromatography on silica gel (hexane-ethyl acetate 19:1) to afford desired product (83 mg, 79%) as a pale yellow solid. ¹H NMR (CDCl₃) δ 7.54 (dt, J=8.4, 1.9 Hz, 2H), 7.50 (s, 4H), 7.46 (d, J=8.0 Hz, 1H), 7.43 (d, J=8.0 Hz, 1H), 7.39 (d, J=1.6 Hz, 1H), 7.39 (dt, J=8.4, 1.9 Hz, 1H), 7.34 (br s, 1H), 7.33 (dd, J=8.0, 1.6 Hz, 1H), 7.27 (dd, J=8.0, 1.6 Hz, 1H), 3.32 (s, 1H), 2.82 (t, J=7.4 Hz, 2H), 2.77 (t, J=7.6 Hz, 2H), 2.43 (s, 3H), 1.69 (pent, J=7.4 Hz, 2H), 1.64 (pent, J=7.6 Hz, 2H), 1.46-1.14 (m, 36H), 0.86 (t, J=6.1 Hz, 3H). ¹³C NMR (CDCl₃) δ 193.3, 145.7, 145.2, 134.2, 132.9, 132.2, 132.1, 131.9, 131.6, 131.6, 128.9, 128.6, 128.3, 124.3, 123.6, 123.3, 122.9, 122.8, 122.7, 121.6, 94.4, 91.5, 90.7, 90.6, 90.5, 89.6, 82.1, 34.6, 34.3, 31.9, 31.6, 30.6, 30.5, 30.3, 29.7, 29.7, 29.6, 29.6, 29.6, 29.5, 29.4, 22.7, 14.1. LRMS calcd for C₅₈H₆₈OS: 812. Found: 812. (This compound is too unstable to afford a HRMS.)

16. See the general procedure for the Pd/Cu coupling reaction. 15 (464 mg, 0.57 mmol), 8 (207 mg, 0.68 mmol), bis(dibenzylideneacetone)palladium(0) (17 mg, 0.029 mmol), copper(I) iodide (11 mg, 0.057 mmol), triphenylphosphine (38 mg, 0.145 mmol), and diisopropylethylamine (0.47 mL, 2.72 mmol) were stirred in THF (2.0 mL) at room temperature for 2 d. More bis(dibenzylideneacetone)palladium(0) (17 mg, 0.029 mmol), copper(I) iodide (11 mg, 0.057 mmol) and triphenylphosphine (38 mg, 0.145 mmol) were then added. The mixture was stirred at room temperature another 4 d. The crude product was purified by a recrystallization from hexane to afford desired product (369 mg, 66%) as a yellow solid. Mp 124-125° C. FTIR (KBr) 2922, 1709, 1511, 1384, 836 cm⁻¹. ¹H NMR (CDCl₃) δ 7.57-7.43 (m, 13H), 7.42-7.30 (m, 10H), 2.84 (t, J=7.4 Hz, 4H), 2.42 (s, 3H), 1.70 (p, J=7.4 Hz, 4H), 1.47-1.14 (m, 36H), 0.90-0.78 (m, 6H). ¹³C NMR (CDCl₃) δ 193.3, 145.2, 137.5, 134.2, 133.1, 132.2, 131.9, 131.8, 131.7, 131.6, 131.6, 131.4, 129.0, 128.8, 128.4, 128.4, 124.3, 123.3, 123.3, 123.2, 123.1, 122.9, 122.8, 122.8, 122.5, 94.8, 94.4, 91.6, 91.4, 90.8, 90.6, 90.1, 89.7, 89.2, 34.7, 32.0, 30.6, 30.3, 29.8, 29.7, 29.7, 29.6, 29.4, 22.8, 14.2. HRMS calcd for C₇₂H₇₆OS: 988.5613. Found: 988.5630.

4-Bromo-(4′-ethyl)biphenyl (18). To a solution of 4,4′-dibromobiphenyl (17) (6.24 g, 20.0 mmol) in THF (100 mL) at −78° C. was added n-BuLi (12.4 mL, 20.0 mmol, 1.61 M in hexane) dropwise. The yellow slurry was stirred for 1 h and iodoethane was added. The mixture was allowed to warm to room temperature and stirred for 20 h. The mixture was poured into water. The organic layer was separated and washed with water (2×) and brine (1×). The combined aqueous solution was extracted with ether (2×). The combined organic fractions were dried over magnesium sulfate. Removal of solvent followed by flash chromatography (silica gel, hexane) gave desired product as a white solid (4.70 g, 90%). FTIR (neat) 2964, 2923, 2872, 1482, 1390, 1267, 1133, 1072, 1000, 815, 739 cm⁻¹. ¹H NMR (300 MHz, CDCl₃) δ 7.53 (d, J=8.4 Hz, 2H), 7.46 (d, J=8.2 Hz, 2H), 7.43 (d, J=8.5 Hz, 2H), 7.26 (d, J=8.8 Hz, 2H), 2.68 (q, J=7.6 Hz, 2H), 1.26 (t, J=7.6 Hz, 3H). ¹³C NMR (75 MHz, CDCl₃) δ 143.92, 140.14, 137.40, 131.89, 128.63, 128.51, 126.93, 121.28, 28.62, 15.65. HRMS calcd for C₁₄H₁₃Br: 260.0201. Found: 260.0204.

4-Ethyl-4′-thioacetylbiphenyl (19). See the general procedure for the conversion of aryl halide to arylthioacetate. The compounds used were 18 (0.784 g, 3.00 mmol) in ether (10 mL), tert-BuLi (2.6 mL, 6.0 mmol, 2.30 M in pentane) in ether (10 mL), sulfur powder (0.16 g, 5.0 mmol) in ether (5 mL), and acetyl chloride (0.43 mL, 6.0 mmol). Gravity chromatography (silica gel, hexane/ether 9/1) afforded desired material as a white solid (0.21 g, 27%). Mp 84-86° C. FTIR (neat) 2964, 2923, 2872, 1703, 1482, 1395, 1354, 1123, 1097, 1005, 954, 815 cm⁻¹. ¹H NMR (300 MHz, CDCl₃) δ 7.60 (d, J=8.1 Hz, 2H), 7.50 (d, J=8.1 Hz, 2H), 7.44 (d, J=8.1 Hz, 2H), 7.27 (d, J=8.0 Hz, 2H), 2.68 (q, J=7.6 Hz, 2H), 2.43 (s, 3H), 1.26 (t, J=7.6 Hz, 3H). ¹³C NMR (75 MHz, CDCl₃) δ 194.30, 144.04, 142.40, 137.54, 134.77, 128.43, 127.80, 127.15, 126.39, 30.24, 28.57, 15.57. HRMS calcd for C₁₆H₁₆OS: 256.0922. Found: 256.0918.

4-Bromo-(4′-propyl)biphenyl (20). To a solution of 17 (9.36 g, 30.0 mmol) in THF (150 mL) at −78° C. was added n-BuLi (18.8 mL, 30.0 mmol, 1.60 M in hexane) dropwise. The yellow slurry was stirred for 1.5 h and iodopropane was added. The mixture was allowed to warm to room temperature and stirred for 5 h. The mixture was poured into water and extracted with ether (2×). The organic fractions were dried over magnesium sulfate. Removal of solvent followed by flash chromatography (silica gel, hexane) gave product as a white solid (7.80 g, 94%). Mp 103-104° C. FTIR (KBr) 2954, 2933, 2872, 1482, 1462, 1390, 1262, 1133, 1077, 1005, 826, 800, 739 cm¹. ¹H NMR (300 MHz, CDCl₃) δ 7.53 (d, J=8.4 Hz, 2H), 7.46 (d, J=7.9 Hz, 2H), 7.43 (d, J=8.4 Hz, 2H), 7.24 (d, J=8.1 Hz, 2H), 2.62 (t, J=7.6 Hz, 2H), 1.67 (sext, J=7.5 Hz, 2H), 0.96 (t, J=7.3 Hz, 3H). ¹³C NMR (75 MHz, CDCl₃) δ 142.37, 140.13, 137.38, 131.86, 129.09, 128.62, 126.81, 121.24, 37.76, 24.61, 13.96. HRMS calcd for C₁₅H₁₅Br: 274.0357. Found: 274.0350.

4-Allyl-4′-(propyl)biphenyl (21). A mixture of 20 (3.96 g, 14.4 mmol), tributylallyltin (4.97 g, 15.0 mmol), Pd(dba)₂ (0.248 g, 0.432 mmol), PPh₃ (0.453 g, 1.73 mmol), and BHT (four crystals) in toluene (20 mL) was heated to reflux for 21 h. The mixture was cooled to room temperature, filtered and concentrated in vacuo. The residue was diluted with ether and aqueous potassium fluoride (8 mL, 3 M) was added. The mixture was stirred for 15 min and filtered through a pad of celite. The filtrate was washed with water (2×) and dried over magnesium sulfate. Removal of solvent in vacuo followed by flash chromatography (silica gel, hexane) gave product as a white solid (2.55 g, 75%). Mp 44-46° C. FTIR (KBr) 3077, 3026, 2964, 2923, 2872, 1641, 1497, 1456, 1431, 1400, 1267, 1118, 1005, 995, 913, 831, 795, 739 cm⁻¹. ¹H NMR (300 MHz, CDCl₃) δ 7.52 (d, J=8.0 Hz, 2H), 7.49 (d, J=8.0 Hz, 2H), 7.25 (d, J=8.0 Hz, 2H), 7.24 (d, J=8.0 Hz, 2H), 6.07-5.94 (ddt, J=17.0, 8.2, 6.7 Hz, 1H), 5.12 (dd, J=17.0, 1.5 Hz, 1H), 5.09 (dd, J=8.2, 1.3 Hz, 1H), 3.42 (d, J=6.7 Hz, 2H), 2.62 (t, J=7.6 Hz, 2H), 1.67 (sext, J=7.5 Hz, 2H), 0.97 (t, J=7.3 Hz, 3H). ¹³C NMR (75 MHz, CDCl₃) δ 141.85, 139.37, 139.09, 138.77, 137.74, 129.33, 129.23, 127.35, 127.19, 116.22, 40.26, 38.09, 24.96, 14.30. HRMS calcd for C₁₈H₂₀: 236.1565. Found: 236.1564.

1-(4′-Propylbiphenyl)-3-thioacetylpropane. A mixture of 21 (0.90 g, 3.8 mmol), thioacetic acid (0.44 mL, 6.0 mmol) and AIBN (0.005 g) in benzene (5 mL) was heated to reflux overnight.^{[22]} After cooling to room temperature, the mixture was poured into water, extracted with ether (2×) and the extracts were dried over magnesium sulfate. Removal of solvent followed by flash chromatography (silica gel, hexane/ether=20/1) gave the title compound as a white solid (0.75 g, 63%). FTIR (KBr) 2954, 2933, 2862, 1677, 1497, 1451, 1421, 1400, 1354, 1144, 1118, 954, 831, 790, 636 cm⁻¹. ¹H NMR (300 MHz, CDCl₃) δ7.49 (d, J=8.0 Hz, 2H), 7.48 (d, J=8.0 Hz, 2H), 7.23 (d, J=8.3 Hz, 2H), 7.22 (d, J=8.1 Hz, 2H), 2.91 (t, J=7.3 Hz, 2H), 2.71 (t, J=7.6 Hz, 2H), 2.61 (t, J=7.6 Hz, 2H), 2.33 (s, 3H), 1.92 (p, J=7.5 Hz, 2H), 1.67 (sext, J=7.4 Hz, 2H), 0.96 (t, J=7.3 Hz, 3H). ¹³C NMR (100 MHz, CDCl₃) δ 195.55, 141.46, 139.75, 138.79, 138.20, 128.71, 128.67, 126.85, 126.66, 37.72, 34.50, 31.15, 30.71, 28.66, 24.62, 13.98. HRMS calcd for C₂₀H₂₄OS: 312.1548. Found: 312.1539.

1-(4′-Propylbiphenyl)-3-propanethiol (22). To a solution of 1-(4′-propylbiphenyl)-3-thioacetylpropane (0.50 g, 1.6 mmol) in ethanol (4 mL) was added water (4 mL) and potassium hydroxide (0.45 g, 8.0 mmol). The mixture was heated to reflux for 15 min. The mixture was cooled to room temperature. The solution was acidified with 3 N HCl and extracted with ether (3×). The extracts were dried over magnesium sulfate. Removal of solvent in vacuo followed by flash chromatography (silica gel, hexane) gave desired product as a white solid (0.31 g, 72%). Mp 32-33° C. FTIR (KBr) 3026, 2954, 2923, 2862, 1497, 1456, 1400, 1374, 1344, 1292, 1.256, 1185, 1118, 1005, 800, 739 cm⁻¹. ¹H. NMR (300 MHz, CDCl₃) δ 7.50 (d, J=8.1 Hz, 2H), 7.48 (d, J=8.1 Hz, 2H), 7.23 (d, J=8.5 Hz, 4H), 2.75 (t, J=7.5 Hz, 2H), 2.61 (t, J=7.6 Hz, 2H), 2.56 (q, J=7.4 Hz, 2H), 1.96 (p, J=7.3 Hz, 2H), 1.67 (sext, J=7.5 Hz, 2H), 1.37 (t, J=7.8 Hz, 2H), 0.96 (t, J=7.3 Hz, 3H). ¹³C NMR (100 MHz, CDCl₃) δ 141.69, 140.10, 138.98, 138.41, 128.92, 128.91, 127.04, 126.86, 37.76, 35.51, 34.04, 24.63, 24.09, 13.98. HRMS calcd for C₁₈H₂₂S: 270.1442. Found: 270.1437.

24. See the general procedure for the Pd/Cu coupling reaction. The compounds used were 1,4-diiodobenzene (0.165 g, 0.500 mmol), 9^{[16]} (0.247 g, 1.40 mmol), Pd(dba)₂ (0.029 g, 0.05 mmol), copper(I) iodide (0.019 g, 0.10 mmol), PPh₃ (0.052 g, 0.20 mmol), THF (13 mL), and diisopropylethylamine (0.70 mL, 4.0 mmol). Flash chromatography (silica gel, hexane, then hexane/CH₂Cl₂ 1/1) afforded desired product as a light brown solid (0.20 g, 94%). Mp 199-120° C. FTIR (KBr) 1692, 1590, 1513, 1385, 1354, 1118, 1092, 1010, 964, 826, 621 cm⁻¹. ¹H NMR (300 MHz, CDCl₃) δ 7.54 (d, J=8.5 Hz, 4H), 7.50 (s, 4H), 7.39 (d, J=8.5, 4H), 2.43 (s, 6H). ¹³C NMR (75 MHz, CDCl₃) δ 193.40, 134.22, 132.1, 6, 131.62, 128.30, 124.21, 122.99, 90.65, 90.57, 30.29. HRMS calcd for C₂₆H₁₈O₂S₂: 426.0748. Found: 426.0740.

1,4-Diethyl-2,5-diiodobenzene. A mixture of 1,4-diethylbenzene (2.43 g, 18.1 mmol), iodine (6.13 g, 24.1 mmol), periodic acid (2.74 g, 12.0 mmol), acetic acid (12 mL) water (2.4 mL) and concentrated sulfuric acid (0.4 mL) was heated to 95° C. for 1 d. The mixture was cooled to room temperature and poured into water. The mixture was neutralized carefully with saturated aqueous sodium bicarbonate. The precipitate was collected by filtration and re-dissolved in ether. The ether solution was washed with aqueous sodium thiosulfate (1×), water (1×), brine (1×) and dried over magnesium sulfate. After filtration, removal of solvent in vacuo gave the title compound as a white solid (6.92 g, 99%). Mp 68-69° C. FTIR (neat) 2964, 2933, 2862, 1462, 1380, 1349, 1318, 1046, 1036, 980, 882, 713, 667 cm⁻¹. ¹H NMR (300 MHz, CDCl₃) δ 7.60 (s, 2H), 2.62 (q, J=7.5 Hz, 4H), 1.16 (t, J=7.5 Hz, 6H). ¹³C NMR (75 MHz, CDCl₃) δ 145.93, 138.70, 100.52, 33.26, 14.61.

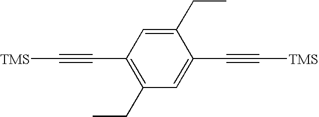

1,4-Diethyl-2,5-bis(trimethysilylethynyl)benzene. See the general procedure for the Pd/Cu coupling reaction. The compounds used were 1,4-diethyl-2,5-diiodobenzene (3.86 g, 10.0 mmol), trimethylsilylacetylene (3.53 mL, 25.0 mmol), bis(triphenylphosphine)palladium(II) chloride(0.35 g, 0.50 mmol), copper(I) iodide (0.19 g, 1.0 mmol), diisopropylethylamine (7 mL, 40 mmol), and THF (10 mL). Flash chromatography (silica gel, hexane) gave the title compound as yellow crystals (2.73 g, 84%). FTIR (neat) 2964, 2872, 2154, 1487, 1456, 1400, 1251, 1195, 1062, 897, 867, 841, 764, 708, 626 cm⁻¹. ¹H NMR (300 MHz, CDCl₃) δ 7.26 (s, 2H), 2.73 (q, J=7.5 Hz, 4H), 1.21 (t, J=7.5 Hz, 6H), 0.25 (s, 18H). ¹³C NMR (75 MHz, CDCl₃) δ 143.82, 131.76, 122.50, 103.78, 99.12, 27.10, 14.50, −0.02.

1,4-Diethyl-2,5-(diethynyl)benzene (26). See the general procedure for the deprotection of a trimethylsilyl-protected alkyne. The compounds used were 1,4-diethyl-2,5-bis(trimethysilylethynyl)benzene (2.52 g, 7.70 mmol) and potassium carbonate (6.40 g, 46.2 mmol) in methanol (50 mL) for 1 d to afford titled compound as a yellow oil (1.29 g, 92%). FTIR (neat) 3290, 2971, 2933, 2875, 1491, 1457, 1239, 1061, 896 cm⁻¹. ¹H NMR (300 MHz, CDCl₃) δ 7.31 (s, 2H), 3.29 (s, 2H), 2.75 (q, J=7.6 Hz, 4H), 1.22 (t, J=7.6 Hz, 6H). ¹³C NMR (75 MHz, CDCl₃) δ 143.99, 132.27, 121.88, 82.10, 81.68, 26.89, 14.63. HRMS calcd for C₁₄H₁₄: 182.1096. Found: 182.1088.

27. See the general procedure for the Pd/Cu coupling reaction. The compounds used were 26 (0.624 g, 3.42 mmol), 3 (1.95 g, 7.00 mmol), di(benzylidineacetone)palladium(0) (0.20 g, 0.35 mmol), triphenylphosphine (0.37 g, 1.4 mmol), copper(I) iodide (0.13 g, 0.70 mmol), diisopropylethylamine (4.9 mL, 28 mmol) and THF (10 mL). Flash chromatography (silica gel, hexane/CH₂Cl₂/ether=12/6/1) gave desired product as a light yellow crystalline solid (1.19 g, 72%). Mp 154-158° C. FTIR (neat) 2954, 2933, 2872, 1692, 1590, 1497, 1395, 1123, 949, 887, 826 cm⁻¹. ¹H NMR (300 MHz, CDCl₃) δ 7.55 (d, J=8.5 Hz, 4H), 7.39 (d, J=8.4 Hz, 4H), 7.38 (s, 2H), 2.83 (q, J=7.5 Hz, 4H), 2.42 (s, 6H), 1.29 (t, J=7.5 Hz, 6H). ¹³C NMR (75 MHz, CDCl₃) δ 193.42, 143.66, 134.29, 132.08, 131.69, 128.11, 124.68, 122.42, 93.44, 89.88, 30.30, 27.20, 14.73. HRMS calcd for C₃₀H₂₆O₂S₂: 482.1374. Found: 482.1373.

28. To 27 (0.15 g, 0.31 mmol) and sodium hydroxide (0.740 g, 18.5 mmol) was added THF (20 mL) and water (4 mL). The mixture was stirred for 12 h. The solvent was decanted and the precipitate was washed with ether (5×). The solid was suspended in ether and acidified with 3 N HCl (10 mL). The organic layer was separated and washed with water (1×), brine (1×) and dried over magnesium sulfate. Removal of solvent in vacuo gave desired product as a yellow solid (0.11 g, 89%). FTIR (KBr) 2964, 2933, 2872, 2359, 2339, 1590, 1497, 1456, 1400, 1097, 1015, 897, 821 cm⁻¹. ¹H NMR (300 MHz, CDCl₃) δ 7.38 (d, J=8.2 Hz, 4H), 7.35 (s, 2H), 7.23 (d, J=8.4 Hz, 4H), 3.52 (s, 2H), 2.82 (q, J=7.5 Hz, 4H), 1.28 (t, J=7.5 Hz, 6H). ¹³C NMR (75 MHz, CDCl₃) δ 144.28, 132.94, 132.73, 132.42, 129.91, 123.33, 121.55, 94.59, 89.66, 28.27, 15.82. HRMS calcd for C₂₆H₂₂S₂: 398.1163. Found: 398.1167.

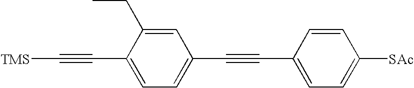

4-Ethynylphenyl-3′-ethyl-4′-trimethylsilylethynyl-1-thioacetylbenzene. See the general procedure for the Pd/Cu coupling reaction. 29^{[20]} (3.28 g, 10.0 mmol), 9^{[16]} (2.23 g, 12.7 mmol), bis(dibenzylideneacetone)palladium(0) (288 mg, 0.50 mmol), copper(I) iodide (0.190 g, 0.042 mmol), triphenylphosphine (655 mg, 2.50 mmol), and diisopropylethylamine (7.0 mL, 40.0 mmol) were stirred in THE (20.0 mL) at room temperature for 1 d. The crude product was purified by flash chromatography on silica gel (hexane-ethyl acetate 19:1) to afford desired product (3.00 g, 80%) as an orange oil. FTIR 2965, 2152, 1713, 1601, 1495, 1250, 1114, 864 cm⁻¹. ¹H NMR (CDCl₃) δ 7.52 (dt, J=8.2, 1.6 Hz, 2H), 7.39 (d, J=7.8 Hz, 1H), 7.38 (dt, J=8.2, 1.6 Hz, 2H), 7.35 (d, J=1.4 Hz, 1H), 7.27 (dd, J=7.8, 1.4 Hz, 1H), 2.78 (q, J=7.6 Hz, 2H), 2.42 (s, 3H), 1.24 (t, J=7.6 Hz, 3H), 0.24 (s, 9H). ¹³C NMR (CDCl₃)

δ 193.3, 146.8, 134.2, 132.4, 132.2, 131.1, 128.8, 128.2, 124.4, 123.0, 122.6, 103.4, 100.0, 91. 1, 90.0, 30.3, 27.6, 14.4, 0.0. HRMS calcd for C₂₃H₂₄OSSi: 376.1317. Found: 376.1308.

30. See the general procedure for the deprotection of a trimethylsilyl-protected alkyne. The compounds used were (31) (940 mg, 2.5 mmol), pyridine (5.0 mL), concentrated hydrofluoric acid (48% in water, 0.18 mL, 5.60 mmol) and TBAF (1.0 M in THF, 2.75 mL, 2.75 mmol) at room temperature for 10 min. The crude product was then purified by flash column chromatography on silica gel (hexane-ether 19:1) to afford desired product (629 mg, 83%). Mp 97-98° C. FTIR (KBr) 3255, 2966, 1702, 1491, 1123, 956, 825 cm⁻¹. ¹H NMR (CDCl₃) δ7.53 (dt, J=8.4, 1.9 Hz, 2H), 7.43 (d, J=7.9 Hz, 1H), 7.38 (dt, J=8.4, 1.9 Hz, 2H), 7.38 (d, J=1.6 Hz, 1H), 7.30 (dd, J=7.9, 1.6 Hz, 1H), 3.33 (s, 1H), 2.81 (q, J=7.6 Hz, 2H), 2.42 (s, 3H), 1.25 (t, J=7.6 Hz, 3H) “³C NMR (CDCl₃) 193.4, 146.9, 134.2, 132.8, 132.2, 131.1, 128.9, 128.3, 124.3, 123.4, 121.9, 90.9, 90.1, 82.4, 81.9, 30.3, 27.4, 14.5. HRMS calcd for C₂₀H₁₆OS: 304.0922. Found: 304.0920.

32. See the general procedure for the Pd/Cu coupling reaction. 1,3,5-Triiodobenzene (228 mg, 0.50 mmol), 30 (547 mg, 1.80 mmol), bis(dibenzylideneacetone)palladium(0) (43 mg, 0.075 mmol), copper(I) iodide (29 mg, 0.15 mmol), triphenylphosphine (98 mg, 0.37 mmol), and diisopropylethylamine (1.0 mL, 6.0 mmol) were stirred in THF (5.0 mL) at room temperature for 65 h. The crude product was washed with a small amount of ethyl acetate to afford a pale yellow solid (107 mg). The washings were combined, evaporated to dryness, and purified by a flash chromatography on silica gel (hexane-ethyl acetate 85:15) to afford another 219 mg yielding a total of 326 mg (66%) of titled compound. Mp 87-88° C. FTIR (KBr) 1700, 1578, 1498, 1384, 1115, 827, 619 cm⁻¹. ¹H NMR (CDCl₃) δ 7.63 (s, 3H), 7.55 (dt, J=8.5, 1.9 Hz, 6H), 7.49 (d, J=7.9 Hz, 3H), 7.43 (d, J=1.6 Hz, 3H), 7.39 (dt, J=8.5, 1.9 Hz, 6H), 7.36 (dd, J=7.9, 1.6 Hz, 3H), 2.90 (q, J=7.5 Hz, 6H), 2.43 (s, 9H), 1.33 (t, J=7.5 Hz, 9H). ¹³C NMR(CDCl₃)δ 193.4, 146.5, 134.3, 133.9, 132.3, 132.2, 131.2, 129.1, 128.3, 124.3, 124.2, 123.3, 122.1, 93.0, 91.0, 90.3, 89.2, 30.3, 27.7, 14.7. HRMS calcd for C₆₆H₄₈O₃S₃: 984.2766. Found: 984.2717.

Bis(4-bromophenyl)methanol (35). To a solution of 1,4-dibromobenzene (5.66 g, 24.0 mmol) in THF (50 mL) at −78° C. was added n-BuLi (14.6 mL, 22.0 mmol, 1.51 M in hexane) dropwise. The slurry was stirred for 40 min and added to a solution of 4-bromobenzylaldehyde (3.7 g, 20 mmol) in THF (40 mL) which was cooled at −78° C. The yellow solution was allowed to warmed to room temperature and stirred for 2 h before pouring into water. The mixture was extracted with ethyl acetate (3×). The combined organic fractions were washed with water (2×) and dried over magnesium sulfate. Removal of solvents in vacuo followed by washing with hexane afforded titled compound as a white solid (5.89 g, 86%). Mp 112-113° C. FTIR (KBr) 3323, 2903, 1590, 1482, 1400, 1328, 1190, 1113, 1072, 1041, 1010, 862, 810, 795 cm⁻¹. ¹H NMR (300 MHz, CDCl₃) δ 7.45 (d, J=8.5 Hz, 4H), 7.21 (d, J=8.3 Hz, 4H), 5.74 (d, J=3.3 Hz, 1H), 2.21 (d, J=3.4 Hz, 1H). ¹³C NMR (75 MHz, CDCl₃) δ 142.23, 131.74, 128.21, 121.78, 75.03. HRMS calcd for C₁₃H₁₀Br₂O: 339.9098. Found: 339.9084.

Bis(4-bromophenyl)methane (36). To a solution of 35 (1.71 g, 5.00 mmol) in TFA (40 mL) was added sodium borohydride (1.89 g, 50.0 mmol) in small portions at room temperature over 10 min.^{[24]} The resulting white slurry was stirred for 40 min before pouring into water. The suspension was carefully made alkaline with aqueous sodium hydroxide solution. The mixture was extracted with ether (3×). The combined organic fraction was washed with water (2×), brine (1×), and dried over magnesium sulfate. Removal of solvents followed by filtering through a short silica gel column (hexane) afforded desired product as a white solid (1.53 g, 94%). Mp 62-62.5° C. FTIR (KBr) 2923, 2851, 1482, 1436, 1400, 1200, 1113, 1067, 1010, 856, 805, 780, 621 cm⁻¹. ¹H NMR (300 MHz, CDCl₃) δ 7.39 (d, J=8.4 Hz, 4H), 7.01 (d, J=8.3 Hz, 4H), 3.86 (s, 2H). ¹³C NMR (75 MHz, CDCl₃) δ 139.46, 131.69, 130.64, 120.26, 40.71. HRMS calcd for C₁₃H₁₀Br₂: 323.9149. Found: 323.9147.

Bis(4-thioacetylphenyl)methane (37). See the general procedure for the conversion of aryl halides to arylthioacetates. The compounds used were 36 (0.978 g, 3.00 mmol) in THF (15 mL), tert-BuLi (8.7 mL, 15 mmol, 1.72 M in pentane) in ether (5 mL), sulfur powder (0.39 g, 12 mmol) in THF (15 mL), and acetyl chloride (1.07 mL, 15.0 mmol). Gravity chromatography (silica gel, hexane/ether 4/1) afforded desired product as a colorless oil (0.764, 81%). Mp 54-55° C. FTIR (neat) 3395, 3026, 2923, 1703, 1595, 1492, 1431, 1405, 1354, 1118, 1092, 1015, 949, 805, 790, 610 cm⁻¹. ¹H NMR (300 MHz, CDCl₃) δ7.32 (d, J=8.2 Hz, 4H), 7.21 (d, J=8.1 Hz, 4H), 4.00 (s, 2H), 2.39 (s, 6H). ¹³C NMR (75 MHz, CDCl₃) δ 194.10, 141.98, 134.70, 129.95, 125.81, 41.37, 30.24. HRMS calcd for C₁₇H₁₆O₂S₂: 316.0592. Found: 316.0583.

4′-Bromo-(4″-iodo)diphenylmethanol (38). See the preparation of 34. The compounds used were 1,4-diiodobenzene (4.29 g, 13.0 mmol) in THF (50 mL), n-BuLi (8.0 mL, 12 mmol, 1.51 M in hexane), and 4-bromobenzylaldehyde (1.85 g, 10.0 mmol) in THF (40 mL). After workup, the solvent was removed in vacuo followed by washing with hexane to give desired compound as a white solid (3.53 g, 91%). Mp 119-120° C. FTIR (KBr) 3333 (broad), 2903, 1590, 1482, 1400, 1328, 1292, 1190, 1113, 1072, 1036, 1005, 862, 831, 810, 790 cm⁻¹. ¹H NMR (300 MHz, CDCl₃) δ 7.65 (d, J=8.4 Hz, 2H), 7.44 (d, J=8.5 Hz, 2H), 7.20 (d, J=8.7 Hz, 2H), 7.08 (d, J=8.5 Hz, 2H), 5.73 (d, J=3.2 Hz, 1H), 2.20 (d, J=3.5 Hz, 1H). ¹³C NMR (75 MHz, CDCl₃) δ 142.92, 142.21, 137.70, 131.75, 128.44, 128.22, 121.79, 93.48, 75.12. HRMS calcd for C₁₃H₁₀BrIO: 389.8939. Found: 389.8930.

4′-Bromo-(4″-iodo)diphenylmethane (39). See the preparation of 35. The compounds used were 38 (1.36 g, 3.50 mmol), sodium borohydride (1.32 g, 35.0 mmol), and TFA (30 mL). Flash chromatography (silica gel, hexane) afforded desired product as white needle-like crystals (1.23 g, 94%). Mp 68-70° C. FTIR (KBr) 3036, 2923, 2851, 1482, 1436, 1395, 1200, 1108, 1067, 1010, 856, 800, 774 cm⁻¹. ¹H NMR (300 MHz, CDCl₃) δ 7.59 (d, J=8.4 Hz, 2H), 7.39 (d, J=8.4 Hz, 2H), 7.01 (d, J=8.5 Hz, 2H), 6.89 (d, J=8.4 Hz, 2H), 3.85 (s, 2H). ¹³C NMR (75 MHz, CDCl₃) δ 140.15, 139.42, 137.68, 131.71, 131.00, 130.68, 120.28, 91.71, 40.84. HRMS calcd for C₁₃H₁₀BrI: 371.9011. Found: 371.8996.

40. See the general procedure for the Pd/Cu coupling reaction. The compounds used were 39 (1.12 g, 3.00 mmol), 1-bromo-4-ethynylbenzene (0.58 g, 3.2 mmol), bis(dibenzylidineacetone)palladium(0) (0.086 g, 0.15 mmol), copper(I) iodide (0.057 g, 0.30 mmol), triphenylphosphine (0.157 g, 0.600 mmol), THF (20 mL), and diisopropylethylamine (2.1 mL, 12 mmol) at room temperature for 2 d. Flash chromatography (silica gel, hexane) afforded desired product as white crystals (1.17 g, 92%). Mp 151-153° C. FTIR (KBr) 2215, 1508, 1482, 1385, 1067, 1005, 867, 826, 810, 780, 621 cm⁻¹. ¹H NMR (300 MHz, CDCl₃) δ 7.46 (d, J=8.8 Hz, 2H), 7.43 (d, J=9.0 Hz, 2H), 7.40 (d, J=8.7 Hz, 2H), 7.35 (d, J=8.3 Hz, 2H), 7.12 (d, J=8.0 Hz, 2H), 7.03 (d, J=8.2 Hz, 2H), 3.92 (s, 2H). ¹³C NMR (75 MHz, CDCl₃) δ 141.10, 139.48, 133.03, 131.85, 131.66, 131.64, 130.70, 129.01, 122.45, 122.31, 120.94, 120.22, 90.43, 88.23, 41.22. HRMS calcd for C₂₁H₁₄Br₂: 423.9462. Found: 423.9465.

41. See the general procedure for the conversion of aryl halide to arylthioacetate. The compounds used were 40 (0.852 g, 2.00 mmol) in THF (20 mL), tert-BuLi (6.0 mL, 10 mmol, 1.67 M in pentane) in ether (5 mL), sulfur powder (0.257 g, 8.00 mmol) in THF (10 mL), and acetyl chloride (0.71 mL, 10 mmol). Flash chromatography (silica gel, hexane/ether 4/1, then hexane/CH₂Cl₂1/1) afforded desired product as a white solid (0.724 g, 87%). Mp 99-100° C. FTIR (KBr) 1697, 1513, 1385, 1354, 1123, 1015, 959, 826, 785, 621 cm⁻¹. ¹H NMR (300 MHz, CDCl₃) δ 7.53 (d, J=8.5 Hz, 2H), 7.45 (d, J=8.3 Hz, 2H), 7.37 (d, J=8.6 Hz, 2H), 7.32 (d, J=8.4 Hz, 2H), 7.20 (d, J=8.4 Hz, 2H), 7.16 (d, J=8.4 Hz, 2H), 4.00 (s, 2H), 2.42 (s, 3H), 2.40 (s, 3H). ¹³C NMR (75 MHz, CDCl₃) δ 194.29, 193.51, 142.13, 140.98, 134.65, 134.23, 132.17, 131.93, 129.83, 129.15, 127.95, 125.66, 124.64, 120.93, 91.03, 88.52, 41.55, 30.30, 30.19. HRMS calcd for C₂₅H₂₀O₂S₂: 416.0905. Found: 416.0919.

Bis(4-diethyltriazenylphenyl)methane (43). To 4,4′-methylenedianiline (42) (19.83 g, 100 mmol) in water (80 mL) and concentrated hydrochloric acid (30 mL) was added sodium nitrite (15.18 g, 220 mmol) in water (120 mL) at 0° C. The reaction was stirred at 0° C. for 30 min and then poured into a solution of potassium carbonate (165.85 g, 1.200 mmol) and diethylamine (22.76 mL, 220 mmol) in water (500 mL) at 0° C. The reaction was stirred for 30 min at 0° C. and then poured into water. The aqueous layer was extracted with diethyl ether (3×25 mL) and the organic layer was dried over magnesium sulfate and the product concentrated in vacuo to afford 17.30 g (47%) of the title compound as a viscous brown liquid. IR (neat) 3083, 3024, 2931, 1905, 1601, 1502, 1090, 1014, 854, 821, 787, 736, 700, 624 cm⁻¹. ¹H NMR (400 MHz, CDCl₃) δ 7.31 (d, J=8.3 Hz, 4H), 7.12 (d, J=8.4 Hz, 4H), 3.94 (s, 2H), 3.72 (q, J=7.2 Hz, 8H), 1.23 (t, J=7.1 Hz, 12H). ¹³C NMR (125 MHz, CDCl₃) δ 150.03, 138.76, 129.85, 120.98, 54.03, 41.60, 13.48.

Bis(4-iodophenyl)methane (44). See the general procedure for the iodination of triazenes. The title compound was prepared as above from 43 (9.15 g, 25 mmol) and iodomethane (25 mL) to yield 6.36 g (61%) of the title compound as a fluffy white solid. IR (KBr) 3025, 2919, 2848, 1898, 1477, 1394, 1196, 1105, 1056, 1003, 854, 798, 772, 617 cm⁻¹. ¹H NMR (400 MHz, CDCl₃) δ 7.58 (d, J=8.3 Hz, 4H), 6.88 (d, J=8.4 Hz, 4H), 3.83 (s, 2H). ¹³C NMR (100 MHz, CDCl₃) δ 140.15, 137.76, 131.15, 92.04, 41.07. LRMS calcd for C₁₃H₁₀I₂: 420. Found: 420.

45. See the general procedure for the Pd/Cu coupling reaction. 44 (84 mg, 0.20 mmol), 9^{[16]} (84 mg, 0.48 mmol), bis(dibenzylideneacetone)palladium(0) (12 mg, 0.021 mmol), copper(I) iodide (8 mg, 0.042 mmol), triphenylphosphine (30 mg, 0.10 mmol), and diisopropylethylamine (0.33 mL, 1.92 mmol) were stirred in THF (2.0 mL) at room temperature for 80 h. The crude product was purified by flash chromatography on silica gel (hexane-ethyl acetate 9:1) to afford titled compound (73 mg, 71%) as a yellow solid. Mp 173-174° C. FTIR (KBr) 1701, 1508, 1385, 1118, 828 cm⁻¹. ¹H NMR (CDCl₃) δ 7.52 (dt, J=8.3, 1.8 Hz, 4H), 7.44 (d, J=8.2 Hz, 4H), 7.37 (dt, J=8.3, 1.8 Hz, 4H), 7.15 (d, J=8.2 Hz, 4H), 3.98 (s, 2H), 2.41 (s, 6H). ¹³C NMR (CDCl₃) δ 193.5, 141.2, 134.2, 132.1, 131.9, 129.0, 127.9, 124.6, 120.9, 91.0, 88.5, 41.7, 30.3. HRMS calcd for C₃₃H₂₄O₂S₂: 516.1218. Found: 516.1207.

46. To a solution of 1,4-diiodobenzene (726 mg, 2.2 mmol) in dry THF (10 mL) was at −78° C. n-butyllithium (1.53 M in hexane, 1.37 mL, 2.1 mmol). The yellow suspension was stirred at −78° C. for 30 min and terephthaldehyde (134 mg, 1.0 mmol) in dry THF (5.0 mL) was added. After stirring at room temperature for 30 min, the suspension was poured into water. The solution was extracted with ether and dried over magnesium sulfate. After filtration, the solvent was evaporated in vacuo to afford a colorless oil. The oil was separated by flash chromatography on silica gel (hexane-ethyl acetate 7:3) to afford the desired product as a white solid (317 mg, 59%). The product was a 1:1 mixture of diastereomers. Mp 160-164° C. FTIR (KBr) 3355, 1482, 1397, 1192, 1038, 1006, 799, 774 cm⁻¹. ¹HNMR(CDCl₃) δ 7.63 (d, J=8.4 Hz, 4H), 7.29 (s, 4H), 7.09 (d, J=8.4 Hz, 4H), 5.75 (s, 1H), 5.74 (s, 1H), 2.16 (s, 1H), 2.15 (s, 1H). ¹³C NMR (CDCl₃) δ 143.2, 143.0, 137.6, 128.4, 126.8, 93.1, 75.4. HRMS calcd for C₂₀H₁₆O₂I₂: 541.9240. Found: 541.9216.

47. To trifluoroacetic acid (20 mL) was added under nitrogen at 0° C. a mixture of 46 (542 mg, 1.0 mmol) and sodium borohydride (760 mg, 20.0 mmol).^{[24]} The mixture was stirred at 0° C. for 1.5 h and poured into water. The solution was extracted with dichloromethane and washed with a saturated solution of sodium bicarbonate and brine. The solution was dried over magnesium sulfate. After filtration, the solvent was evaporated in vacuo to afford a white solid. The solid was crystallized from cyclohexane and purified by flash chromatography on silica gel to afford the desired product as a white solid (359 mg, 70%). Mp 141-142° C. FTIR (KBr) 1511, 1480, 1426, 1398, 1181, 1003, 797, 752, 627, 471 cm⁻¹. ¹H NMR (CDCl₃) δ 7.57 (d, J=8.2 Hz, 4H), 7.05 (s, 4H), 6.91 (d, J=8.2 Hz, 4H), 3.86 (s, 4H). ¹³C NMR (CDCl₃) δ 140.8, 138.4, 137.5, 131.0, 129.0, 91.3, 41.0. HRMS calcd for C₂₀H₁₆I₂: 509.9342. Found: 509.9331.

48. See the general procedure for the Pd/Cu coupling reaction. 47 (255 mg, 0.50 mmol), 9^{[16]} (201 mg, 1.1 mmol), bis(dibenzylideneacetone)palladium(0) (23 mg, 0.040 mmol), copper(I) iodide (20 mg, 0.10 mmol), triphenylphosphine (75 mg, 0.25 mmol), and diisopropylethylamine (0.70 mL, 4.0 mmol) were stirred in THF (4.0 mL) at room temperature for 65 h. The crude product was washed with a small amount of ethyl acetate to afford a yellow solid. The solid was dissolved in hot ethyl acetate and the solution was filtered. After the solvent was evaporated in vacuo, the title compound was afforded as a yellow solid (269 mg, 89%). Mp 188-190° C. (ethyl acetate). FTIR (KBr) 1692, 1560, 1508, 1384, 1112, 826, 695 cm⁻¹. ¹H NMR (CDCl₃) δ7.52 (dt, J=8.5, 1.9 Hz, 4H), 7.43 (d, J=8.3 Hz, 4H), 7.37 (dt, J=8.5, 1.9 Hz, 4H), 7.15 (d, J=8.3 Hz, 4H), 7.09 (s, 4H), 3.95 (s, 4H), 2.41 (s, 6H). ¹³C NMR (CDCl₃) δ 193.5, 141.9, 138.5, 134.2, 132.1, 131.8, 129.1, 129.0, 127.9, 124.7, 120.6, 91.1, 88.3, 41.5, 30.3. HRMS calcd for C₄₀H₃₀O₂S₂: 606.1687. Found: 606.1698.

4-Iodobenzaldehyde.^{[41]} To a solution of 1,4-diiodobenzene (5.11 g, 0.015 mol) in diethyl ether (2.1 mL) at −78° C. was added dropwise n-butyllithium (6.14 mL, 1.50 M in hexanes) over a period of 30 min. The reaction was stirred for 1 h. To this solution was added dropwise dry DMF (1.19 mL) over a period of 30 min. The reaction mixture was gradually allowed to warm to room temperature. The reaction mixture was quenched with distilled water and the mixture extracted with methylene chloride (3×70 mL). It was dried over sodium sulfate and the solvents were removed in vacuo to yield a yellow oil that solidified on cooling. The sample was purified by silica gel column chromatography using hexane/methylene chloride (1:1, v/v) to provide 2.50 g (70%) of the title compound as a white solid. ¹H NMR (300 MHz, CDCl₃) δ 9.95 (s, 1H), 7.55 (d, J=8.4 Hz, 2H), 7.87 (d, J=8.37 Hz, 2H). FABMS Calcd for C₇H₅IO: 232. Found: 232. C NMR (100 MHz, CDCl₃) δ 130.77, 135.56, 138.39, 191.23. Anal. Calcd for C₇H₅₁₀: C, 36.23; H, 2.17. Found. C, 36.46; H, 2.12.

3,4′,5-Triiododiphenylmethanol (49). To a solution of 1,3,5-triiodobenzene (3.37 g, 7.41 mmol) in dry THF (90 mL) at −78° C. was added n-butyllithium (1.57 M in hexane, 5.18 mL, 8.14 mmol). The solution was stirred for 30 min and transferred via cannula into 4-iodobenzaldehyde (2.06 g, 8.88 mmol) in dry THF (50 mL) at −78° C. The solution was stirred for 10 min and temperature was gradually raised to room temperature. The solution was poured into water and extracted with ether and washed with brine. The extract was dried over magnesium sulfate. After filtration, the solvent was evaporated in vacuo to afford a brown oil. The oil was separated by flash chromatography on silica gel (hexane-ethyl acetate 19:1 to 8:2) to afford desired product (2.32 g, 59%) as white crystals. Mp 146-147° C. FTIR (KBr) 3416, 1567, 1540, 1410, 1384, 1167, 1038, 1005, 830 cm⁻¹. At NMR (CDCl₃) δ 7.93 (t, J=1.5 Hz, 1H), 7.67 (dt, J=8.7, 2.0 Hz, 2H), 7.63 (dd, J=1.5, 0.6 Hz, 2H), 7.06 (dtd, J=8.7, 2.0, 0.3 Hz, 2H), 5.63 (d, J=2.4 Hz, 1H), 2.25 (d, J=3.3 Hz, 1H). ¹³C NMR (CDCl₃) 3147.1, 144.4, 142.2, 137.9, 134.7, 128.4, 95.0, 93.9, 74.3. HRMS calcd for C₁₃H₉I₃O: 561.7789. Found; 561.7798.

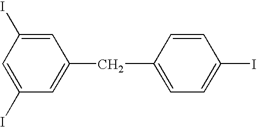

3,4′,5-Triiododiphenylmethane. The procedure by Gribble was modified as follows.^{[24]} To trifluoroacetic acid (50 mL) was added under nitrogen at room temperature sodium borohydride (1.05 g, 27.6 mmol). Before all of the sodium borohydride reacted with the trifluoroacetic acid, 49 (1.56 g, 2.78 mmol) in dichloromethane (50 mL) was added dropwise. The mixture was stirred for 1 h. Additional pieces of sodium borohydride (606 mg, 15.9 mmol) were added in portions over 6 h. The mixture was stirred for 1 h and then poured into ice water. The solution was neutralized by a careful addition of sodium hydroxide pellets. The solution was extracted with dichloromethane and washed with brine. The extract was dried over magnesium sulfate. After filtration, the solvent was evaporated in vacuo to afford a mixture of a yellow oil and a white solid. The mixture was washed with hexane-ethyl acetate (8:2) and filtered to afford a white solid (599 mg). The washings were combined, evaporated to dryness, and again purified by flash chromatography on silica gel (hexane-ethyl acetate 8:2) to afford another 145 mg yielding a total of 744 mg (49%) of desired compound in addition to the recovery of 49 (338 mg, 22%). Mp 147-148° C. FTIR (KBr) 1571, 1539, 1482, 1418, 1384, 1006, 858, 787, 706 cm⁻¹. ¹ H NMR (CDCl₃) δ 7.88 (t, J=1.5 Hz, 1H), 7.61 (dt, J=8.6, 2.1 Hz, 2H), 7.43 (d, J=1.5 Hz, 2H), 6.88 (dt, J=8.6, 2.1 Hz, 2H), 3.77 (s, 2H). ¹³C NMR (CDCl₃) δ 144.5, 143.1, 139.0, 137.8, 137.1, 130.9, 95.1, 92.1, 40.4. HRMS calcd for C₆₆H₄₈O₃S₃: 545.7838. Found: 545.7840.

50. See the general procedure for the Pd/Cu coupling reaction. 49 (295 mg, 0.54 mmol), 30 (587 mg, 1.93 mmol), bis(dibenzylideneacetone)palladium(0) (47 mg, 0.081 mmol), copper(I) iodide (30 mg, 0.16 mmol), triphenylphosphine (107 mg, 0.41 mmol), and diisopropylethylamine (1.13 mL, 6.5 mmol) were stirred in THF (5.0 mL) at room temperature for 3 d. The crude product was washed with a small amount of ethyl acetate to afford a pale brown solid (355 mg). The washings were combined, evaporated to dryness, and further purified by flash chromatography on silica gel (hexane-ethyl acetate 8:2) to afford a yellow oil. The oil was crystallized from ethyl acetate to afford another 125 mg yielding a total of 480 mg (83%) of desired product. Mp 132-134° C. FTIR (KBr) 2954, 2203, 1698, 1588, 1498, 1384, 1116, 827, 620 cm⁻¹. ¹H NMR (CDCl₃) δ 7.55-7.53 (m, 7H), 7.48 (d, J=8.2 Hz, 2H), 7.46 (d, J=7.9 Hz, 2H), 7.46 (d, J=8.0 Hz, 1H), 7.41 (d, J=1.4 Hz, 2H), 7.41-7.37 (m, 7H), 7.33 (dd, J=7.9, 1.4 Hz, 2H), 7.34-7.31 (m, 3H), 7.21 (d, J=8.2 Hz, 2H), 4.00 (s, 2H), 2.87 (q, J=7.6 Hz, 4H), 2.86 (q, J=7.5 Hz, 2H), 2.42 (s, 91H), 1.31 (t, J=7.6 Hz, 6H), 1.30 (t, J=7.5 Hz, 3H). ¹³C NMR (CDCl₃) δ 193.4, 146.4, 146.2, 141.3, 140.5, 134.4, 134.2, 132.4, 132.3, 132.2, 132.1, 131.9, 131.6, 131.2, 129.1, 129.0, 129.0, 128.4, 128.3, 128.3, 128.2, 124.4, 124.4, 124.0, 123.1, 122.8, 122.7, 122.4, 121.5, 94.7, 93.8, 91.2, 91.1, 90.2, 90.0, 88.6, 87.9, 41.4, 30.3, 27.7, 27.6, 14.6, 14.6. Anal. calcd for C₇₃H₅₄O₃S₃: C, 81.53; H, 5.06. Found: C, 81.48; H, 5.07.

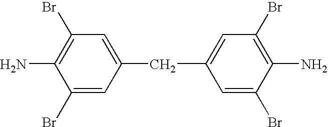

Bis(3,5-dibromo-4-aminophenyl)methane. To 4,4′-diaminodiphenylmethylene (594 mg, 3.0 mmol) in a methanol/dichloromethane (1:1) solution (20 mL) was added dropwise bromine (0.77 mL, 15.0 mmol) in a methanol/dichloromethane (1:1) solution (20 mL). The mixture was stirred at room temperature for 3 h before poured into 1 N sodium hydroxide solution. The mixture was filtered to afford a white solid. The solid was washed with water and dried to give titled compound (1.45 g, 94%). Mp>250° C. FTIR (KBr) 3424, 3315, 1618, 1472, 1060 cm¹. ¹H NMR (CDCl₃) δ 7.14 (s, 4H), 3.66 (s, 2H). HRMS calcd for C₁₃H₁₀N₂Br₄: 509.7577, Found: 509.7600. Insolubility of the material inhibited obtaining other spectral characterization.

Bis(3,5-dibromophenyl)methane (51). To sodium nitrite (208 mg, 3.0 mmol) in sulfuric acid (5.0 mL) at 5° C. was added dropwise a suspension of bis(3,5-dibromo-4-aminophenyl)methane (514 mg, 1.0 mmol) in glacial acetic acid (5.0 mL). During the addition, the temperature was maintained below 10° C. The mixture was stirred at 5° C. for 30 min and a 50% aqueous solution of hypophosphorous acid (3.12 mL, 30 mmol) was added dropwise. After stirring for 30 min at 5° C., the mixture was placed in a refrigerator for 1 d and then allowed to stand at room temperature overnight. The mixture was poured into water and extracted with ethyl acetate. The extract was washed with sodium bicarbonate solution and brine and dried over magnesium sulfate. After filtration, the solvent was evaporated in vacuo to afford a brown solid. The solid was crystallized from chloroform to afford desired product (109 mg, 23%) as a white solid. Mp 196° C. FTIR (KBr) 3036, 1575, 1556, 1417, 1104, 849 cm⁻¹. ¹H NMR (CDCl₃) δ 7.54 (t, J=1.7 Hz, 2H), 7.21 (d, J=1.7 Hz, 4H), 3.82 (s, 2H). ¹³C NMR (CDCl₃) δ 143.1, 132.5, 130.7, 123.2, 40.4. HRMS calcd for C₁₃H₈Br₄: 479.7359. Found: 479.7357.

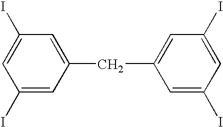

Bis(3,5-diiodophenyl)methane. To a solution of bis(3,5-dibromophenyl)methane (484 mg, 1.0 mmol) in dry THF (1.0 mL) was added under nitrogen at −78° C./1-butyllithium (1.58 M in hexane, 3.2 mL, 5.0 mmol). The solution was stirred at −78° C. for 1 h. After chlorotrimethylsilane (1.27 mL, 10.0 mmol) was added, the solution was stirred at −78° C. for 30 min and at room temperature overnight. The solution was poured into water and extracted with ether. The extract was dried over magnesium sulfate. After filtration, the solvent was evaporated in vacuo to afford a brown oil. The oil was separated by flash chromatography on silica gel (hexane-ethyl acetate 19:1) to afford bis(3,5-bistrimethylsilylphenyl)methane (377 mg) as a yellow oil. The oil contained a small amount of impurity but it was used for next reaction without further purification. To a solution of bis(3,5-bistrimethylsilylphenyl)methane (332 mg, 0.73 mmol) in carbon tetrachloride (10 mL) was added at room temperature iodine monochloride (0.16 mL, 3.2 mmol) in carbon tetrachloride (5.0 mL). The solution was stirred at room temperature for 1 h and poured into an aqueous solution of sodium thiosulfate. The aqueous solution was extracted with dichloromethane. The solution was dried over magnesium sulfate. After filtration, the solvent was evaporated in vacuo to afford a brown oil. The oil was washed with a small amount of dichloromethane to afford the desired product (209 mg, 36%) as a white solid. Mp 219-221° C. FTIR (KBr) 1560, 1542, 1412, 1384, 712 cm⁻¹. ¹H NMR (CDCl₃) δ 7.91 (s, 2H), 7.42 (t, J=1.5 Hz, 4H), 7.42 (d, J=1.5, 4H), 3.71 (s, 2H). ¹³C NMR (CDCl₃) δ 143.6, 137.1, 94.8, 39.8. HRMS calcd for C₁₃H₈I₄: 671.6805. Found: 671.6802.

52. See the general procedure for the Pd/Cu coupling reaction. Bis(3,5-diiodophenyl)methane (170 mg, 0.25 mmol), 9^{[16]} (211 mg, 1.20 mmol), bis(dibenzylideneacetone)palladium(0) (29 mg, 0.050 mmol), copper(I) iodide (19 mg, 0.10 mmol), triphenylphosphine (66 mg, 0.25 mmol), and diisopropylethylamine (0.70 mL, 4.0 mmol) were stirred in THF (4.0 mL) at room temperature for 2 d. The crude product was dissolved in ethyl acetate and passed through a plug of silica gel. Then the crude solid was washed with a small amount of ethyl acetate, dissolved in hot ethyl acetate and filtered to afford titled compound (102 mg, 47%) as a pale yellow solid. Mp 1.77-178° C. FTIR (KBr) 1701, 1593, 1486, 1385, 1118, 828 cm⁻¹. ¹H NMR (CDCl₃) δ 7.59 (t, J=2.5 Hz, 2H), 7.53 (dt, J=8.3, 1.7 Hz, 8H), 7.38 (dt, J=8.3, 1.7 Hz, 8H), 7.34 (d, J=1.5 Hz, 4H), 3.96 (s, 2H), 2.41 (s, 12H). ¹³C NMR (CDCl₃) δ 193.3, 140.7, 134.2, 133.0, 132.2, 132.2, 128.4, 124.1, 123.7, 90.1, 89.5, 30.0. HRMS calcd for C₅₃H₃₆O₄S₄: 864.1496. Found: 864.1453.

53. See the general procedure for the Pd/Cu coupling reaction. Bis(3,5-diiodophenyl)methane (108 mg, 0.16 mmol), 30 (220 mg, 0.72 mmol), bis(dibenzylideneacetone)palladium(0) (18 mg, 0.032 mmol), copper(I) iodide (12 mg, 0.064 mmol), triphenylphosphine (42 mg, 0.16 mmol), and diisopropylethylamine (0.45 mL, 2.59 mmol) were stirred in THF (3.0 mL) at room temperature for 60 h. The crude product was dissolved in hexane-ethyl acetate (1:1) to afford a pale yellow solid. The solid was washed with a small amount of ethyl acetate to afford the desired product (107 mg, 49%) as a pale yellow solid. Mp 104-107° C. FTIR (KBr) 1707, 1585, 1498, 1384, 1108, 826 cm¹. 1 H NMR (CDCl₃) δ 7.57 (t, J=1.3 Hz, 2H), 7.54 (dt, J=8.3, 1.7 Hz, 8H), 7.48 (d, J=8.0 Hz, 4H), 7.41 (d, J=1.3 Hz, 4H), 7.38 (dt, J=8.3, 1.7 Hz, 8H), 7.35 (d, J=1.3 Hz, 4H), 7.33 (dd, J=8.0, 1.3 Hz, 4H), 4.00 (s, 2H), 2.88 (q, J=7.6 Hz, 8H), 2.42 (s, 12H), 1.31 (t, J=7.6 Hz, 12H). ¹³C NMR (CDCl₃) δ 193.8, 146.8, 141.1, 134.6, 133.0, 132.6, 132.6, 132.3, 131.6, 129.4, 128.6, 124.8, 124.5, 123.5, 122.7, 94.1, 91.4, 90.6, 89.1, 41.3, 30.7, 28.0, 15.0. Anal. calcd for C₉₃H₆₈O₄S₄: C, 81.07; H, 4.97. Found: C, 81.16; H, 4.99.

2,5-Bis(p-bromobenzoyl)-1,4-dibromobenzene (56). To a suspension of aluminum chloride (2.67 g, 20.0 mmol) in CH₂Cl₂ (50 mL) at 0° C. was slowly added a solution of 54^{[26]} (3.25 g, 9.00 mmol) in CH₂Cl₂. The resultant yellow slurry was stirred for 10 min and a solution of 1-bromo-4-trimethylsilylbenzene (4.89 g, 21.3 mmol) in CH₂Cl₂ (15 mmol) was added. The mixture was stirred for 2 h at 0° C. and overnight at room temperature. The brown mixture was carefully poured into cold 1.5 N HCl solution. Dichloromethane (100 mL) was added to dissolve the precipitate and the organic phase was separated. The aqueous phase was extracted with CH₂ Cl₂ (2×). Combined organic fractions were washed with H₂O (1×) and dried over magnesium sulfate. After filtration, the solvent was concentrated to ca. 100 mL and filtered through a short silica gel column [CH₂Cl₂/hexane (1/1)]. Removal of solvents followed by washing with hexane and ether afforded desired product as a white solid (3.25 g, 60%). Mp 254-256° C. FTIR (KBr) 3097, 1677, 1585, 1400, 1385, 1339, 1246, 1067, 1010, 928, 882, 841, 749 cm⁻¹. ¹H NMR (300 MHz, CDCl₃) δ 7.69 (d, J=8.9 Hz, 4H), 7.65 (d, J=9.0 Hz, 4H), 7.58 (s, 2H). ¹³C NMR (CDCl₃, 50° C., 100 MHz) 192.16, 142.94, 134.02, 133.08, 132.29, 131.42, 129.86, 118.54. HRMS calcd for C₂₀H₁₀Br₄O₂: 597.7414. Found: 597.7400.

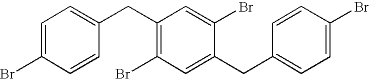

2,5-Bis(p-bromobenzyl)-1,4-dibromobenzene. To a suspension of 56 (2.11 g, 3.50 mmol) in CH₂ Cl₂ (70 mL) was added dropwise trifluoromethanesulfonic acid (3.15 g, 21.0 mmol). The clear golden solution was cooled to 0° C. and a solution of triethylsilane (3.15 g, 17.5 mmol) in CH₂Cl₂ (10 mL) was added dropwise.²² The resulting light yellow solution was stirred at 0° C. for 10 min. Another portion of trifluoromethanesulfonic acid (3.15 g, 21.0 mmol) and triethylsilane (3.15 g, 17.5 mmol) was added by the above addition sequence at 0° C. The obtained light yellow solution was allowed to warm to room temperature and stir for 3 h before pouring into saturated aqueous sodium carbonate (100 mL). The aqueous phase was separated and extracted with CH₂Cl₂ (2×). The combined organic fractions were washed with H₂O (2×) and dried over magnesium sulfate. Removal of solvents followed by washing with hexane afforded desired product as a white solid (1.76 g, 88%). Mp 161-167° C. FTIR (KBr) 1487, 1472, 1436, 1405, 1385, 1072, 1056, 1010, 897, 831, 774 cm⁻¹. ¹H NMR (300 MHz, CDCl₃) δ 7.41 (d, J=8.4 Hz, 4H), 7.28 (s, 2H), 7.03 (d, J=8.4 Hz, 4H), 3.97 (s, 4H). ¹³C NMR (75 MHz, CDCl₃) δ 139.97, 137.63, 134.75, 131.76, 130.69, 123.74, 120.52, 40.59. HRMS calcd for C₂₀H₁₄Br₄: 569.7829. Found: 569.7834.

2,5-Bis(p-iodobenzyl)-1,4-diiodobenzene (57). To tert-BuLi (5.62 mL, 10.0 mmol, 1.78 M in pentane) in ether (5 mL) at −78° C. was added via cannula a solution of 2,5-bis(p-bromobenzyl)-1,4-dibromobenzene (0.574 g, 1.00 mmol) in THF (15 mL) dropwise. The brown slurry was stirred for 30 min and then warmed to 0° C. The slurry was re-cooled to −78° C. and a solution of iodine (2.54 g, 10.0 mmol) in THF (10 mL) was added via cannula. The mixture was allowed to warmed to room temperature and stir for 1 h before pouring into an aqueous solution of sodium thiosulfate. The organic phase was separated. The aqueous layer was extracted with CH₂Cl₂ (2×). Combined organic fractions were washed with H₂O (2×) and dried over magnesium sulfate. Removal of solvents followed by washing with ethyl acetate afforded desired product as a white solid (0.442 g, 58%). Mp 210-213° C. FTIR (KBr) 3149, 1482, 1431, 1400, 1385, 1354, 1185, 1041, 1005, 897, 815, 774 cm⁻¹. ¹H NMR (300 MHz, CDCl₃) δ 7.61 (d, J=8.4 Hz, 4H), 7.53 (s, 2H), 6.89 (d, J=8.4 Hz, 4H), 3.94 (s, 4H). No ¹³C could be obtained due to the limited solubility of 57. HRMS calcd for C₂₀H₁₄I₄: 761.7274. Found: 761.7270.

58. See the general procedure for the Pd/Cu coupling reaction. The compounds used were 57 (0.38 g, 0.50 mmol), 9^{[16]} (0.44 g, 2.5 mmol), di(benzylidineacetone)palladium(0) (0.058 g, 0.10 mmol), copper(I) iodide (0.038 g, 0.20 mmol), triphenylphosphine (0.53 g, 0.20 mmol), THF (15 mL), and diisopropylethylamine (1.4 mL, 8.0 mmol) at room temperature. The mixture was stirred for 8 h. Another portion of di(benzylidineacetone)palladium(0) (0.029 g, 0.050 mmol) and PPh₃ (0.026 g, 0.10 mmol) in THF (5 mL) was added. The mixture was further stirred for 21 h. Flash chromatography (silica gel, hexane/CH₂Cl₂ 1/1) gave desired product as a white solid (0.165 g, 35%). Mp 239-240° C. FTIR (KBr) 1708, 1497, 1385, 1354, 1123, 1015, 854, 826, 621 cm⁻¹. ¹H NMR (300 MHz, CDCl₃) δ 7.52 (d, J=8.5 Hz, 4H), 7.46 (d, J=7.9 Hz, 8H), 7.37 (d, J=8.5 Hz, 4H), 7.36 (d, J=8.6 Hz, 4H), 7.35 (s, 2H), 7.24 (d, J=8.3 Hz, 4H), 4.19 (s, 4H), 2.42 (s, 6H), 2.41 (s, 6H). ¹³C NMR (75 MHz, CDCl₃) δ 193.53, 193.37, 140.72, 140.69, 134.32, 134.24, 133.34, 132.19, 132.11, 131.94, 129.10, 128.53, 127.94, 124.67, 124.12, 123.23, 120.89, 94.61, 91.17, 89.64, 88.56, 39.80, 30.36, 30.32. HRMS calcd for C₆₀H₄₂O₄S₄: 954.1966. Found: 954.1999. Anal. calcd for C₆₀H₄₂O₄S₄: C, 75.44; H, 4.43. Found: C, 75.52; H, 4.51.

59. See the general procedure for the Pd/Cu coupling reaction. The compounds used were 57 (0.076 g, 0.10 mmol), 30 (0.157 g, 0.500 mmol), di(benzylidineacetone)palladium(0) (0.012 g, 0.020 mmol), copper(I) iodide (0.0076 g, 0.040 mmol), triphenylphosphine (0.026 g, 0.10 mmol), THF (3 mL), and diisopropylethylamine (0.28 mL, 1.6 mmol) for 60 h at room temperature. Flash chromatography (silica gel, CHCl₃/hexane 1/1) afforded desired product as a green/yellow solid (0.060 g, 41%). Mp 159-162° C. FTIR (KBr) 2964, 2933, 2872, 2205, 1708, 1595, 1508, 1400, 1385, 1349, 1118, 1087, 1015, 949, 892, 826, 613 cm⁻¹.

¹H NMR (300 MHz, CDCl₃) δ 7.54 (d, J=8.1 Hz, 8H), 7.48-7.43 (m, 6H), 7.40-7.36 (m, 16H), 7.32 (dd, J=8.2, 1.7 Hz, 4H), 7.25 (d, J=8.1 Hz, 4H), 4.25 (s, 4H), 2.86 (q, J=7.6 Hz, 4H), 2.76 (q, J=7.6 Hz, 4H), 2.42 (s, 1211), 1.29 (t, J=7.6 Hz, 6H), 1.21 (t, J=7.6 Hz, 6H). ¹³C NMR (100 MHz, CDCl₃) δ 193.31, 193.28, 146.19, 146.11, 140.53, 140.22, 134.21, 133.37, 132.27, 132.16, 132.04, 131.73, 131.16, 128.97, 128.94, 128.25, 128.14, 124.43, 124.32, 123.59, 123.15, 122.83, 1.22.68, 122.37, 121.26, 94.82, 93.72, 93.30, 91.21, 91.07, 90.32, 90.00, 87.77, 39.78, 30.45, 27.81, 27.75, 14.86, 14.77. LRMS calcd for C₁₀₀H₇₄O₄S₄: 1468. Found: 1468. Anal. calcd for C₁₀₀H₇₄O₄S₄: C, 81.82; H, 5.08. Found: C, 81.68; H, 5.13.

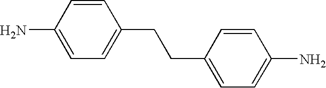

1,2-Bis(4′-aminophenyl)ethane. To a Parr flask was added 60 (5.45 g, 20.0 mmol), 10% palladium on activated carbon (274 mg), and ethanol (50 mL). The flask was purged with hydrogen and pressurized to 60 psi. The flask was shaken for 5 h at room temperature. After filtration, the solvent was evaporated in vacuo to afford desired compound (2.50 g, 59%) as a white solid. Mp>250° C. ¹H NMR (CDCl₃) δ 6.95 (d, J=8.2 Hz, 4H), 6.61 (d, J=8.2 Hz, 4H), 3.47 (br, 4H), 2.74 (s, 4H).

1,2-Bis(4′-diethyltriazenylphenyl)ethane (61). To 1,2-bis(4′-aminophenyl)ethane (1.00 g, 4.72 mmol), hydrochloric acid (15 mL), and water (50 mL) was added at 0° C. sodium nitrite (716 mg, 10.4 mmol) in water (2.0 mL). The solution was stirred for 30 min at 0° C. and poured into potassium carbonate (10.4 g, 75.2 mmol), diethylamine (10 mL), and water (100 mL). An orange solid was removed by filtration and washed with water. After drying, the desired solid (1.59 g, 87%) was obtained. Mp 64-66° C. FTIR (KBr) 2980, 2935, 1433, 1402, 1384, 1351, 1235, 1089, 841 cm⁻¹. ¹H NMR (CDCl₃) δ 7.30 (dt, J=8.3, 2.0 Hz, 4H), 7.11 (dt, J=8.3, 2.0 Hz, 4H), 3.73 (q, J=7.2 Hz, 8H), 2.87 (s, 4H), 1.24 (t, J=7.2 Hz, 12H). ¹³C NMR (CDCl₃) δ 149.4, 138.8, 128.9, 120.3, 37.7, 13.1 (br) (one carbon is missing due to the quadropolar effect of nitrogen.). HRMS calcd for C₂₂H₃₂N₆: 380.2688. Found: 380.2696.

1,2-Bis(4′-iodophenyl)ethane (62). See the standard procedure. The compounds used were 61 (800 mg, 2.48 mmol) and iodomethane (15 mL) at 120° C. overnight. After cooling, the reaction was diluted with hexane-ethyl acetate (1:1) and passed through a plug of silica gel. The solvent was evaporated in vacuo to afford desired compound (834 mg, 78%) as a yellow solid. Mp 150-151° C. FTIR (KBr) 1482, 1384, 1002, 816 cm⁻¹. ¹H NMR (CDCl₃) δ 7.56 (d, J=8.3 Hz, 4H), 6.86 (d, J=8.3 Hz, 4H), 2.81 (s, 4H). ¹³C NMR (CDCl₃) δ 140.8, 137.4, 130.6, 91.2, 37.1. HRMS calcd for C₁₄H₁₂I₂: 433.9028. Found: 433.9027.

63. See the general procedure for the Pd/Cu coupling reaction. 62 (304 mg, 0.7 mmol), 9^{[16]} (296 mg, 1.68 mmol), bis(dibenzylideneacetone)palladium(0) (40 mg, 0.070 mmol), copper(I) iodide (27 mg, 0.14 mmol), triphenylphosphine (92 mg, 0.35 mmol), and diisopropylethylamine (0.97 mL, 5.6 mmol) were stirred in THF (10 mL) at room temperature for 2 d. The crude product was passed thorough a plug of silica gel (hexane-ethyl acetate 1:1) to afford a yellow solid. The solid was recrystallized from ethyl acetate to afford the desired compound (227 mg, 61%). FTIR (KBr) 1700, 1512, 1384, 1123, 828, 623 cm⁻¹. ¹H NMR (CDCl₃) δ 7.54 (dt, J=8.5, 1.8 Hz, 4H), 7.43 (dt, J=8.3, 1.7 Hz, 4H), 7.38 (dt, J=8.5, 1.8 Hz, 4H), 7.11 (dt, J=8.3, 1.7 Hz, 4H), 2.92 (s, 4H), 2.42 (s, 6H). ¹³C NMR (CDCl₃) δ 193.5, 142.1, 134.2, 132.2, 131.7, 128.7, 127.9, 124.7, 120.5, 91.2, 88.4, 37.6, 30.3. HRMS calcd for C₃₄H₂₆O₂S₂: 530.1374. Found: 530.1366.

64. See the general procedure for the Pd/Cu coupling reaction. The compounds used were 1,4-diethynylbenzene (1.26 g, 10.0 mmol), 1-iodo-4-trimethylsilylbenzene (6.09 g, 22.0 mmol), di(benzylidineacetone)palladium(0) (0.57 g, 1.0 mmol), triphenylphosphine (0.53 g, 2.0 mmol), copper(I) iodide (0.38 g, 2.0 mmol), THF (40 mL), and diisopropylethylamine (13.9 mL, 80.0 mmol). The mixture was stirred at room temperature for 30 h. After workup, the residue was dissolved in CH₂Cl₂ and filtered through a silica gel column [hexane/CH₂Cl₂ (2/1)]. Removal of the solvent in vacuo followed by crystallization from hexane gave a pale yellow solid (2.86 g). The mother liquor was purified by flash chromatography to give another pale yellow solid (0.66 g). A total of 3.52 g (83%) of desired product was obtained. Mp 214-220° C. FTIR (KBr) 3067, 3015, 2954, 2892, 1595, 1513, 1385, 1308, 1246, 1103, 846, 821, 754, 718, 682 cm⁻¹. ¹H NMR (300 MHz, CDCl₃) δ 7.49 (s, 12H), 0.26 (s, 18H). ¹³C NMR (75 MHz, CDCl₃) δ 141.36, 133.31, 131.61, 130.74, 123.36, 123.18, 91.51, 89.59, −1.17. HRMS calcd for C₂₈H₃₀Si₂: 422.1886. Found: 422.1878.

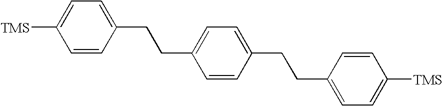

1,4-Bis(2-(4′-trimethylsilylphenyl)ethyl)benzene. A mixture of 64 (1.27 g, 3.00 mmol) in ethanol (100 mL) and 37% hydrochloric acid (10 drops) was hydrogenated over Pd on carbon (0.2 g, 10% of Pd on carbon) at 60 psi for 21 h. The mixture was filtered and the residue was washed with ethyl acetate. Removal of solvent in vacuo gave desired compound as a white solid (1.26 g, 97%). Mp 168-173° C. FTIR (KBr) 3067, 3015, 2954, 2923, 2851, 1600, 1513, 1451, 1395, 1246, 1108, 831, 754, 718, 692, 651 cm⁻¹. ¹H NMR (300 MHz, CDCl₃) δ 7.44 (d, J=7.9 Hz, 4H), 7.20 (d, J=7.9 Hz, 4H), 7.14 (s, 4H), 2.89 (s, 8H), 0.29 (s, 18H). ¹³C NMR (75 MHz, CDCl₃) δ 142.66, 139.52, 137.61, 133.52, 128.45, 127.96, 38.07, 37.50, −0.96. HRMS calcd for C₂₈H₃₈Si₂: 430.2512. Found: 430.2497.

1,4-Bis(2-(4′-iodophenyl)ethyl)benzene (65). To a suspension of 1,4-bis(2-(4′-trimethylsilylphenyl)ethyl)benzene (1.13 g, 2.62 mmol) in carbon tetrachloride (60 mL) was added dropwise iodine monochloride (0.37 mL, 7.3 mmol). The mixture was stirred for 80 min and then decolorized with aqueous sodium thiosulfate. The mixture was extracted with methylene chloride (2×). The extracts were dried over magnesium sulfate. Removal of solvent in vacuo gave a white solid. The solid was re-dissolved in methylene chloride and passed through a short silica gel column to afford desired compound as a white solid (1.39 g, 98%). Mp 147-160° C. FTIR (KBr) 3026, 2944, 2923, 2851, 1513, 1482, 1451, 1400, 1385, 1200, 1139, 1087, 1062, 1005, 815, 790, 759, 703, 610 cm⁻¹. ¹H NMR (300 MHz, CDCl₃) δ 7.56 (d, J=8.2 Hz, 4H), 7.03 (s, 4H), 6.88 (d, J=8.2 Hz, 4H), 2.83 (s, 8H). ¹³C NMR (75 MHz, CDCl₃) δ 141.39, 138.94, 137.35, 130.68, 128.50, 91.04, 37.41, 37.26. HRMS calcd for C₂₂H₂₀I₂: 537.9655. Found: 537.9634.

66. See the general procedure for the Pd/Cu coupling reaction. The compounds used were 65 (0.463 g, 0.860 mmol), 9^{[16]} (0.379 g, 2.15 mmol), di(benzylidineacetone)palladium(0) (0.049 g, 0.086 mmol), copper(I) iodide (0.033 g, 0.17 mmol), triphenylphosphine (0.090 g, 0.34 mmol), THF (15 mL), and diisopropylethylamine (0.91 mL, 5.2 mmol) for 24 h at room temperature. Flash chromatography (silica gel, CH₂Cl₂/hexane 2/1) afforded desired compound as a white solid (0.41 g, 75%). Mp 182° C. (decompose). FTIR (KBr) 2913, 2851, 1703, 1513, 1385, 1129, 1092, 1015, 949, 831, 821 cm⁻¹. ¹H NMR (300 MHz, CDCl₃) δ 7.52 (d, J=8.2 Hz, 4H), 7.43 (d, J=8.1 Hz, 4H), 7.37 (d, J=8.3 Hz, 4H), 7.13 (d, J=8.2 Hz, 4H), 7.05 (s, 4H), 2.89 (br s, 8H), 2.42 (s, 6H). ¹³C NMR (100 MHz, CDCl₃) δ 193.28, 142.40, 138.83, 134.07, 131.99, 131.52, 128.51, 128.35, 127.69, 124.61, 120.24, 91.20, 88.16, 37.93, 37.25, 30.34. HRMS calcd for C₄₂H₃₄O₂S₂: 634.2000. Found: 634.1990.

67. See the general procedure for the Pd/Cu coupling reaction. A solution of bis(dibenzylidineacetone)palladium(0) (0.0770 g, 0.135 mmol) and triplhenylphosphine (0.14 g, 0.54 mmol) in THF (5 mL) was added to a solution of 65 (0.724 g, 1.35 mmol), phenylacetylene (0.138 g, 1.35 mmol) and copper(I) iodide (0.050 g, 0.27 mmol) in THF (10 mL). The mixture was stirred for 19 h at room temperature. A solution of 9^{[16]} (0.44 g, 2.5 mmol), bis(dibenzylidineacetone)palladium(0) (0.015 g, 0.027 mmol) and triphenylphosphine (0.028 g, 0.11 mmol) in THF (5 mL) was added. The mixture was stirred for 28 h at room temperature and then poured into water. The mixture was extracted with methylene chloride (2×). The filtrate was dried over magnesium sulfate. Removal of solvent followed by flash chromatography (silica gel, CH₂Cl₂/hexane 1/1) and recrystallization from cyclohexane/CH₂Cl₂ afforded desired compound as a white solid (0.266 g, 35%). Mp 180-183° C. FTIR (KBr) 2915, 2850, 2371, 2213, 1707, 1591, 1508, 1387, 11.13, 1.011, 946, 830 cm⁻¹. ¹H NMR (300 MHz, CDCl₃) δ 7.52 (d, J=8.5 Hz, 2H), 7.51 (dd, J=7.8, 2.0 Hz, 2H), 7.43 (d, J=8.1 Hz, 4H), 7.38-7.30 (m, 3H), 7.13 (d, J=8.3 Hz, 2H), 7.12 (d, J=8.2 Hz, 2H), 7.05 (s, 4H), 2.89 (br s, 8H), 2.42 (s, 3H). ¹³C NMR (100 MHz, CDCl₃) δ 193.12, 142.28, 141.92, 138.74, 138.68, 133.94, 131.87, 131.39, 131.31, 128.38, 128.33, 128.22, 128.07, 127.87, 127.57, 124.49, 123.19, 120.49, 120.12, 91.09, 89.34, 88.77, 88.04, 37.79, 37.12, 30.20. HRMS calcd for C₄₀H₃₂OS: 560.2174. Found: 560.2157.

2-Bromo-4-nitro-5-(phenylethynyl)acetanilide (69). See the general procedure for the Pd/Cu-catalyzed coupling reaction. The compounds used were 2,5-dibromo-4-nitroacetanilide (68)^{[26]} (3.0 g, 8.88 mmol), phenylacetylene (0.98 mL, 8.88 mmol), copper(I) iodide (0.17 g, 0.89 mmol), bis(triphenylphosphine)palladium(II) chloride (0.25 g, 0.44 mmol), triphenylphosphine (0.47 g, 1.78 mmol), diisopropylethylamine (6.18 mL, 35.52 mmol), and THF (25 mL) at room temperature for 1 d then 50° C. for 12 h. The resultant mixture was subjected to an aqueous workup as described above. The desired material was purified by gravity liquid chromatography using silica gel as the stationary phase and methylene chloride as the eluent. R_{f} (product)=0.60. The reaction afforded 1.79 g (56% yield) of the desired product. IR (KBr) 3261.5, 3097.4, 2215.4, 1671.8, 1553.8, 1533.3, 1502.6, 1379.5, 1333.3, 1261.5, 1092.3, 1020.5, 892.3, 851.3, 753.8, 687.2, 651.3 cm⁻¹. ¹H NMR (400 MHz, CDCl₃) δ 8.84 (s, 1H), 8.39 (s, 1H), 7.80 (br s, 1H), 7.66-7.60 (m, 2H), 7.43-7.36 (m, 3H), 2.32 (s, 3H). ¹³C NMR (400 MHz, CDCl₃) δ 168.30, 139.81, 132.20, 129.49, 129.03, 128.49, 124.87, 122.21, 119.88, 117.49, 111.00, 98.64, 84.81, 25.33. HRMS calcd C₁₆H₁₁N₂O₃Br: 357.9953. Found: 357.9948.

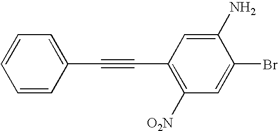

2-Bromo-4-nitro-5-(phenylethynyl)aniline. To a 100 mL round bottom flask equipped with a magnetic stirbar, 69 (0.33 g, 0.92 mmol), potassium carbonate (0.64 g, 4.6 mmol), methanol (15 mL), and methylene chloride (15 mL) were added. The reaction was allowed to stir at room temperature for 1 h. The reaction mixture was quenched with water and extracted with methylene chloride (3×). The organic layers were combined and dried over magnesium sulfate. Solvents were removed in vacuo. No further purification needed. The reaction afforded 0.29 g (100% yield) of the titled compound as a yellow solid. IR (KBr) 3476.9, 3374.4, 3159.0, 1656.4, 1615.4, 1559.0, 1379.5, 1307.7, 1138.5, 1102.6, 892.3, 748.7, 687.2 cm⁻¹. ¹H NMR (400 MHz, CDCl₃) δ 8.46 (s, 1H), 7.74-7.68 (m, 2H), 7.52-7.46 (m, 3H), 7.06 (s, 1. H), 4.93 (br s, 2H). ¹³C NMR (400 MHz, CDCl₃) δ 148.55, 139.41, 132.02, 130.45, 129.25, 128.46, 122.46, 120.17, 118.38, 106.86, 96.94, 85.46. HRMS calcd: 317.9828. Found: 317.9841.

2′-Amino-4,4′-diphenylethynyl-5′-nitro-1-thioacetylbenzene (70). See the general procedure for the Pd/Cu-catalyzed coupling reaction. 2-Bromo-4-nitro-5-(phenylethynyl)aniline (0.10 g, 0.30 mmol) was coupled to 9^{[16]} (0.10 g, 0.56 mmol) as described above using copper(I) iodide (0.01 g, 0.03 mmol), bis(triphenylphosphine)palladium(II) chloride (0.01 g, 0.02 mmol), triphenylphosphine (0.02 g, 0.06 mmol), diisopropylethylamine (0.24 mL, 1.40 mmol), and THF (10 mL) in an oven dried round screw capped pressure tube equipped with a stirbar. The reaction mixture was allowed to react at 80° C. for 3 d. The resultant mixture was subjected to an aqueous workup as described above. The desired material was purified by gravity liquid chromatography using silica gel as the stationary phase and 3:1 methylene chloride/hexanes as the eluent. R_{f} (product): 0.26. An additional hexanes wash gave yellow crystals of the desired compound, 0.80 g (67% yield). IR (KBr) 3374.4, 3138.5, 2205.1, 1384.6, 1312.8, 1246.2, 111.2.8, 825.6, 753.8, 692.3, 615.4 cm⁻¹. ¹H NMR (400 MHz, CDCl₃) δ 8.27 (s, 1H), 7.59 (m, 2H), 7.55 (d, J=8.0 Hz, 2H), 7.42 (d, J=8.2 Hz, 2H), 7.38 (m, 3H), 6.92 (s, 1H), 4.89 (br s, 2H), 2.45 (s, 3H). ¹³C NMR (400 MHz, CDCl₃) δ 193.03, 150.99, 139.53, 134.36, 132.12, 132.08, 130.24, 129.23, 129.19, 128.441, 123.21, 122.55, 121.06, 118.01, 106.88, 97.66, 96.53, 85.98, 84.89, 30.51. HRMS calcd C₂₄H₁₆N₂O₃S: 412.0882. Found: 412.0882.

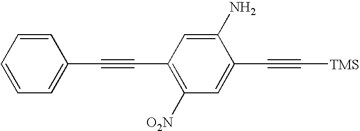

4-Nitro-3-phenylethynyl-6-trimethylsilylethynylaniline. See the general procedure for the Pd/Cu-catalyzed coupling reaction. The compounds used were 2-bromo-4-nitro-5-(phenylethynyl)aniline (0.26 g, 0.83 mmol), trimethylsilylacetylene (0.17 mL, 1.25 mmol), copper(I) iodide (0.02 g, 0.08 mmol), bis(triphenylphosphine)palladium(II) chloride (0.03 g, 0.04 mmol), diisopropylethylamine (0.58 mL, 3.32 mmol), and THF (10 mL) at 75° C. for 3 d. The desired material was purified by gravity liquid chromatography using silica gel as the stationary phase and a mixture of 3:1 methylene chloride/hexanes as the eluent. R_{f}=0.72. The reaction afforded 0.22 g (81% yield) of the desired compound. IR (KBr) 3465.06, 3350.39, 3214.34, 2958.03, 2360.06, 2341.17, 2146.27, 1625.20, 1539.10, 1507.32, 1305.69, 1247.56, 1199.99, 1091.12, 878.19, 843.71, 756.00, 663.28, 472.37 cm⁻¹. ¹H NMR (400 MHz, CDCl₃) δ 8.23 (s, 1H), 7.65-7.60 (m, 2H), 7.43-7.38 (m, 3H), 6.91 (s, 1H), 4.87 (br s, 2H), 0.31 (s, 9H). ¹³C NMR (400 MHz, CDCl₃) δ 151.80, 139.68, 132.47, 130.77, 129.62, 128.85, 122.95, 121.37, 118.22, 107.50, 103.95, 99.08, 97.83, 86.32, 0.30. HRMS calcd C₁₉H₁₈N₂O₂Si: 334.1138. Found: 334.1135. This material was deprotected using the standard potassium carbonated protocol described above, and then further coupled with 3 by the Pd/Cu protocol to afford 70 in 82% yield. The spectra were identical to that described above for 70.

2′-Acetamido-4,4′-diphenylethynyl-5′-nitro-1-thioacetylbenzene (71). See the general procedure for the Pd/Cu-catalyzed coupling reaction. 69 (0.10 g, 0.28 mmol) was coupled to 9^{[16]} (0.08 g, 0.45 mmol) as described above using copper(I) iodide (0.01 g, 0.02 mmol), bis(triphenylphosphine)palladium(II) chloride (0.01 g, 0.01 mmol), triphenylphosphine (0.01 g, 0.04 mmol), diisopropylethylamine (0.19 mL, 1.12 mmol), and THF (10 mL) in a screw capped pressure tube equipped with a magnetic stirbar. The reaction mixture was allowed to stir at 80° C. for 3 d. The resultant mixture was subjected to an aqueous workup as described above. The desired material was purified by gravity liquid chromatography using silica gel as the stationary phase and methylene chloride as the eluent. R_{f}=0.40. The compound was further purified by a hexanes wash to give 0.10 g (82% yield) of the desired compound as bright yellow crystals. IR (KBr) 3138.5, 2205.1, 1384.6, 1333.3, 1241.0, 1117.9, 953.8, 897.4, 825.6, 753.6, 687.2, 615.4 cm⁻¹. ¹H NMR (400 MHz, CDCl₃) δ 8.41 (s, 1H), 8.29 (s, 1H), 8.06 (br s, 1H), 7.62 (m, 2H), 7.57 (d, J=8.4 Hz, 2H), 7.46 (d, J=8.5 Hz, 2H), 7.38 (m, 3H), 2.64 (s, 3H), 2.32 (s, 3H). ¹³C NMR (400 MHz, CDCl₃) δ 192.77, 168.29, 143.82, 142.02, 134.51, 132.23, 132.17, 130.17, 129.47, 128.61, 128.46, 123.57, 122.27, 122.21, 120.70, 111.15, 99.43, 98.68, 85.55, 83.51, 30.58, 25.33. HRMS calcd C₂₆H₁₈N₂O₄S: 454.0987. Found: 454.0987.

4-Iodophenyl methyl sulfide. 1,4-Diiodobenzene (6.60 g, 20.0 mmol) was added to an oven-dried 2-neck round bottom flask equipped with a stir bar. Air was removed and nitrogen backfilled (3×). THF (2.5 mL) was then added under N₂ and the apparatus was cooled in a dry ice/acetone bath to −78° C. tert-BuLi (23.4 mL of 1.7 M solution) was then added drop wise over a period of 45 min. The mixture was allowed to stir for 30 min and sulfur (0.769 g, 24 mmol) was then added to the flask. This mixture was allowed to stir for 10 min and subsequently heated to 0° C. and stirred for 10 min. The mixture was then cooled to −78° C. and methyl iodide (1.87 mL, 30 mmol) added. The reaction was allowed to warm to room temperature overnight while maintaining stirring. The reaction was then quenched with water and washed with brine and methylene chloride (3×). Gravity column chromatography (silica gel with hexanes as eluent) afforded the desired product (3.14 g, 63% yield). IR (KBr) 3070.5, 2910.5, 2851.5, 1883.0, 1469.0, 1426.3, 1381.1, 1092.3, 1000.2, 801.5, 482.2 cm⁻¹. ¹H NMR (400 MHz, CDCl₃) δ 7.60 (dt, J=8.6, 2.0 Hz, 2H), 7.01 (dt, J=8.6, 2.0 Hz, 2H), 2.48 (s, 3H). ¹³C NMR (100 MHz, CDCl₃) δ 139, 138.06, 128.68, 90, 16.10. HRMS calc'd for C₇,H₇,S,I: 249.9313. Found: 249.9307.

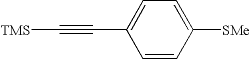

4-Thiomethyl-1-(trimethylsilylethynyl)benzene. See the general procedure for the Pd/Cu-catalyzed coupling reaction. The compounds used were 4-iodophenyl methyl sulfide (2.0 g, 8.0 mmol), bis(triphenylphosphine)palladium(II) chloride (0.281 g, 0.40 mmol), copper(I) iodide (0.15 g, 0.80 mmol), THF (30 mL), diisopropylethylamine (5.57 mL, 32.0 mmol), and trimethylsilylacetylene (1.47 mL, 10.4 mmol) at 50° C. for 10 h. Flash column chromatography (hexanes as eluent) afforded the desired product (1.74 g, 99% yield). ¹H NMR (400 MHz, CDCl₃) δ 7.39 (dt, J=8.6, 2.0 Hz, 2H), 7.17 (dt, J=8.6, 2.0 Hz, 2H), 2.50 (s, 3H), 0.27 (s, 9H). ¹³C NMR (100 MHz, CDCl₃) δ 139.99, 132.63, 126.05, 119.78, 105.27, 94.56, 15.72, 0.39. IR (KBr) 3740.6, 3645.4, 3070.5, 3026.7, 2956.4, 2920.0, 2157.7, 1898.8, 1590.8, 1488.9, 1438.7, 1320.2, 1250.8, 1092.2, 1014.6. HRMS calculated for C₁₂H₁₆SSi: 220.0742. Found: 220.0737.

1-Ethynyl-4-thiomethylbenzene (72). See the general procedure for the deprotection of a trimethylsilyl-protected alkyne. The compounds used were 4-thiomethyl-1-(trimethylsilylethynyl)benzene (0.29 g, 1.33 mmol), potassium carbonate (0.92 g, 6.63 mmol), methanol (20 mL), and methylene chloride (20 mL) for 2 h. Due to the instability of conjugated terminal alkynes, the material was immediately used in the next step without additional purification.

73. 2-Bromo-4-nitro-5-(phenylethynyl)aniline (317 mg, 1.00 mmol), bis(triphenylphosphine)palladiumdichloride (35 mg, 0.05 mmol), copper(I) iodide (19 mg, 0.1 mmol), diisopropylethylamine (0.70 mL, 4.0 mmol), 72 (178 mg, 1.2 mmol), and THF (25 mL) were coupled according to the general coupling procedure except that 72 was dissolved in THF and transferred via cannula into the reaction. The reaction mixture was heated at 75° C. overnight. The crude product was then separated via flash chromatography (1:1 CH₂Cl₂/hexanes) to afford 143 mg (37%) as a yellow solid. IR (KBr) 3474.1, 3366.0, 2360.1, 2204.9, 1616.3, 1541.0, 1517.0, 1473.0, 1286.3, 1248.4, 1148.4, 1090.1, 814.8, 754.1, 686.4 cm⁻¹. ¹H NMR (400 MHz, CDCl₃) δ 8.26 (s, 1H), 7.60-7.53 (m, 2H), 7.42 (d, J=8.4, 2H), 7.37-7.35 (m, 3H), 7.21 (d, J=8.5, 2H) 4.85 (br s, 1H). ¹³C NMR (100 MHz, CDCl₃) δ 151.3, 141.1, 132.8, 132.5, 132.3, 132.1, 130.5, 129.6, 129.0, 128.9, 126.2, 126.1, 123.0, 121.1, 118.5, 118.3, 107.9, 97.7, 15.6. HRMS Calc'd for C₂₃H₁₆N₂O₂S: 384.0933. Found: 384.0932.

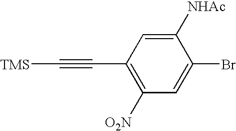

2-Bromo-4-nitro-5-(trimethylsilylethynyl)acetanilide. See the general procedure for the Pd/Cu-catalyzed coupling reaction. The compounds used were 68 (4.00 g, 11.84 mmol), trimethylsilylacetylene (1.30 mL, 11.8 mmol), copper(I) iodide (0.22 g, 1.18 mmol), bis(triphenylphosphine)palladium(II) chloride (0.41 g, 0.59 mmol), diisopropylethylamine (8.25 mL, 47.36 mmol), and THF (80 mL) at 70° C. for 2 d. The desired material was purified by gravity liquid chromatography using silica gel as the stationary phase and a mixture of 3:1 diethyl ether/hexanes as the eluent. R_{f} (product): 0.43. The reaction afforded 1.46 g (35% yield, 54% based on a recovered 1.44 g of starting material) of the desired product. IR (KBr) 3384.6, 3107.7, 3056.4, 2964.1, 2143.6, 1717.9, 1559.0, 1523.1, 1492.3, 1446.2, 1379.5, 1333.3, 1246.2, 1225.6, 1097.4, 846.2, 764.1, 712.8 cm⁻¹. ¹H NMR (400 MHz, CDCl₃) δ 8.84 (s, 1H), 8.29 (s, 1H), 7.75 (br s, 1H), 2.30 (s, 3H), 0.27 (s, 9H). ¹³C NMR (100 MHz, CDCl₃) δ 169.38, 145.60, 140.82, 129.90, 126.63, 120.52, 112.46, 106.70, 100.03, 26.45, 0.93. HRMS Calcd C₁₃H₁₅BrN₂O₃Si: 354.0035. Found: 354.0034.

2-(Ethynylphenyl)-4-nitro-5-(trimethylsilylethynyl)acetanilide (74). See the general procedure for the Pd/Cu-catalyzed coupling reaction. 2-Bromo-4-nitro-5-(trimethylsilylethynyl)acetanilide (1.20 g, 3.38 mmol) was coupled to phenylacetylene (0.56 mL, 5.07 mmol) as described above using copper(I) iodide (0.06 g, 0.34 mmol), bis(triphenylphosphine)palladium(II) chloride (0.12 g, 0.17 mmol), diisopropylethylamine (2.36 mL, 13.52 mmol), and THF (25 mL) at 75° C. for 3 d. The desired material was purified by gravity liquid chromatography using silica gel as the stationary phase and a mixture of 3:1 methylene chloride/hexanes as the eluent. Rr (product): 0.38. The reaction afforded 1.00 g (79% yield) of the desired product. IR (KBr) 3384.6, 3128.2, 2953.8, 2215.4, 2153.8, 1707.7, 1543.6, 1523.1, 1497.4, 1456.4, 1384.6, 1338.5, 1225.6, 1169.2, 1112.8, 1051.3, 846.2, 748.7, 687.2, 620.5 cm⁻¹. ¹H NMR (400 MHz, CDCl₃) δ 8.77 (s, 1H), 8.21 (d, J=0.03 Hz, 1H), 8.07 (br s, 1H), 7.57-7.52 (m, 2H), 7.47-7.39 (m, 3H), 2.30 (s, 3H), 0.29 (s, 9H). ¹³C NMR (100 MHz, CDCl₃) δ 169.35, 145.49, 142.99, 132.82, 131.01, 129.94, 129.34, 125.26, 122.25, 121.06, 112.98, 107.23, 100.90, 100.76, 83.10, 26.45, 0.96. HRMS Calcd C₂₁H₂₀N₂O₃Si: 376.1243. Found: 376.1235.

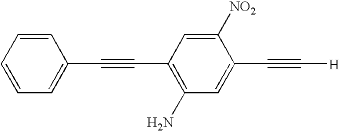

5-Ethynyl-2-(ethynylphenyl)₄-nitroaniline. See the general procedure for the deprotection of trimethylsilyl-protected alkynes. 74 (0.10 g, 0.27 mmol) was deprotected to the terminal alkyne and the free amine using the procedure described above using potassium carbonate (0.19 g, 1.35 mmol), methanol (15 mL), and methylene chloride (15 mL). The reaction mixture was allowed to stir at room temperature for 2 h. The resultant mixture was subjected to an aqueous workup as described above. Due to the instability of conjugated terminal alkynes, the material was immediately used in the next step without additional purification or identification.

5′-Amino-4,4′-diethynylphenyl-2′-nitro-1-thioacetylbenzene (75). See the general procedure for the Pd/Cu-catalyzed coupling reaction. The compounds used were 5-ethynyl-2-(ethynylphenyl)-4-nitroaniline (0.08 g, 0.27 mmol), 3 (0.09 g, 0.32 mmol), copper(I) iodide (0.005 g, 0.01 mmol), bis(triphenylphosphine)palladium(II) chloride (0.01 g, 0.01 mmol), diisopropylethylamine (0.20 mL, 1.08 mmol), and THF (20 mL) at 70° C. for 12 h. The desired material was purified by gravity liquid chromatography using silica gel as the stationary phase and a mixture of 3:1 methylene chloride/hexanes as the eluent. Rᵣ=0.32. The reaction afforded 0.09 g (82% yield over 3 steps) of the desired product as a yellow solid which turned yellowish-green upon standing. IR (KBr) 3466.7, 3364.1, 2205.1, 1702.6, 1615.4, 1548.7, 1507.7, 1476.9, 1307.7, 1246.2, 1117.9, 948.7, 912.8, 871.8, 820.5, 748.7, 682.1 cm⁻¹. ¹H NMR (400 MHz, CDCl₃) δ 8.28 (s, 1H), 7.61 (½ABq, J=8.4 Hz, 2H), 7.55 (m, 2 H), 7.41 (½ABq, J=8.4 Hz, 2H), 7.41-7.35 (m, 3H), 6.90 (s, 1H), 4.93 (br s, 2H), 2.44 (s, 3H). ¹³C NMR (100 MHz, CDCl₃) δ 193.09, 150.93, 139.33, 134.98, 134.13, 132.46, 131.55, 130.06, 129.07, 128.49, 123.69, 121.94, 120.25, 117.91, 107.50, 97.51, 96.26, 87.50, 83.16, 30.45. HRMS Calcd C₂₄H₁₆N₂O₃S: 412.0882. Found: 412.0883.

1-Bromo-3-nitro-4-(trimethylsilylethynyl)benzene. See the general procedure for the Pd/Cu-catalyzed coupling reaction. The compounds used were 2,5-dibromonitrobenzene (1.37 g, 4.89 mmol), bis(triphenylphosphine)palladium(I) chloride (0.17 g, 0.25 mmol), copper(I) iodide (0.09 g, 0.49 mmol), THF (30 mL), Hünig's base (3.41 mL, 19.56 mmol), and trimethylsilylacetylene (0.69 mL, 4.9 mmol) at 70° C. for 18 h. Due to difficulty in separation of products, full characterization was not achieved and the resulting mixture was carried on to the next reaction step. ¹H NMR (300 MHz, CDCl₃) δ 8.14 (d, J=2.0 Hz, 1H), 7.66 (dd, J=8.3, 2.0 Hz, 1H), 7.49 (d, J=8.3 Hz, 1H), 0.26 (s, 9H).

2-Ethynyl-5-ethynylphenyl-1-nitrobenzene (77). 2,5-Dibromonitrobenzene (76) (4.0 g, 14.24 mmol), bis(triphenylphosphine)palladium(II) dichloride (0.300 g, 0.427 mmol), copper(I) iodide (0.163 g, 0.854 mmol), THF (30 mL), diisopropylethylamine (9.9 mL, 57.0 mmol), and trimethylsilylacetylene (2.21 mL, 15.66 mmol) were used at room temperature for 10 h following the general procedure for couplings. Flash column chromatography (silica gel using 2:1 hexanes/dichloromethane as eluent) afforded a mixture of products that was taken onto the next step. The product mixture (3.09 g), bis(triphenylphosphine)palladium(II) dichloride (0.217 g, 0.31 mmol), copper(I) iodide (0.118 g, 0.62 mmol), THF (30 mL), diisopropylethylamine (7.2 mL, 41.44 mmol), and phenylacetylene (1.7 mL, 15.54 mmol) were used following the general procedure for couplings at 50° C. for 15 h. Flash column chromatography (silica gel using 1:1 hexanes/dichloromethane as eluent) afforded a mixture of products that was taken onto the next step. The product mixture (1.95 g), potassium carbonate (4.2 g, 30.4 mmol), methanol (50 mL), and dichloromethane (50 mL) were used following the general procedure for deprotection. Flash column chromatography (silica gel using 1:1 hexanes/dichloromethane as eluent) afforded the desired product as an orange solid (1.23 g, 37% yield for three steps). IR (KBr) 3267.2, 3250.1, 3079.6, 2208.4, 2102.6, 1541.6, 1522.5, 1496.0, 1347.1, 1275.2, 900.9, 840.5, 825.0, 759.0, 688.0, 528.8 cm⁻¹. ¹H NMR (400 MHz, CDCl₃) δ 8.16 (d, J=1.5 Hz, 1H), 7.67 (dd, J=8.1, 1.5 Hz, 1H), 7.64 (d, J=7.8 Hz, 1H), 7.53 (m, 2H), 7.37 (m, 3H), 3.58 (s, 1H). ¹³C NMR (100 MHz, CDCl₃) δ 150.62, 135.82, 135.65, 132.24, 129.72, 128.97, 127.80, 125.51, 122.33, 117.01, 94.35, 87.04, 86.97, 78.82. HRMS calc'd for C₁₆,H₉,N,O₂: 247.0633. Found: 247.0632.

4,4′-Di(ethynylphenyl)-2′-nitrol-thioacetylbenzene (78). See the standard procedure for Pd/Cu couplings. The compounds used were 77 (0.500 g, 2.02 mmol), 3 (0.675 g, 2.43 mmol), bis(dibenzylideneacetone)palladium(0) (0.232 g, 0.404 mmol), copper(I) iodide (0.077 g, 0.404 mmol), triphenylphosphine (0.212 g, 0.808 mmol), THY (10 mL), and diisopropylethylamine (0.7 mL, 4.04 mmol) at 50° C. oil bath for 2 d. Column chromatography (silica gel using 2:1 dichloromethane/hexanes as eluent) afforded the desired product as an orange solid (0.381 g, 47% yield). IR (KBr) 3100, 2924, 2213.1, 1697.1, 1537.3, 1346.9, 1131.9, 831.9, 751.4, 684.9, 623.0. ¹H NMR (400 MHz, CDCl₃) δ 8.22 (dd, J=1.1, 0.3 Hz, 1H), 7.70 (dd, J=8.1, 1.5 Hz, 1H), 7.67 (d, J=8.0 Hz, 1H), 7.61 (dt, J 8.5, 1.9 Hz, 2H), 7.54 (m, 2H), 7.42 (dt, J=8.5, 1.8 Hz, 2H), 7.37 (m, 3H), 2.43 (s, 3H). ¹³C NMR (75 MHz, CDCl₃) δ 193.10, 149.5, 135.30, 134.55, 134.27, 132.57, 131.84, 129.56, 129.26, 128.56, 127.65, 124.47, 123.40, 122.05, 117.5, 97.84, 93.82, 86.86, 86.31, 30.36. HRMS calculated for C₂₄,H₁₅,N,O₃, S: 397.0076. Found: 397.0773.

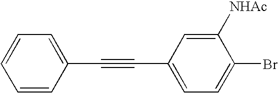

2-Bromo-5-(ethynylphenyl)acetanilide. See the general procedure for the Pd/Cu-catalyzed coupling reaction. 2,5-Dibromoacetanilide (6.00 g, 17.76 mmol) was coupled to phenylacetylene (1.95 mL, 17.76 mmol) using copper(I) iodide (0.34 g, 1.78 mmol), bis(triphenylphosphine)palladium(II) chloride (0.62 g, 0.89 mmol), diisopropylethylamine (12.37 mL, 71.04 mmol), and THF (75 mL) at 75° C. for 2.5 d. The desired material was purified by gravity liquid chromatography using silica gel as the stationary phase and methylene chloride as the eluent. R_{f}=0.38. An additional purification was performed using gravity liquid chromatography using silica gel as the stationary phase and a mixture of 3:1 hexanes/ethyl acetate as the eluent. R_{f}=0.50. The reaction afforded 1.79 g (32% yield, 42% based on a recovered 0.69 g of starting material) of the desired compound as a white solid. IR (KBr) 3282.1, 3159.0, 1661.5, 1559.0, 1507.7, 1461.5, 1405.1, 1379.5, 1271.8, 1107.7, 1066.7, 1015.4, 964.1, 892.3, 861.5, 820.5, 748.7, 682.1, 610.3 cm⁻¹. ¹H NMR (400 MHz, CDCl₃) δ 8.66 (br s, 1H), 7.92 (br s, 1H), 7.55-7.49 (m, 2H), 7.41-7.37 (m, 3H), 7.32 (½ABq, J=8.3 Hz, 1H), 7.20 (½ABq d, J=6.4, J=1.8 Hz, 1H), 2.25 (s, 3H). ¹³C NMR (100 MHz, CDCl₃) δ 169.15, 140.81, 133.62, 132.61, 130.32, 129.80, 127.70, 124.93, 123.33, 123.15, 111.69, 98.63, 84.65, 26.32. HRMS Calcd C₁₆H₁₂BrNO: 313.0102. Found: 313.0107.

3-Ethynylphenyl-6-(trimethylsilylethynyl)acetanilide (80). See the general procedure for the Pd/Cu-catalyzed coupling reaction. 2-Bromo-5-(ethynylphenyl)acetanilide (0.91 g, 2.90 mmol) was coupled to trimethylsilylacetylene (0.47 mL, 4.35 mmol) using copper(I) iodide (0.06 g, 0.29 mmol), bis(triphenylphosphine)palladium(II) chloride (0.11 g, 0.15 mmol), diisopropylethylamine (2.02 mL, 11.60 mmol), and THF (20 mL) at 70° C. for 3 d. The desired material was purified by gravity liquid chromatography using silica gel as the stationary phase and methylene chloride as the eluent. R_{f}=0.33. The reaction afforded 0.81 g (84% yield) of the desired compound as a yellow foam after drying in a vacuum atmosphere. IR (KBr) 3394.9, 3138.5, 2953.8, 2143.6, 1702.6, 1553.85, 1553.8, 1523.1, 1410.3, 1384.6, 1271.8, 1246.2, 1169.2, 1112.8, 1015.4, 846.2, 753.8, 687.2, 620.5 cm⁻¹. ¹H NMR (400 MHz, CDCl₃) δ 8.53 (br s, 1H), 7.91 (br s, 1H), 7.55-7.49 (m, 2H), 7.43-7.36 (m, 4H), 7.15 (dd, J=6.6, 1.5 Hz, 1H), 2.24 (s, 3H), 0.25 (s, 9H). ¹³C NMR (100 MHz, CDCl₃) δ 169.09, 139.72, 132.62, 132.49, 130.27, 129.79, 128.06, 125.58, 123.63, 123.24, 112.98, 105.68, 99.09, 97.67, 85.26, 26.33, 1.28. HRMS Calcd C₂₁H₂₁BrNOSi: 331.1392. Found: 331.1391.

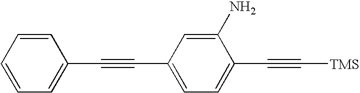

3-Ethynylphenyl-6-(trimethylsilylethynyl)aniline. A 100 mL round bottom flask equipped with a magnetic stirbar was charged with 3-ethynylphenyl-6-(trimethylsilylethynyl)acetanilide (0.25 g, 0.75 mmol), hydrochloric acid (15 mL, 1.5 M), and THF (15 mL). The reaction mixture was heated to reflux for 2.5 h. The reaction progress was monitored by TLC. The reaction was quenched and extracted with water (3×) and diluted with methylene chloride. The organic layers were combined and dried over magnesium sulfate. Volatiles were removed in vacuo. Crude ¹ H NMR and TLC showed two inseparable products with similar amine and aromatic resonances. Therefore, the crude reaction mixture was reacted further without purification.

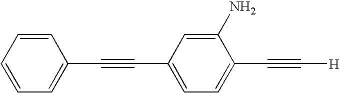

2-Ethynyl-5-(ethynylphenyl)aniline. See the general procedure for the deprotection of trimethylsilyl-protected alkynes. The compounds used were 3-ethynylphenyl-6-(trimethylsilylethynyl)aniline (0.22 g, 0.75 mmol) potassium carbonate (0.52 g, 3.75 mmol), methanol (15 mL), and methylene chloride (15 mL) for 2 h. Due to the instability of conjugated terminal alkynes, the material was immediately used in the next step without additional purification or identification.

2′-Amino-4,4′-di(phenylethynyl)-1-thioacetylbenzene (81). See the general procedure for the Pd/Cu-catalyzed coupling reaction. The compounds used were 2-ethynyl-5-(ethynylphenyl)aniline (0.16 g, 0.75 mmol), 3 (0.25 g, 0.90 mmol), copper(I) iodide (0.02 g, 0.08 mmol), bis(triphenylphosphine)palladium(II) chloride (0.03 g, 0.04 mmol), diisopropylethylamine (0.53 mL, 3.00 mmol), and THF (15 mL) at 45° C. for 12 h. The desired material was purified by gravity liquid chromatography using silica gel as the stationary phase and a mixture of 1:3 diethyl ether/hexanes as the eluent. R_{f} (product): 0.40. The reaction afforded 0.28 g (43% yield, over three steps) of the desired compound as a bright yellow solid. IR (KBr) 3138.5, 2205.1, 1702.6, 1610.3, 1384.6, 1117.9, 943.6, 825.6, 753.8, 692.3, 615.4 cm⁻¹. ¹H NMR (400 MHz, CDCl₃) δ 7.56-7.50 (m, 4H), 7.42-7.31 (m, 6H), 6.92-6.87 (m, 2H), 4.32 (br s, 2H), 4.44 (s, 3H). ¹³C NMR (100 MHz, CDCl₃) δ 193.66, 148.20, 134.72, 132.40, 131.75, 128.89, 128.86, 128.84, 128383, 124.60, 124.10, 123.32, 121.49, 117.14, 108.58, 96.57, 91.32, 89.72, 85.78, 30.48. HRMS Calcd C₂₄H₁₇NOS: 367.1031. Found: 367.1032.

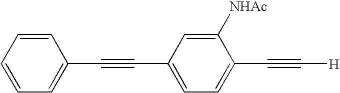

2-Ethynyl-5-(ethynylphenyl)acetanilide. See the general procedure for the deprotection of trimethylsilyl-protected alkynes. The compounds used were 80 (0.20 g, 0.60 mmol) potassium carbonate (0.25 g, 1.80 mmol), methanol (15 mL), and methylene chloride (15 mL) for 2 h. Due to the instability of conjugated terminal alkynes, the material was immediately used in the next step without additional purification or identification.

2′-Acetamido-4,4′-di(phenylethynyl)-1-thioacetylbenzene (82). See the general procedure for the Pd/Cu-catalyzed coupling reaction. The compounds used were 2-ethynyl-5-(ethynylphenyl)acetanilide (0.16 g, 0.60 mmol), 3 (0.20 g, 0.72 mmol) copper(I) iodide (0.01 g, 0.06 mmol), bis(triphenylphosphine)palladium(II) chloride (0.02 g, 0.03 mmol), diisopropylethylamine (0.42 mL, 2.40 mmol), and THF (20 mL) at 70° C. for 12 h. The desired material was purified by gravity liquid chromatography using silica gel as the stationary phase and a mixture of 3:1 ethyl acetate/hexanes as the eluent. R_{f} (product): 0.35. The reaction afforded 0.12 g (50% yield, two steps) of the desired compound as an off-white solid. IR (KBr) 3138.5, 2933.3, 1702.6, 1656.4, 1543.6, 1379.5, 1261.5, 1112.8, 1010.3, 948.7, 882.1, 820.5, 748.7, 682.1, 610.3 cm⁻¹. ¹H NMR (400 MHz, CDCl₃) δ 8.62 (br s, 1H), 7.96 (br s, 1H), 7.58-7.52 (m, 4H), 7.46 (½ABq, J=7.8 Hz, 1H), 7.42-7.37 (m, 5H), 7.23 (½ABq d, J=8.1, 1.4 Hz, 1H), 2.43 (s, 3H), 2.27 (s, 3H). ¹³C NMR (100 MHz, CDCl₃) δ 193.62, 168.51, 139.39, 134.70, 132.48, 132.02, 131.88, 129.52, 129.09, 129.00, 126.87, 124.41, 124.25, 122.45, 122.27, 112.45, 98.38, 91.06, 90.61, 84.24, 30.48, 25.10. HRMS Calcd C₂₆H₁₉NO₂S: 410.1215. Found: 410.1212.

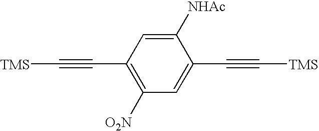

2,5-Bis(trimethylsilylethynyl)₄-nitroacetanilide. See the general procedure for the Pd/Cu-catalyzed coupling reaction. The compounds used were 68^{[26]} (0.60 g, 1.78 mmol), trimethylsilylacetylene (0.78 mL, 7.12 mmol), copper(I) iodide (0.07 g, 0.37 mmol), bis(triphenylphosphine)palladium(II) chloride (0.13 g, 0.18 mmol), diisopropylethylamine (2.48 mL, 14.24 mmol), and THF (20 mL) at 75° C. for 3 d. The desired material was purified by gravity liquid chromatography using silica gel as the stationary phase and a mixture of 3:1 diethyl ether/hexanes as the eluent. Rr (product): 0.80. The reaction afforded 0.63 g (95% yield; 0.26 g of material as the product with the deprotected amino moiety instead of the acetamide was also obtained) of the desired product. IR (KBr) 3374.4, 3117.9, 2964.1, 2143.6, 1723.1, 1610.3, 1543.6, 1502.6, 1456.4, 1400.0, 1379.5, 1333.3, 1251.3, 1220.5, 1112.8, 882.1, 846.2, 759.0, 620.5 cm⁻¹. ¹H NMR (400 MHz, CDCl₃) δ 8.72 (s, 1H), 8.11 (s, 1H), 8.07 (br s, 1. H), 2.25 (s, 3H), 0.31 (s, 9H), 0.26 (s, 9H). ¹³C NMR (100 MHz, CDCl₃) δ169.27, 145.23, 143.53, 129.21, 124.94, 121.27, 112.68, 107.86, 107.26, 1.00.70, 98.57, 26.25, 1.08, 0.94. HRMS Calcd C₁₈H₂₄N₂O₃Si₂: 372.1325. Found: 372.1332.

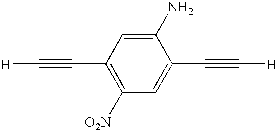

2,5-Di(ethynyl)-4-nitroaniline. See the general procedure for the deprotection of trimethylsilyl-protected alkynes. The compounds used were 2,5-bis(trimethylsilylethynyl)-4-nitroacetanilide (0.60 g, 1.61 mmol), potassium carbonate (2.22 g, 16.10 mmol), methanol (40 mL), and methylene chloride (40 mL) for 2 h. Due to the instability of conjugated terminal alkynes, the material was immediately used in the next step without additional purification or identification.

2,5-Diphenylethynyl-4′,4″-dithioacetyl-4-nitroaniline (83). See the general procedure for the Pd/Cu-catalyzed coupling reaction. The compounds used were 2,5-di(ethynyl)-4-nitroaniline (0.30 g, 1.61 mmol), 3 (1.09 g, 3.86 mmol) copper(I) iodide (0.06 g, 0.32 mmol), bis(triphenylphosphine)palladium(II) chloride (0.11 g, 0.16 mmol), diisopropylethylamine (2.25 mL, 12.88 mmol), and THF (40 mL) at 50° C. for 2 d. The desired material was purified by gravity liquid chromatography using silica gel as the stationary phase and a mixture of 1:1 ethyl acetate/hexanes as the eluent. R_{f}=0.52. The reaction afforded 0.47 g (57% over three steps) of the desired compound as a bright yellow solid. IR (KBr) 3476.9, 3364.1, 3117.9, 1687.2, 1625.6, 1543.6, 1507.7, 1476.9, 1384.6, 1307.7, 1246.2, 1117.9, 1010.3, 948.7, 825.6, 615.4 cm⁻¹. ¹H NMR (400 MHz, CDCl₃) δ 8.28 (s, 1H), 7.62 (½ABq, J=8.2 Hz, 2H), 7.56 (½ABq, J=8.4 Hz, 2H), 7.44 (½ABq, J=4.4 Hz, 2H), 7.42 (½ABq, J=4.2 Hz, 2H), 6.92 (s, 1H), 4.90 (br s, 2H), 2.45 (s, 3H), 2.44 (s, 3H). ¹³C NMR (100 MHz, CDCl₃) δ 193.00, 192.91, 150.99, 134.26, 134.25, 134.25, 134.13, 134.11, 132.45, 132.04, 130.16, 123.64, 123.09, 120.52, 118.01, 107.00, 96.59, 96.45, 87.44, 84.79, 30.44, 30.42. HRMS Calcd C₂₄H₁₇NOS: 487.0786. Found: 487.0792.

4-(Trimethylsilylethynyl)aniline. See the general procedure for the Pd/Cu cross couplings. The compounds used were 4-bromoaniline (6.88 g, 40 mmol), trimethylsilylacetylene (11.3 mL, 80 mmol), tetrakis(triphenylphosphine)palladium(0) (393 mg, 0.34 mmol), copper iodide (76 mg, 0.4 mmol) and diisopropylamine (40 mL) at 110-120° C. for 12 h. The mixture was concentrated and filtered through a plug of silica get using 1:1 ethyl acetate/hexane. The filtrate was concentrated and purified on a silica gel column (1:5 ethyl acetate/hexane). IR (KBr) 3469, 3374, 2958, 2156, 2144, 1624, 1508, 1294, 1249 cm⁻¹. ¹H NMR (300 MHz, CDCl₃) δ 7.26 (d, J=8.6 Hz, 2H), 6.57 (d, J=8.6 Hz, 2H), 0.22 (s, 9H).

4-Ethynylaniline. See the general procedure for the deprotection of trimethylsilyl alkynes. The compounds used were 4-(trimethylsilylethynyl)aniline (2.48 g, 13 mmol), potassium carbonate (11 g) and methanol (100 mL) for 12 h. Hexane was added to a highly concentrated ether solution to give fine crystals. The collected crystals were washed with hexane and dried in vacuo to afford 1.14 g (74%) of the title compound. ¹H NMR (400 MHz, CDCl₃) δ 7.28 (d, J=8.6 Hz, 2H), 6.58 (d, J=8.6 Hz, 2H), 3.72-3.88 (br, 2H), 2.94 (s, 1H). ¹³C NMR (100 MHz, CDCl₃) δ 147.0, 133.5, 114.6, 111.4, 84.4, 74.9.

4′-Ethynylformanilide (84). A solution of 4-ethynylaniline (0.87 g, 6.0 mmol) in ethyl formate (40 mL) was heated to reflux for 24 h. After removal of the solvents by a rotary evaporation, another portion of ethyl formate (40 mL) was added and the solution was heated to reflux for 24 h. The evaporated residue was chromatographed on silica gel (1:2 ethyl acetate/hexane) to afford 0.65 g (75%) of a slightly brown-white solid of the title compound. IR (KBr) 3292, 2107, 1686, 1672, 1601, 1536, 1407, 1314, 842, 668, 606 cm⁻¹. ¹H NMR (400 MHz, CDCl₃) δ 8.71 (d, J=11.3 Hz, a), 8.38 (d, J=1.5 Hz, b), 7.82-7.92 (br d, J=110 Hz, c), 7.48 (dt, J=14.5, 8.7 Hz, 3H), 7.2 (br, d), 7.02 (d, J=8.6 Hz, 1H), 3.07 (s, e), 3.04 (s,f) where (a+b=1H, c+d=1H, e+f=1H).

85. See the general procedure for the Pd/Cu-catalyzed coupling reaction. The compounds used were 2-bromo-4-nitro-5-(phenylethynyl)aniline (0.26 g, 0.83 mmol), 84 (0.15 g, 1.00 mmol), copper(I) iodide (0.02 g, 0.08 mmol), bis(triphenylphosphine)palladium(II) chloride (0.03 g, 0.04 mmol), diisopropylethylamine (0.58 mL, 3.32 mmol), and THF (25 mL) at 70° C. for 3 d. The desired material was purified by gravity liquid chromatography using silica gel as the stationary phase and a mixture of 1:1 ethyl acetate/hexanes as the eluent. R_{f}=0.09. An additional purification was performed using gravity liquid chromatography using silica gel as the stationary phase and a mixture of ethyl acetate as the eluent. R_{f}=0.63. The reaction afforded an impure product of 0.23 g. The crude reaction product was taken on to the next synthetic step.

2′-Amino-4,4′-diphenylethynyl-5′-nitrobenzeneisonitrile (86). To an oven dried 100 mL round bottom flask equipped with a stirbar and a West condenser was added 85 (0.04 g, 0.10 mmol), triphenylphosphine (0.09 g, 0.33 mmol), triethylamine (0.04 mL, 0.39 mmol), carbon tetrachloride (0.03 mL, 0.31 mmol), and methylene chloride (10 mL).^{[31]} The reaction was heated to 60° C. for 5 h. The reaction mixture was cooled and quenched with water and extracted with methylene chloride (3×). Organic layers were combined and dried over MgSO₄. The volatiles were removed in vacuo. The crude reaction mixture was purified by gravity liquid chromatography using silica gel as the stationary phase and ethyl acetate as the eluent. R_{f}=0.85. An additional purification was performed using gravity liquid chromatography using silica gel as the stationary phase and a mixture of 1:1 methylene chloride/hexanes as the eluent. R_{f} (product): 0.30. The reaction afforded 0.03 g (83% yield, two steps) of the desired material. IR (KBr) 3450.62, 3358.15, 2925.78, 2855.52, 2200.00, 2114.03, 1618.06, 1542.38, 1506.39, 1432.51, 1367.16, 1309.39, 1246.34, 1203.57, 1144.72, 1097.07, 995.30, 835.22, 749.25, 470.10 cm⁻¹. ¹H NMR (400 MHz, CHCl₃) δ 8.32 (s, 1H), 7.68-7.55 (m, 4H), 7.45-7.37 (m, 5H), 6.97 (s, 1H), 4.89 (br s, 2H). ¹³C NMR (100 MHz, CDCl₃) δ 151.38, 133.03, 132.52, 132.07, 130.82, 129.74, 129.03, 128.89, 127.11, 126.98, 123.92, 122.86, 121.80, 1.18.54, 106.73, 98.30, 95.78, 86.36, 86.16. HRMS Calcd C₂₃H₁₃N₃O₂: 363.1008. Found: 363.1008.

1-Bromo-4-n-hexylbenzene. The procedure of Ranu et al. was followed.^{[33]} In an 125 mL flask, bromine (0.52 mL, 10 mmol) was absorbed onto neutral, Brockmann grade I, alumina (10 g). 1-Phenylhexane (1.88 mL, 10 mmol) was absorbed onto neutral alumina (10 g) in a second 125 mL flask. The contents of both flasks were combined in a 250 mL flask equipped with a magnetic stirbar. The reaction was complete within 1 min when the dark orange color of the bromine became light yellow. The solid mass was then poured in a column that contained a short plug of silica gel. The desired product was eluted with methylene chloride to give 2.58 g of a 80:15:5 mixture (desired product: starting material: ortho-substituted product) as judged by ¹H NMR. ¹H NMR (400 MHz, CDCl₃) δ 7.37 (d, J=8.2 Hz, 2H), 7.03 (d, J=8.2 Hz, 2H), 2.54 (t, J=7.5 Hz, 2H), 1.60 (p, J=7.1 Hz, 2H), 1.38-1.24 (m, 8H), 0.92-0.84 (m, 3H).

1-n-Hexyl-4-(trimethylsilyiethynyl)benzene. See the general procedure for the Pd/Cu-catalyzed coupling reaction. The compounds used were 1-bromo-4-n-hexylbenzene (7.23 g, 30.0 mmol) trimethylsilylacetylene (5.94 mL, 42.0 mmol), copper(I) iodide (0.69 g, 3.6 mmol), bis(triphenylphosphine)palladium(II) chloride (0.84 g, 1.2 mmol), triphenylphosphine (1.57 g, 6.0 mmol), triethylamine (30.36 mL, 300 mmol), and THF (30 mL) at 85° C. for 3 d. The resultant mixture was subjected to an aqueous workup as described above. The desired material was purified by gravity liquid chromatography using silica gel as the stationary phase and hexanes as the eluent. The reaction afforded 5.26 g (68% yield) of the desired material. IR (KBr) 2923.1, 2851.3, 2158.2, 1923.1, 1507.7, 1461.5, 1405.1, 1246.2, 1220.5, 861.5, 835.9, 753.8, 600.0 cm⁻¹. ¹H NMR (400 MHz, CDCl₃) δ 7.35 (d, J=8.0 Hz, 2H), 7.07 (d, J=8.1 Hz, 2H), 2.56 (t, J=7.7 Hz, 2H), 1.62-1.50 (m, 2H), 1.28 (br s, 8H), 0.86 (br t, 3H), 0.22 (s, 9H). ¹³C NMR (400 MHz, CDCl₃) δ 143.48, 131.75, 128.18, 120.17, 105.36, 93.15, 35.95, 31.76, 31.24, 28.95, 22.68, 14.18, 0.17. HRMS calcd C₁₇H₂₆Si: 258.1804. Found: 258.1793.

1-Ethynyl-4-n-hexylbenzene. See the general procedure for the deprotection of trimethylsilyl-protected alkynes. The compounds used were 1-n-hexyl-4-(trimethylsilylethynyl)benzene (0.18 g, 0.7 mmol), potassium carbonate (0.48 g, 3.5 mmol), methanol (10 mL), and methylene chloride (10 mL) for 2 h. The material was immediately reacted in the next step without additional purification or identification.

2-Bromo-5-(4′-n-hexylphenylethynyl)-4-nitroacetanilide (88). See the general procedure for the Pd/Cu-catalyzed coupling reaction. The compounds used were 68 (1.42 g, 4.21 mmol) 1-ethynyl-4-it-hexylbenzene (0.95 g, 3.83 mmol), copper(I) iodide (0.02 g, 0.08 mmol), bis(triphenylphosphine)palladium(II) chloride (0.07 g, 0.38 mmol), diisopropylethylamine (2.69 mL, 15.38 mmol), and THF (20 mL) at 75° C. for 3 d. The desired material was purified by gravity liquid chromatography using silica gel as the stationary phase and a mixture of methylene chloride as the eluent. R_{f} (product): 0.58. The reaction afforded 0.52 g (31% yield, two steps) of the desired material. IR (KBr) 3276.65, 3086.57, 3016.72, 2926.07, 2852.18, 2213.34, 1671.79, 1592.84, 1560.91, 1534.12, 1500.11, 1460.89, 1389.78, 1337.01, 1260.89, 1093.45, 1020.52, 894.33, 813.73, 743.88, 631.04, 464.48, 442.99 cm⁻¹. ¹H NMR (400 MHz, CHCl₃) δ 8.83 (s, 1H), 8.39 (s, 1H), 7.81 (br s, 1H), 7.35 (ABq, J=8.3 Hz, Δν=110.6 Hz, 4H), 2.65 (t, J=7.6 Hz, 2H), 2.33 (s, 3H), 1.63 (p, J=7.8, 6.1, 2H), 1.40-1.22 (m, 6H), 0.93 (t, J=7.2 Hz, 3H). ¹³C NMR (100 MHz, CDCl₃) δ 168.83, 145.36, 144.28, 140.22, 132.55, 129.38, 129.03, 125.18, 120.44, 119.69, 111.21, 99.49, 84.76, 36.43, 32.08, 31.53, 29.32, 25.49, 22.99, 14.49. HRMS Calcd C₂₂H₂₃⁷⁹BrN₂O₃: 442.0892. Found: 442.0895.

Methyl 4-(trimethylsilylethynyl)benzoate. See the general procedure for the Pd/Cu-catalyzed coupling reaction. The compounds used were methyl 4-iodobenzoate (5.00 g, 19.1 mmol), bis(triphenylphosphine)palladium(II) chloride (0.670 g, 0.955 mmol), copper(I) iodide (0.36 g, 1.91 mmol), THF (50 mL), diisopropylethylamine (13.31 mL, 76.4 mmol) and trimethylsilylacetylene (3.51 mL, 24.8 mmol) at 60° C. for 18 h. Column chromatography (silica gel, 1:1 hexanes/methylene chloride) afforded the desired product (4.34 g, 98% yield) as orange crystals. IR (KBr) 2958.6, 2159.9, 1720.7, 1603.2, 1443.2, 1404.8, 1278.3, 1243.6, 1171.1, 1110.5, 1017.0, 841.6, 771.1 cm⁻¹. ¹H NMR (400 MHz, CDCl₃) δ 7.99 (dt, J=8.7 Hz, 1.7 Hz, 2H), 7.54 (dt, J=8.6, 1.7 Hz, 2H), 3.94 (s, 3H), 0.28 (s, 9H). ³C NMR (100 MHz, CDCl₃) δ 166.68, 132.06, 129.89, 129.57, 127.97, 104.27, 97.88, 52.40, 0.029. HRMS calculated for C₁₃H₁₆O₂Si: 232.091959. Found: 232.0919.

Methyl 4-ethynylbenzoate (89). See the general procedure for the deprotection of trimethylsilyl-protected alkynes. The compounds used were methyl 4-(trimethylsilylethynyl)benzoate (0.75 g, 3.23 mmol), potassium carbonate (2.23 g, 16.15 mmol), methanol (50 mL) and methylene chloride (50 mL) for 2 h. Extraction of the product afforded 0.49 g of the desired product that was immediately reacted in the next step.

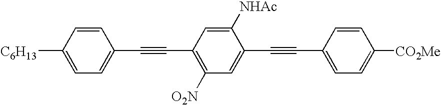

Methyl 2′-acetamido-4,4′-diphenylethynyl-4″-n-hexyl-5′-nitrobenzoate. See the general procedure for the Pd/Cu-catalyzed coupling reaction. The compounds used were 88 (0.23 g, 0.52 mmol), 89 (0.11 g, 0.68 mmol), copper(I) iodide (0.01 g, 0.05 mmol), bis(triphenylphosphine)palladium(II) chloride (0.02 g, 0.03 mmol), diisopropylethylamine (0.36 mL, 2.08 mmol), and THF (15 mL) at 75° C. for 3 d. The desired material was purified by gravity liquid chromatography using silica gel as the stationary phase and a mixture of methylene chloride as the eluent. R_{f}: 0.20. The reaction afforded 0.26 g (96% yield) of the desired material. IR (KBr) 3426.99, 3286.07, 2926.72, 2844.78, 2361.19, 2334.33, 2194.63, 1722.66, 1671.72, 1602.42, 1546.11, 1494.92, 1.426.27, 1407.39, 1339.77, 1276.39, 1173.17, 1105.95, 760.00 cm⁻¹. ¹H NMR (400 MHz, CHCl₃) δ 8.86 (s, 1H), 8.33 (s, 1H), 8.06 (br s, 1H), 7.85 (ABq, J=6.8 Hz, Δν=188.8 Hz, 4H), 7.35 (ABq, J=8.2 Hz, Δν=170.20 Hz, 4H), 3.98 (s, 3H), 2.66 (t, J=7.6 Hz, 2H), 2.35 (s, 3H), 1.65 (p, J=7.8, 6.1 Hz, 2H), 1.40-1.37 (m, 6H), 0.93 (t, J=6.8 Hz, 3H). ¹³C NMR (100 MHz, CDCl₃) δ 168.70, 166.52, 145.43, 144.23, 142.39, 132.65, 132.03, 131.37, 130.30, 129.15, 129.03, 126.09, 123.95, 121.65, 119.74, 111.04, 100.61, 98.76, 85.46, 85.05, 52.86, 36.45, 32.08, 31.54, 29.32, 25.56, 22.99, 14.48. HRMS Calcd C₃₂H₃₀N₂O₅: 522.2155. Found: 522.2147.

Methyl 2′-amino-4,-4′-diphenylethynyl-4″-n-hexyl-5′-nitrobenzoate (90). To a 100 mL round bottom flask equipped with a magnetic stirbar was added methyl 2′-acetamido-4,4′-diphenylethynyl-4″-n-hexyl-5′-nitrobenzoate (0.10 g, 0.19 mmol), potassium carbonate (0.16 g, 1.15 mmol), methanol (15 mL), and methylene chloride (15 mL). The reaction mixture was allowed to react at room temperature for 1 h. The reaction was quenched with water and extracted with methylene chloride (3×). Organic layers were combined and dried over MgSO₄. Volatiles were removed in vacuo. No further purification was needed. The reaction afforded 0.09 g (99% yield) of the desired material. IR (KBr) 3475.47, 3362.54, 2914.63, 2850.15, 2205.37, 1706.79, 1629.40, 1596.36, 1543.77, 1519.70, 1426.27, 1316.01, 1290.51, 1279.59, 1173.73, 1141.49, 1114.87, 760.00, 679.40, 614.93, 469.85 cm⁻¹. ¹H NMR (400 MHz, CHCl₃) δ 8.31 (s, 1H), 7.85 (ABq, J=8.6 Hz, Δν=182.9 Hz, 4H), 7.36 (ABq, J=8.2 Hz, Δν=129.83 Hz, 4H), 6.95 (s, 1H), 4.92 (br s, 2H), 3.96 (s, 3H), 2.64 (t, J=7.6 Hz, 2H), 1.65 (p, J=7.7, 6.8 Hz, 2H), 1.36-1.27 (m, 6H), 0.91 (t, J=7.1 Hz, 3H). ¹³C NMR (100 MHz, CDCl₃) δ 166.74, 151.42, 145.13, 139.96, 132.46, 131.92, 130.77, 130.64, 130.10, 129.00, 127.11, 121.96, 120.01, 118.38, 106.80, 98.72, 96.69, 86.51, 85.81, 52.75, 36.42, 32.08, 31.56, 29.32, 22.99, 14.47. HRMS Calcd C₃₀H₂₈N₂O₄: 480.2049. Found: 480.2050.

2′-Amino-4,4′-diphenylethynyl-4″-n-hexyl-5′-nitrobenzoic acid (91). The procedure by Corey et al. was followed.^{[34]} To a 250 mL round bottom flask equipped with a magnetic stirbar was added 90 (0.07 g, 0.15 mmol), lithium hydroxide (0.02, 0.75 mmol), methanol (9 mL), methylene chloride (5 mL), and water (3 mL). The reaction mixture was allowed to stir at room temperature for 2.5 d. The reaction was quenched with water and extracted with methylene chloride (3×). The yellow aqueous phases were combined and acidified to pH=3 whereupon a yellow solid precipitated. The solid material was collected on a fritted funnel. The collected solid reaction mixture was purified by gravity column chromatography using silica gel as the stationary phase and methylene chloride as the eluent. R_{f} (product): 0.10. The reaction afforded 0.065 g (94% yield) of the desired material. IR (KBr) 3460.77, 3378.60, 2957.49, 2921.54, 2844.51, 2207.7, 1580.98, 1542.74, 1428.19, 1385.56, 1307.71, 1242.23, 1.108.70, 774.89, 646.51, 615.69, 456.49 cm⁻¹. ¹H NMR (400 MHz, MeOH) δ 8.22 (s, 1H), 7.72 (ABq, J=8.5 Hz, Δν=142.14 Hz, 4H), 7.38 (ABq, J=8.2 Hz, Δν=97.07 Hz, 4H), 6.99 (s, 1H), 2.61 (t, J=7.6 Hz, 2H), 1.69-1.59 (m, 2H), 1.42-1.28 (m, 6H), 0.96-0.86 (m, 3H).

4,4′-Dibromo-2,2′-dinitrobiphenyl (92).^{[35]} In a large oven dried screw capped tube equipped with a magnetic stirbar was added 2,2′-dinitrobiphenyl (2.44 g, 10.0 mmol) and silver acetate (4.01 g, 24.0 mmol). Glacial acetic acid (20 mL), sulfuric acid (2.03 mL, 38.0 mmol), and bromine (1.54 mL, 30.0 mmol) were sequentially added and the reaction vessel was capped. The reaction vessel was heated to 80° C. for 16 h. The reaction mixture was cooled and was poured into ice water. The solid material was then collected by filtration. The desired material was purified by gravity liquid chromatography using silica gel as the stationary phase and a mixture of 1:1 methylene chloridelhexanes as the eluent. R_{f} (product): 0.58. The reaction afforded 1.43 (36% yield) of the desired material as a yellow solid. IR (KBr) 3097.4, 2861.5, 1523.1, 1384.6, 1338.5, 1271.8, 1241.0, 1148.7, 1092.3, 1000.0, 892.3, 835.9, 764.1, 723.1, 697.4 cm⁻¹. ¹H NMR (400 MHz, CDCl₃) δ 8.37 (d, J=2.0 Hz, 2H), 7.81 (dd, J=2.0, 8.2 Hz, 2H), 7.15 (d, J=8.0 Hz, 2H). ¹³C NMR (100 MHz, CDCl₃) δ 147.07, 136.34, 131.76, 131.69, 127.81, 122.66. HRMS Calcd C₁₂H₆Br₂N₂O₄: 399.8694. Found: 399.8675.

4,4′-Bis(trimethylsilylethynyl)-2,2′-dinitrobiphenyl (93). See the general procedure for the Pd/Cu-catalyzed coupling reaction. The compounds used were 4,4′-dibromo-2,2′-dinitrobiphenyl (1.50 g, 3.73 mmol), trimethylsilylacetylene (1.32 mL, 9.33 mmol), copper(I) iodide (0.07 g, 0.37 mmol), bis(triphenylphosphine)palladium(II) chloride (0.13 g, 0.19 mmol), triphenylphosphine (0.20 g, 0.75 mmol), triethylamine (1.62 mL, 14.92 mmol), and THF (25 mL) at 75° C. for 3 d. The desired material was purified by gravity liquid chromatography using silica gel as the stationary phase and a mixture of 1:1 methylene chloride/hexanes as the eluent. R_{f} (product): 0.55. The reaction afforded 1.44 g (88% yield) of the desired compound as a very viscous yellow liquid. IR (KBr) 3743.6, 3651.3, 3076.9, 2953.8, 2892.3, 2153.8, 2061.8, 1943.6, 1876.9, 1805.1, 1610.4, 1523.3, 1477.1, 1405.3, 1338.6, 1256.6, 1215.6, 1143.8, 1092.5, 1000.2, 928.4, 851.5, 759.2, 692.5, 641.2 cm⁻¹. ¹H NMR (400 MHz, CDCl₃) δ 8.28 (d, J=1.6 Hz, 2H), 7.71 (dd, J=6.2, 0.7 Hz, 2H), 7.20 (d, J=6.9 Hz, 2H), 0.19 (s, 18H). ¹³C NMR (100 MHz, CDCl₃) δ 146.76, 136.22, 133.26, 130.71, 128.04, 124.97, 101.67, 98.74, −0.07. HRMS Calcd C₂₂H₂₄N₂O₄Si₂: 436.1275. Found: 436.1281.

2-Amino-4,4′-bis(trimethylsilylethynyl)-2′-nitrobiphenyl (94). 93 (0.70 g, 1.60 mmol), glacial acetic acid (15 mL), and THF (15 mL) were added to a 100 mL round bottom flask equipped with a magnetic stirbar and a West condenser. The reaction mixture was heated to reflux. Iron powder (0.20 g, 3.52 mmol) was carefully added to the refluxing reaction mixture.^{[36]} The reaction mixture was allowed to reflux for 2 h while being monitored by TLC. The reaction mixture was cooled, quenched with water, and filtered through filter paper to remove unreacted iron. The filtrate was extracted with brine (3×) and diluted with methylene chloride. Organic layers were combined and dried over magnesium chloride. Volatiles were removed in vacuo. The crude reaction mixture was purified by gravity liquid chromatography using silica gel as the stationary phase and a mixture of 3:1 methylene chloride/hexanes as the eluent. R_{f} (product): 0.68. The reaction afforded 0.13 g (21% yield, 33% based on a recovered 0.26 g of starting material) of the desired material. IR (KBr) 3469.7, 3382.5, 2953.8, 2154.7, 1617.1, 1529.9, 1479.1, 1413.7, 1346.2, 1242.5, 848.4, 759.5 cm⁻¹. ¹H NMR (400 MHz, CDCl₃) δ 8.02 (d, J=1.7 Hz, 1H), 7.68 (dd, J=7.8, 1.6 Hz, 1H), 7.36 (d J=7.8 Hz, 1H), 6.93-6.86 (m, 3H), 3.49 (s, 2H), 0.28 (s, 9H), 0.25 (s, 9H). ¹³C NMR (100 MHz, CDCl₃) δ 149.08, 143.25, 135.73, 132.67, 132.41, 128.92, 127.58, 124.33, 124.19, 123.13, 122.56, 118.91, 104.72, 101.77, 98.24, 94.43, 0.09, −0.12. HRMS Calcd C₂₂H₂₆N₂O₂Si₂: 406.1533. Found: 406.1532.

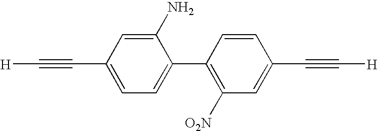

2-Amino-4,4′-diethynyl-2′-nitrobiphenyl. See the general procedure for the deprotection of trimethylsilyl-protected alkynes. The compounds used were 94 (0.13 g, 0.33 mmol), potassium carbonate (0.46 g, 3.30 mmol), methanol (10 mL) and methylene chloride (10 mL) for 2 h. Due to the instability of conjugated terminal alkynes, the material was immediately used in the next step without additional purification or identification.

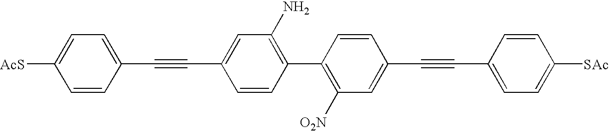

95. See the general procedure for the Pd/Cu-catalyzed coupling reaction. The compounds used were 2-amino-4,4′-diethynyl-2′-nitrobiphenyl (0.09 g, 0.33 mmol), 3 (0.22 g, 0.79 mmol), copper(I) iodide (0.02 g, 0.10 mmol), bis(triphenylphosphine)palladium(II) chloride (0.02 g, 0.03 mmol), diisopropylethylamine (0.46 mL, 2.64 mmol), and THF (10 mL) at 50° C. for 2 d. The desired material was purified by gravity liquid chromatography using silica gel as the stationary phase and methylene chloride as the eluent. R_{f} (product): 0.55. The reaction afforded 0.11 g (61% yield, two steps) of the desired compound as a bright yellow solid. IR (KBr) 3128.2, 2924.8, 2859.4, 1718.8, 1348.6, 1261.1, 1108.5, 948.7, 825.2, 614.5 cm⁻¹. ¹H NMR (400 MHz, CDCl₃) δ 8.12 (d, J=1.2 Hz, 1H), 7.78 (dd, J=6.2, 1.6 Hz, 1H), 7.58 (dd, J=6.6, 1.8 Hz, 2H), 7.54 (d, J=8.6 Hz, 2H), 7.46-7.36 (m, 5H), 7.02-6.94 (m, 3H), 3.59 (s, 2H), 2.45 (s, 3H), 2.43 (s, 3H). ¹³C NMR (100 MHz, CDCl₃) δ 193.26, 192.96, 149.29, 1.43.50, 135.56, 134.24, 134.14, 132.74, 132.66, 132.44, 132.36, 132.26, 132.14, 129.17, 128.02, 127.35, 124.42, 124.22, 124.09, 123.21, 122.38, 118.631, 91.64, 90.84, 88.86, 88.12, 30.48, 30.42. HRMS Calcd C₃₂H₂₂N₂O₄S₂: 563.1.099. Found: 563.1094.

3,3′-Dinitro-2,2′-bipyridyl (97).^{[37]} To a 250 mL round bottom flask equipped with a magnetic stirbar and a West condenser was added 2-chloro-3-nitropyridine (15.0 g, 94.61 mmol) and copper bronze (15.03 g, 236.53 mmol). DMF (100 mL) was added and the reaction mixture was heated to reflux for 18 h. The reaction mixture was cooled and filtered through a pad of celite. The filter cake was washed with hot DMF. The filtrate was poured into 1 L of water and the desired material precipitated. The solid material was collected on a fritted funnel to give 3.57 g (35% yield) of a golden brown solid. ¹H NMR (400 MHz, CDCl₃) δ 8.91 (dd, J=4.8, 1.5 Hz, 2H), 8.60 (dd, J=8.3, 1.5 Hz, 2H), 7.67 (dd, J=8.4, 4.8 Hz, 2H). ¹³C NMR (100 MHz, CDCl₃) δ 153.52, 151.79, 144.33, 133.44, 124.65.

5,5′-Dibromo-3,3′-dinitro-2,2′-bipyridyl (98). To a 100 mL round bottom flask equipped with a magnetic stirbar was added 97 (1.00 g, 4.06 mmol). The starting material was dissolved in MeOH. (50 mL) and CH₂Cl₂ (50 mL). In a separate 100 mL two necked round bottom flask was added KBr (9.66 g, 81.2 mmol), and then bromine (4.33 mL, 81.2 mmol) was slowly added.^{[38]} The KBr/Br₂ mixture was slowly transferred via cannula over 30 min to the first flask containing the bipyridine. The desired material precipitated and was collected on a fritted funnel. The collected solid was added to an oven dried pressure tube equipped with a magnetic stirbar and capped with a septum. Bromine (0.42 mL, 8.12 mmol) was added, the septum was removed and the reaction vessel was quickly sealed with a screw cap then heated to 180° C. for 3 d. The reaction was cooled and poured into a solution of ice water. 1 M NaHSO₃ (aq) was added to react with any unreacted bromine. The solution was made alkaline with NaOH (s). The resulting solution was extracted with CH₂Cl₂ (4×). The organic layers were combined and dried over MgSO₄. Volatiles were removed in vacuo. The reaction mixture was purified by gravity liquid chromatography using silica gel as the stationary phase and 2:3 ethyl acetate/hexanes as the eluent mixture. R_{f}=0.41. The reaction afforded 0.52 g (45% yield). IR (KBr) 3425.07, 3059.70, 1578.41, 1544.96, 1428.03, 1345.68, 1232.84, 1104.05, 1027.57, 897.37, 879.49, 789.60, 749.49, 649.64, 551.72, 475.22 cm⁻¹. ¹H NMR (400 MHz, CDCl₃) δ 8.89 (d, J=2.0 Hz, 2H), 8.67 (d, J=2.1 Hz, 2H). ¹³C NMR (100 MHz, CDCl₃) 8154.26, 148.55, 143.76, 135.50, 120.86. HRMS Calcd C₁₀H₄Br₂N₄O₄: 401.8600. Found: 401.8603.

4-(Trimethylsilylethynyl)benzaldehyde. See the general procedure for the Pd/Cu-catalyzed coupling reaction. The compounds used were 4-iodobenzaldehyde (0.5 g, 2.15 mmol), THF (2.7 mL), trimethylsilylacetylene (0.44 mL, 0.31 g, 3.18 mmol), diisopropylethylamine (0.6 mL, 3.5 mmol), bis(triphenylphosphine)palladium(II) chloride (4 mg, 0.21 mmol) and copper iodide (0.0020 g, 2.1 mmol) at room temperature for 24 h. After workup, the residue was purified by silica gel column chromatography using hexane/methylene chloride (1: It) to provide 0.063 g (73%) of the title compound as a brown solid. MP: 60-66° C. IR (KBr) 2955.6, 2833.4, 2722.2, 2144.5, 1700.0, 1594.5, 1555.6, 1383.3, 1294.5, 1244.5, 1200.0, 1155.6, 861.1, 838.9, 755.6, 661.1 cm¹. ¹H NMR (300 MHz, CDCl₃) δ 9.98 (s, 1H), 7.81 (d, J=8.37 Hz, 2H), 7.59 (d, J=8.28 Hz, 2H), 0.13 (s, 9H). C NMR (100 MHz, CDCl₃) δ 191.38, 135.59, 132.47, 129.34, 103.83, 99.02, −0.21. Anal. Calcd for C₁₂H₁₄OSi: C, 71.00; H, 6.95. Found: C, 71.29; H, 6.96.

4-Ethynylbenzaldehyde. According to the general procedure, the compounds used were 4-(trimethylsilylethynyl)benzaldehyde (0.093 g, 0.45 mmol), methylene chloride (5 mL), methanol (5 mL) and potassium carbonate (0.47 g, 3.42 mmol) for 6 h The residue was purified by silica gel column chromatography using methylene chloride to provide 0.056 g (95%) of the title compound as a pale yellow solid. MP: 84-86° C. JR (KBr) 3210.3, 1696.9, 1682.0, 1600.0, 1550.0, 1384.6, 1205.1, 1164.1, 825.6, 738.5 cm⁻¹. ¹H NMR (300 MHz, CDCl₃) δ 10.01 (s, 1H), 7.81 (d, J=8.4 Hz, 2H), 7.63 (d, J=8.25 Hz, 2H), 3.27 (s, 1H). ¹³C NMR (100 MHz, CDCl₃) δ 192.38, 137.06, 133.83, 130.62, 129.43, 83.84, 82.28. FABMS Calcd for C₉H₆O: 130. Found: 130.

4-Thioacetyldiphenylethynylcarboxaldehyde (110). See the Pd/Cu coupling protocol. The compounds used were 4-ethynylbenzaldehyde (0.049 g, 0.37 mmol), 3 (0.123 g, 0.44 mmol), bis(triphenylphosphine)palladium(II) chloride (0.013 g, 0.06 mmol), copper iodide (0.35 mg, 0.18 mmol) and THF (0.2 mL). The residue was purified by silica gel column chromatography using methylene chloride/hexane (1:1) as the eluent. The solvent was removed in vacuo to afford 0.078 g (75%) of the title product as a yellow solid. MP: 122-123° C. IR (KBr) 3138.5, 2841.0, 1.697.4, 1594.9, 1379.5, 1287.2, 1123.1, 959.0, 820.5, 723.1 cm⁻¹. ¹H NMR (300 MHz, CDCl₃) δ 10.10 (s, 1H), 7.84 (d, J=8.4 Hz, 2H), 7.65 (d, J=8.25 Hz, 2H), 7.55 (d, J=8.4 Hz, 2H), 7.39 (d, J=8.4 Hz, 2H), 2.43 (s, 3H). ¹³C NMR (100 MHz, CDCl₃) δ 194.14, 192.31, 136.67, 135.34, 134.17, 133.27, 130.67, 130.26, 130.04, 124.76, 93.68, 91.18, 31.66. FABMS Calcd for C₁₇H₁₂O₂S: 280. Found: 280. Anal. Calcd for C₁₇H₁₂O₂S: C, 72.83; H, 4.34. Found: C, 72.21; H, 4.35.

5,15-Bis(4-thioacetyldiphenylethynyl)-10,20-bis(phenyl)porphyrin (111). A solution of 110 (0.10 g, 0.35 mmol) and meso-phenyldipyrrromethane (102)^{[41]} (0.079 g, 0.36 mmol), in CHCl₃ (36 mL) at room temperature was degassed under nitrogen for 15 min. This was followed by the addition of two drops of BF₃OEt₂. The solution was left stirring under nitrogen for 1 h after which time DDQ (0.081 g, 0.36 mmol) was added and stirring continued for another 1 h. The solvent was removed in vacuo and the crude sample was purified by silica gel column chromatography using methylene chloride as the eluent followed by a second column purification with methylene chloride/hexane (1:1) to provide 0.047 g (27%) of the title compound in the first major fraction as a purple powder. MP: 200-204° C. IR (KBr) 3435.9, 3128.2, 1625.6, 1384.6, 1123.1, 800 cm⁻¹. ¹H NMR (300 MHz, CDCl₃) δ 8.85 (m, 8H), 8.19 (d, J=7.92 Hz, 8H), 7.91 (d, J=7.83 Hz, 4H), 7.70-7.76 (m, 10H), 7.45 (d, J=8.19 Hz, 4H), 2.46 (s, 6H), −2.79 (s, 2H). C NMR (100 MHz, CDCl₃) δ 193.49, 142.47, 141.99, 134.59, 134.52, 134.32, 132.31, 130.06, 128.24, 127.79, 126.71, 124.52, 122.48, 122.43, 120.53, 120.44, 119.47, 119.37, 119.31, 119.21, 91.0, 89.81, 30.32. UV/Vis (CH₂Cl₂) λₘₐₓ (log ε): 450.92 (5.52), 570.12 (3.23), 619.50 (3.91), 670.58 (4.73). FABMS Calcd for C₁₄H₄₂N₄O₂S₂: 962. Found: 962. Anal. Calcd for C₁₄H₄₂N₄O₂S₂.CHCl₃: C, 72.11; H, 4.00; N, 5.17. Found: C, 73.15; H, 4.33; N, 5.17.

5,15-Bis(4-thioacetyldiphenylethynyl)-10,20-bis(4-methylphenyl)porphyrin (112). See the preparation of 111 for the synthetic protocol. The compounds used were 110 (0.125 g, 0.45 mmol), meso-(4-methylphenyl)dipyrrromethane (103)^{[41]} (0.1 g, 0.45 mmol), CHCl₃ (36.66 mL), two drops of BF₃OEt₂, and DDQ (0.10 g, 0.45 mmol). The solvent was removed in vacuo and the sample was purified by silica gel column chromatography using methylene chloride as the eluent followed by a second column purification with methylene chloride/hexane (1:1) to provide 0.059 g (27%) of the title compound in the first major fraction as a purple solid. MP: 214-216° C. IR (KBr) 3433.3, 3128.2, 1704.3, 1464.5, 1384.6, 1108.5, 963.2, 796.2, 730.8 cm⁻¹. ¹H NMR (300 MHz, CDCl₃) δ 8.89-8.84 (m, 8H), 8.19 (d, J=8.19 Hz, 4H), 8.07 (d, J=7.89 Hz, 41H), 7.9 (d, J=7.95 Hz, 4H), 7.68 (d, J=8.22 Hz, 4H), 7.53 (d, J=7.89 Hz, 4H), 7.45 (d, J=8.34 Hz, 4H), 2.69 (s, 6H), 2.46 (s, 6H), −2.75 (s, 2H). ¹³C NMR (100 MHz, CDCl₃) δ 193.50, 142.58, 139.07, 137.45, 134.58, 134.48, 134.32, 132.31, 130.04, 131.00, 128.22, 127.44, 124.54, 122.37, 120.70, 120.53, 119.16, 119.00, 91.03, 89.77, 30.32, 21.52. UV/Vis (CH₂Cl₂) λₘₐₓ (log ε): 456.03 (5.20), 617.80 (3.59), 679.10 (4.42). HRFABMS Calcd for C₆₆H₄₆N₄O₂S₂: 990.3062. Found: 990.3080. Anal. Calcd for C₆₆H₄₆N₄O₂S₂: C, 79.97; H, 4.67; N, 5.65. Found: C, 80.42; H, 4.98; N, 5.97.

5,15-Bis(4-thioacetyldiphenylethynyl)-10,20-bis(4-bromophenyl)porphyrin (113). See the preparation of 111 for the synthetic protocol. The compounds used were 110 (0.061 g, 0.22 mmol), meso-(4-bromophenyl)dipyrromethane (104)^{[41]} (0.065 g, 0.22 mmol), CHCl₃ (21.87 mL), two drops of BF₃OEt₂ and DDQ (0.049 g, 0.22 mmol). The solvent was removed in vacuo and the crude sample was purified by silica gel column chromatography using methylene chloride followed by a second column purification with methylene chloride/hexane (1:1) to provide 0.034 g (28%) of the title compound in the first major fraction as a purple solid. MP: 204-206° C. JR (KBr) 3435.9, 3138.5, 2923.1, 1625.6, 1461.5, 1384.6, 1117.9, 800 cm⁻¹. ¹H NMR (300 MHz, CDCl₃) δ 8.87 (m, 8H), 8.21 (d, J=8.07 Hz, 4H), 8.05 (d, J=8.04 Hz, 4H), 7.91 (m, 8H), 7.68 (d, J=8.22 Hz, 4H), 7.48 (d, J=8.19 Hz, 4H), 2.46 (s, 6H), −2.82 (s, 2H). ¹³C NMR (100 MHz, CDCl₃) δ 193.50, 142.25, 142.21, 140.86, 135.82, 134.57, 134.33, 132.43, 132.31, 130.10, 129.96, 128.27, 124.47, 122.59, 122.58, 119.69, 118.90, 90.90, 89.91, 30.34. UV/Vis (CH₂Cl₂) λₘₐₓ (log ε): 458.68 (5.69), 571.82 (3.32), 675.69 (4.92), 621.20 (4.10). HRFABMS calcd for C₆₄H₄₀Br₂N₄O₂S₂: 1119.1038. Found: 1119.1039. Anal. Calcd for C₆₄H₄₀Br₂N₄O₂S₂: C, 68.57; H, 3.59; N, 4.99. Found: C, 67.81; H, 3.92; N; 4.86.

5,15-Bis(4-thioacetyldiphenylethynyl)-10,20-bis(4-iodophenyl)porphyrin (114). See the preparation of 111 for the synthetic protocol. The compounds used were 110 (0.060 g, 0.21 mmol), meso-(4-iodophenyl)dipyrrromethane (105)[41] (0.075 g, 0.21 mmol), CHCl₃ (43 mL), two drops of BF₃OEt₂ and DDQ (0.049 g, 0.21 mmol). The solvent was removed in vacuo and the crude sample was purified by silica gel column chromatography using methylene chloride as the eluent followed by a second column purification with methylene chloride/hexanes (1:1, v/v) to provide 0.034 g (28%) of the title compound in the first major fraction as a purple powder. MP=216-218° C. IR (KBr) 3435.9, 3128.2, 1466.7, 1384.6, 1117.9, 800 cm⁻¹. ¹H NMR (300 MHz, CDCl₃) δ 8.86-8.83 (m, 8H), 8.17 (d, J=8.13 Hz, 4H), 8.05 (d, J=8.19 Hz, 4H), 7.89 (d, J=7.95 Hz, 8H), 7.67 (d, J=8.22 Hz, 4H), 7.45 (d, J=8.19 Hz, 4H), 2.46 (s, 6H), −2.84 (s, 2H). C NMR (100 MHz, CDCl₃) 6194.26, 143.26, 142.51, 137.13, 136.94, 135.59, 135.34, 133.34, 132.10, 131.14, 129.40, 125.54, 123.67, 120.76, 120.07, 95.40, 92.07, 91.07, 31.61. HRFABMS Calcd for C₆₄ H₄₀I₂N₄O₂S₂: 1214.0682. Found: 1214.0759 UV/Vis is (CH₂Cl₂) λₘₐₓ (log ε): 457.88 (5.44), 578.63 (3.35), 614.39 (3.85), 673.99 (4.66). Anal. Calcd for C₆₄H₄₀I₂ N₄O₂S₂.CHCl₃: C, 58.51; H, 3.09; N; 4.19. Found: C, 57.85; H, 3.15; N, 4.54.

Meso-(4-thioacetyldiphenylethynyl)dipyrromethane (115). A solution of pyrrole (6 mL, 87 mmol) and 110 (0.055 g, 0.19 mmol) in methanol (0.27 mL) was treated with acetic acid (0.82 mL) under nitrogen at room temperature for 20 h. The reaction mixture was diluted with CH₂Cl₂ and washed with water. The organic phase was dried over MgSO₄ and the solvents were removed in vacuo. The crude sample was purified by silica gel column chromatography using methylene chloride/triethylamine (100:1, v/v) and was isolated as the second light yellow band. The solvent was removed in vacuo to provide 0.067 g (86%) of the title product as a tan viscous oil. IR (KBr) 3394.9, 3169.2, 1384.6, 1117.9, 1025.6, 769.2, 717.9 cm⁻¹. ¹H NMR (300 MHz, CDCl₃) δ 8.02 (br s, 2H), 7.53 (d, J=8.13 Hz, 2H), 7.45 (d, J=8.25 Hz, 2H), 7.37 (d, J=8.04 Hz, 2H), 7.19 (d, J=8.31 Hz, 2H), 6.7 (br s, 2H), 6.17 (dd, J=5.4, 2.6 Hz, 2H), 5.89 (br s, 2H), 2.41 (s, 3H), 5.41 (s, 1H). ¹³C NMR (100 MHz, CDCl₃) δ 193.43, 142.75, 134.17, 132.12, 131.92, 128.44, 127.96, 124.485, 121.405, 117.45, 108.43, 107.39, 90.96, 88.72, 43.94, 30.43. HRFABMS Calcd for C₂₅H₂₀N₂OS: 396.1296. Found: 396.1303.

5,10,15,20-tetrakis(4-thioacetyldiphenylethynyl)porphyrin (116). To a stirred solution of 110 (0.062 g, 0.22 mmol) and pyrrole (0.015 g, 0.22 mmol) in CHCl₃(22 mL) that contained 0.75% EtOH was added two drops of BF₃OEt₂. The reaction mixture was allowed to stir under nitrogen for 5 h. After 5 h, p-chloranil (0.05 g, 0.22 mmol) was added and the reaction mixture stirred for another 1 h. The solvent was removed in vacuo and the crude residue was purified by silica gel column chromatography using methylene chloride as the eluent followed by a second column purification using methylene chloride/hexane (5:1). The solvent was removed in vacuo to provide 0.02 g (29%) of purple solid. MP: 168-170° C. IR (KBr): 3403.2, 3128.2, 1703.3, 1464.5, 1336.4, 1304.7, 11108.5, 956.0, 883.3, 796.2, 738 cm⁻¹. ¹H NMR (300 MHz, CDCl₃) δ 8.87 (s, 8H), 8.19 (d, J=8.13 Hz, 8H), 7.91 (d, J=8.13 Hz, 8H), 7.62 (d, J=8.67 Hz, 8H), 7.45 (d, J=8.13 Hz, 8H), 2.46 (s, 12H), −2.78 (s, 2H). ¹³C NMR (100 MHz, CDCl₃) δ 193.14, 142.13, 134.43, 134.17, 132.16, 129.96, 128.15, 124.37, 122.43, 1.19.51, 90.91, 89.85, 30.43. U/Vis (CH₂Cl₂) λₘₐₓ (log ε): 464.55 (5.69), 628.01 (3.90), 685.91 (4.91). FABMS Calcd for C₈₄H₅₄N₄O₄S₄: 131.0. Found: 1310.

4-Trimethylsilylethynylbenzonitrile. See the general procedure for the Pd/Cu-catalyzed coupling reaction. The compounds used were 4-bromobenzonitrile (0.50 g, 2.75 mmol), trimethylsilylacetylene (0.59 mL, 4.13 mmol), copper(I) iodide (0.05 g, 0.28 mmol), bis(triphenylphosphine)palladium(II) chloride (0.10 g, 0.14 mmol), triphenylphosphine (0.14 g, 0.55 mmol), triethylamine (1.19 mL, 11.00 mmol), and THF (15 mL) at 65° C. for 60 h. The desired material was purified by gravity liquid chromatography using silica gel as the stationary phase and a mixture of 1:1 methylene chloride/hexanes as the eluent. R_{f} (product): 0.60. The reaction afforded 0.52 g (93% yield) of the desired compound as off white crystals. IR (KBr) 3128.2, 2953.8, 2225.6, 2143.6, 1600.0, 1492.3, 1384.6, 1246.2, 1174.4, 841.0, 753.8 cm⁻¹. ¹H NMR (400 MHz, CDCl₃) δ 7.57 (d, J=8.4 Hz, 2H), 7.52 (d, J=8.3 Hz, 2H), 0.26 (s, 9H). ¹³C NMR (100 MHz, CDCl₃) 6132.15, 131.63, 127.73, 118.17, 111.53, 102.74, 99.35, −0.30. HRMS calcd C₁₂H₁₃NSi: 199.0817. Found: 199.0816.

4-Ethynylbenzonitrile. See the general procedure for the deprotection of a trimethylsilyl-protected alkyne. The compounds used were 4-trimethylsilylethynylbenzonitrile (0.35 g, 1.72 mmol), potassium carbonate (1.19 g, 8.60 mmol), methanol (10 mL), and methylene chloride (10 mL) for 2 h. The material was immediately reacted in the next step without additional purification or identification.

118. See the general procedure for the Pd/Cu-catalyzed coupling reaction. The compounds used were 4-ethynylbenzonitrile (0.22 g, 1.65 mmol), 3 (0.60 g, 2.15 mmol), copper(I) iodide (0.03 g, 0.17 mmol), bis(triphenylphosphine)palladium(II) chloride (0.06 g, 0.09 mmol), triphenylphosphine (0.09 g, 0.34 mmol), triethylamine (0.96 mL, 6.88 mmol) and THF (20 mL) at 65° C. for 3 d. The desired material was purified by gravity liquid chromatography using silica gel as the stationary phase and a mixture of 3:1 methylene chloride/hexanes as the eluent. R_{f}=0.49. The compound was further purified by a hexanes wash to give 0.28 g (76% yield over two steps) of the desired compound as yellow crystals. IR (KBr) 3117.9, 2225.6, 1692.3, 1379.5, 1266.7, 1164.1, 1112.8, 1010.3, 959.0, 825.6, 615.4 cm⁻¹. ¹H NMR (400 MHz, CDCl₃) δ 7.63 (d, J=8.6 Hz, 2H), 7.59 (d, J=8.6 Hz, 2H), 7.56 (d, J=8.62 Hz, 2H), 7.42 (d, J=8.6 Hz, 2H), 2.42 (s, 3H). ¹³C NMR (400 MHz, CDCl₃) δ 192.94, 134.22, 132.25, 132.10, 132.02, 129.16, 127.78, 132.32, 118.41, 111.77, 92.88, 89.22, 30.48. HRMS calcd C₁₇H₁₁NOS: 277.0561. Found: 277.0573.

2-Trimethylsilylethynylbenzonitrile. See the general procedure for the Pd/Cu-catalyzed coupling reaction. The compounds used were 2-bromobenzonitrile (0.50 g, 2.75 mmol), trimethylsilylacetylene (0.59 mL, 4.13 mmol), copper(I) iodide (0.05 g, 0.28 mmol), bis(triphenylphosphine)palladium(II) chloride (0.10 g, 0.14 mmol), triphenylphosphine (0.14 g, 0.55 mmol), triethylamine (1.19 mL, 11.00 mmol) and THF (15 mL) at 65° C. for 60 d. The desired material was purified by gravity liquid chromatography using silica gel as the stationary phase and a mixture of 1:1 methylene chloride/hexanes as the eluent. R_{f}=0.60. The reaction afforded 0.52 g (93% yield) of the desired compound as off white crystals. IR (KBr) 3066.7, 2953.8, 2902.6, 225.6, 2153.8, 1589.7, 1559.0, 1476.9, 1446.2, 1405.1, 1251.3, 1220.5, 1164.1, 1092.3, 1035.9, 953.8, 861.5, 764.1, 733.3, 697.4, 641.0 cm⁻¹. ¹H NMR (400 MHz, CDCl₃) δ 7.62 (d, J=7.7 Hz, 1H), 7.53 (t, J=13.7 Hz, 1H), 7.52 (d, J=11.7 Hz, 1H), 7.38 (t, J=8.8 Hz, 1H), 0.30 (s, 9H). ¹³C NMR (100 MHz, CDCl₃) δ 132.45, 132.35, 132.08, 128.35, 126.87, 117.20, 115.73, 102.16, 100.49, −0.19. HRMS calcd C₁₂H₁₃NSi: 199.0817. Found: 199.0814.

2-Ethynylbenzonitrile. See the general procedure for the deprotection of a trimethylsilyl-protected alkyne. The compounds used were 2-trimethylsilylethynylbenzonitrile (0.35 g, 1.72 mmol), potassium carbonate (1.19 g, 8.60 mmol), methanol (10 mL) and methylene chloride (10 mL) for 2 h. The material was immediately reacted in the next step without additional purification or identification.

120. See the general procedure for the Pd/Cu-catalyzed coupling reaction. The compounds used were 2-ethynylbenzonitrile (0.22 g, 1.72 mmol), 3 (0.61 g, 2.15 mmol) as described above using copper(I) iodide (0.03 g, 0.17 mmol), bis(triphenylphosphine)palladium(II) chloride (0.06 g, 0.09 mmol), triphenylphosphine (0.09 g, 0.34 mmol), triethylamine (0.96 mL, 6.88 mmol), and THF (20 mL) at 65° C. for 48 h. The resultant mixture was subjected to an aqueous workup as described above. The desired material was purified by gravity liquid chromatography using silica gel as the stationary phase and a mixture of 1:3 ethyl acetate/hexanes as the eluent. R_{f}=0.38. The compound was further purified by a hexanes wash to give 0.23 g (48% yield over two steps) of the desired compound as a yellow solid. IR (KBr) 3425.6, 3138.5, 2369.2, 2225.6, 1702.6, 1656.4, 1384.6, 1112.8, 1015.4, 943.6, 825.6, 769.2, 620.5 cm⁻¹. ¹H NMR (400 MHz, CDCl₃) δ 7.68 (d, J=7.7 Hz, 1H), 7.65 (d, J=8.4 Hz, 2H), 7.64 (buried d, 1H), 7.57 (t, J=7.6, 1H), 7.44 (buried d, 1H), 7.41 (d, J=8.7 Hz, 2H), 2.44 (s, 3H). ¹³C NMR (100 MHz, CDCl₃) δ 192.96, 134.20, 132.64, 132.46, 132.35, 132.14, 129.27, 128.46, 126.81, 123.14, 117.41, 115.45, 95.08, 87.06, 30.48. HRMS calcd C₁₇H₁₁NOS: 277.0561. Found: 277.0574.

2-Trimethylsilylethynylpyridine. See the general procedure for the Pd/Cu-catalyzed coupling reaction. The compounds used were 2-bromopyridine (121) (0.45 mL, 3.16 mmol), trimethylsilylacetylene (0.68 mL, 4.74 mmol), copper(I) iodide (0.06 g, 0.32 mmol), bis(triphenylphosphine)palladium(II) chloride (0.11 g, 0.16 mmol), triphenylphosphine (0.17 g, 0.63 mmol), triethylamine (1.38 mL, 12.64 mmol), and THF (15 mL) at 70° C. for 48 h. The desired material was purified by gravity liquid chromatography using silica gel as the stationary phase and a mixture 3:1 methylene chloride/hexanes as the eluent. R_{f} (product): 0.15. The reaction afforded 0.50 g (88% yield) of the desired compound. IR (KBr) 3056.4, 2953.8, 2902.6, 2153.8, 1579.5, 1.559.0, 1456.4, 1425.6, 1246.2, 1220.5, 1148.7, 1046.2, 984.6, 866.7, 841.0, 774.4, 759.0, 733.3, 697.4, 651.3 cm⁻¹. ¹H NMR (400 MHz, CDCl₃) δ 8.55 (d, J=3.1 Hz, 1H), 7.63 (t, J=6.1 Hz, 1H), 7.43 (d, J=7.7 Hz, 1H), 7.20 (t, J=3.6 Hz, 1H), 0.27 (s, 9H). ¹³C N (100 MHz, CDCl₃) δ 149.87, 143.03, 135.97, 127.20, 122.95, 103.65, 94.76, −0.07. HRMS calcd C₁₀H₁₃NSi: 175.0817. Found: 175.0812.

2-Ethynylpyridine. See the general procedure for the deprotection of a trimethylsilyl-protected alkyne. The compounds used were 2-trimethylsilylethynylpyridine (0.35 g, 1.95 mmol), potassium carbonate (1.35 g, 9.75 mmol), methanol (15 mL), and methylene chloride (15 mL) for 2 h. The material was immediately reacted in the next step without additional purification or identification.

122. See the general procedure for the Pd/Cu-catalyzed coupling reaction. The compounds used were 2-ethynylpyridine (0.20 g, 1.95 mmol), 3 (0.66 g, 2.34 mmol), copper(I) iodide (0.02 g, 0.12 mmol), bis(triphenylphosphine)palladium(II) chloride (0.04 g, 0.06 mmol), triphenylphosphine (0.06 g, 0.23 mmol), diisopropylethylamine (1.36 mL, 7.80 mmol), and THF (15 mL) at 50° C. for 16 h. The desired material was purified by gravity liquid chromatography using silica gel as the stationary phase and a mixture of 1:1 ethyl acetate/hexanes as the eluent. R_{f} (product): 0.38. The reaction afforded 0.26 g (53% yield over two steps) of the desired compound as a yellow solid. IR (KBr) 3128.2, 2215.4, 1697.4, 1574.4, 1461.5, 1384.6, 1276.9, 1117.9, 1005.1, 948.7, 830.8, 779.5, 733.3, 615.4 cm⁻¹. ¹H NMR (400 MHz, CDCl₃) δ 8.60 (d, J=4.0 Hz, 1H), 7.65 (t, J=5.8 Hz, 1H), 7.59 (d, J=8.0 Hz, 2H), 7.51 (d, J=4.0 Hz, 1H), 7.38 (d, J=8.6 Hz, 2H), 7.22 (t, J=3.7 Hz, 1H), 2.41 (s, 3H). ¹³C NMR (400 MHz, CDCl₃) δ 193.01, 150.05, 143.04, 136.14, 134.12, 132.50, 128.94, 127.26, 123.39, 122.96, 90.12, 88.28, 30.46. HRMS calcd C₁₅H₁₁NOS: 253.0561. Found: 253.0562.

124. See the general procedure for the Pd/Cu-catalyzed coupling reaction. The compounds used were 5-bromopyrimidine (0.18 g, 1.15 mmol), 9^{[16]} (0.24 g, 1.38 mmol), copper(I) iodide (0.02 g, 0.12 mmol), bis(triphenylphosphine)palladium(II) chloride (0.04 g, 0.06 mmol), triphenylphosphine (0.06 g, 0.23 mmol), triethylamine (0.51 mL, 4.60 mmol), and THF (15 mL) at 75° C. for 4 d. The desired material was purified by gravity liquid chromatography using silica gel as the stationary phase and a mixture of 1:1 ethyl acetate/hexanes as the eluent. R_{f} (product): 0.53. The reaction afforded 0.15 g (52%) of the desired compound as bright yellow solid. IR (KBr) 3425.6, 3128.2, 2215.4, 1702.6, 1656.4, 1543.6, 1384.6, 1117.9, 1097.4, 943.6, 820.6, 717.9, 615.4 cm⁻¹. ¹H NMR (400 MHz, CDCl₃) δ 9.14 (s, 1H), 8.85 (s, 2H), 7.76 (d, J=8.1 Hz, 2H), 7.42 (d, J=8.0 Hz, 2H), 2.44 (s, 3H). ¹³C NMR (400 MHz, CDCl₃) δ 192.84, 158.57, 156.79, 134.26, 132.22, 129.49, 122.82, 119.59, 95.46, 83.84, 30.50. HRMS calcd C₁₄H₁₀N₂OS: 254.0514. Found: 254.0513.

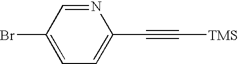

3-Bromo-6-(trimethylsilylethynyl)pyridine. See the general coupling procedure. The compounds used were 2,5-dibromopyridine (125) (2.37 g, 10.0 mmol), bis(triphenylphosphine)palladium(II) chloride (0.35 g, 0.50 mmol), copper(I) iodide (0.19 g, 1.0 mmol), triphenylphosphine (0.52 g, 2.0 mmol), triethylamine (4.35 mL, 40.0 mmol), THF (50 mL), and trimethylsilylacetylene (1.4 mL, 10 mmol) at 65° C. for 2 d. The reaction was separated via flash chromatography affording a light brown solid (2.130 g, 84% yield), R_{f}=0.22 (50% hexanes/methylene chloride). IR (KBr) 3031.8, 2958.2, 2163.8, 1561.3, 1543.6, 1451.4, 1367.0, 1248.9, 1089.4, 1001.1, 844.6, 760.9, 678.6, 642.87, 534.52 cm⁻¹. ¹H NMR (400 MHz, CDCl₃) δ 8.61 (dd, J=2.4, 0.73 Hz, 1H), 7.76 (dd, J=8.4, 2.4 Hz, 1H), 7.32 (dd, J=8.2, 0.73 Hz, 1H). ¹³C NMR δ 151.05, 141.36, 138.72, 128.19, 120.24, 102.58, 96.40, −0.40.

3-Ethynylphenyl-6-(trimethylsilylethynyl)pyridine (126). See the general procedure for the coupling reaction. The compounds used were 5-bromo-2-(trimethylsilylethynyl)pyridine (2.00 g, 7.90 mmol), bis(triphenylphosphine)palladium(II) chloride (0.28 g, 0.40 mmol), copper(I) iodide (0.15 g, 0.8 mmol), THF (20 mL), diisopropylethylamine (5.50 mL, 31.6 mmol), and phenylacetylene (0.87 mL, 7.9 mmol) at 55° C. overnight. The reaction was separated via flash chromatography affording a light brown solid (1.37 g, 63%), R_{f}=0.36 (2:1 methylene chloride to hexanes). IR (KBr) 2959.5, 2157.9, 1492.3, 1463.6, 1384.0, 1247.7, 1019.9, 844.4, 754.8, 690.3 cm⁻¹. ¹H NMR (400 MHz, CDCl₃) δ 8.70 (d, J=1.3 Hz, 1H), 7.74 (dd, J=6.0, 2.6 Hz, 1H), 7.53 (m, 2H), 7.43 (d, J=8.0 Hz, 1H), 7.36 (m, 3H). ¹³C NMR (75 MHz, CDCl₃) δ 152.32, 141.52, 138.38, 131.73, 129.02, 128.52, 126.59, 122.33, 119.76, 103.51, 96.95, 94.49, 85.93, −0.12. HRMS Calc'd for C₁₉H₁₇NSi: 275.1130. Found: 275.1126.

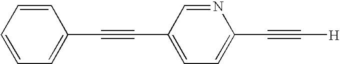

2-Ethynyl-5-ethynylphenylpyridine. See the general procedure for the deprotection of a trimethylsilyl-protected alkyne. The compounds used were 126 (272 mg, 1.00 mmol), potassium carbonate (690 mg, 5.00 mmol), methanol (30 mL) and dichloromethane (30 mL) for 2.5 h. The product was used without purification.

127. See the general procedure for the Pd/Cu-catalyzed coupling reaction. The compounds used were 2-ethynyl-5-ethynylphenylpyridine (0.167 g, 1.00 mmol), 3 (0.334 g, 1.20 mmol), bis(triphenylphosphine)palladium(II) chloride (0.035 g, 0.050 mmol), copper(I) iodide (0.019 g, 0.10 mmol), triphenylphosphine (0.026 g, 0.10 mmol), THF (30 mL) and diisopropylethylamine (0.70 mL, 4.0 mmol) at 50° C. for 2 d. Column chromatography eluting with 3:1 methylene chloride to hexanes yielded 199 mg (56%) of a light brown solid. IR (KBr) 3052.1, 2923.3, 2214.1, 1703.5, 1571.6, 1536.4, 1493.7, 1460.4, 1397.5, 1359.9, 1222.2, 1124.8, 1107.4, 1081.7, 1013.6, 943.1, 824.9, 754.3, 687.7, 618.5, 523.7 cm⁻¹. ¹H NMR (300 MHz, CDCl₃) δ 8.76 (br s, 1H), 7.80 (dd, J=2.0, 8.1 Hz, 1H), 7.62 (½ABq, J=8.5 Hz, 2H), 7.54 (m, 3H), 7.41 (½ABq, J=8.1 Hz, 2H), 7.37 (m, 3H). ¹³C NMR (75 MHz, CDCl₃) δ 193.15, 152.51, 141.57, 138.50, 134.23, 132.61, 131.75, 129.28, 129.05, 128.53, 126.63, 123.23, 122.33, 119.73, 94.61, 90.22, 85.97, 30.37. HRMS C₂₃H₁₆NOS Calc'd: 353.0870. Found: 353.0874.

129. See the general procedure for the Pd/Cu-catalyzed coupling reaction. The compounds used were 2-iodoaniline (128) (0.607 g, 2.77 mmol), bis(triphenylphosphine)palladium(II) chloride (0.098 g, 0.139 mmol), copper(I) iodide (0.053 g, 0.277 mmol), diisopropylethylamine (1.93 mL, 11.08 mmol), 89 (0.488 g, 3.05 mmol) and THF (25 mL) at 70° C. for 7 d. Column chromatography (silica gel with methylene chloride as eluent) afforded the desired product (0.40 g, 57% yield). IR (KBr) 3468.06, 3375.97, 2941.49, 2210.75, 1711.99, 1602.74, 1485.37, 1453.52, 1308.06, 1280.46, 1099.68, 770.84, 753.54, 695.52 cm⁻¹. ¹H NMR (400 MHz, CDCl₃) δ 8.04 (dt, J=8.5 Hz, 1.8 Hz, 2H), 7.59 (dt, J=8.5, 1.7 Hz, 2H), 7.40 (dd, J=7.8, 1.5 Hz, 1H), 7.18 (td, J=7.6, 1.5 Hz, 1H), 6.75 (m, 2H), 4.33 (br s, 2H), 3.94 (s, 3H). ¹³C NMR (100 MHz, CDCl₃) δ 166.95, 148.44, 132.74, 131.70, 130.70, 129.98, 129.76, 128.46, 118.44, 114.87, 107.64, 94.43, 89.54, 52.65. HRMS calculated for C₁₆H₁₃NO₂,: 251.094629. Found: 251.0940.

4-(2′-Aminoethynylphenyl)benzoic acid (130). 129 (0.300 g, 1.194 mmol), lithium hydroxide (0.250 g, 5.97 mmol), methanol (30 mL), water (10 mL), methylene chloride (20 mL) and a stir bar were added to a 100 mL round bottom flask.^{[34]} The mixture was stirred at room temperature for 2 d. The mixture was washed with methylene chloride and the layers separated. The aqueous portion was adjusted to pH=4 and washed with methylene chloride to afford 0.277 g of product (98% yield). IR (KBr) 3468.1, 3376.3, 3054.3, 2957.6, 2656.7, 2538.5, 2205.4, 1681.3, 1604.8, 1488.4, 1422.2, 1318.8, 1281.9, 860.4, 758.7 cm⁻¹. ¹H NMR (400 MHz, d-DMSO) δ 7.95 (dt, J=8.5, 1.8 Hz, 2H), 7.72 (dt, J=8.5, 1.7 Hz, 2H), 7.26 (dd, J=7.7, 1.5 Hz, 1H), 7.11 (td, J=7.7, 1.6 Hz, 1H), 6.75 (dd, J=8.3, 0.6 Hz, 1H), 6.55 (td, J=7.6, 1.0 Hz, 1. H), 5.59 (br s, 2H). ¹³C NMR (100 MHz, d-DMSO) δ 167.65, 150.85, 132.88, 132.12, 131.19, 130.72, 130.24, 128.32, 116.66, 114.94, 105.64, 94.14, 90.90. HRMS calculated for C₁₅H₁₁NO₂: 237.0790. Found: 237.0792.

Methyl 4-(2′-methoxyethynylphenyl)benzoate (132). See the general procedure for the Pd/Cu-catalyzed coupling reaction. The compounds used were 2-iodoanisole (131) (0.49 mL, 3.74 mmol), 89 (0.50 g, 3.12 mmol), copper(I) iodide (0.06 g, 0.31 mmol), bis(triphenylphosphine)palladium(II) chloride (0.11 g, 0.16 mmol), diisopropylethylamine (2.17 mL, 12.48 mmol) and THF (15 mL) at 75° C. for 2.5 d. The desired material was purified by gravity liquid chromatography using silica gel as the stationary phase and methylene chloride as the eluent. R_{f} (product): 0.59. An additional purification was performed using gravity liquid chromatography using silica gel as the stationary phase and a mixture of 1:1 diethyl ether/hexanes as the eluent. R_{f}=0.54. The reaction afforded 0.47 g (57% yield) of the desired compound as a white solid. IR (KBr) 3426.87, 2941.49, 2828.66, 2200.00, 1720.89, 1597.73, 1487.07, 1463.09, 1433.24, 1275.68, 1245.54, 1167.90, 1102.30, 1018.13, 853.62, 753.68, 691.05, 474.58 cm⁻¹. ¹H NMR (400 MHz, CDCl₃) δ 7.80 (ABq, J=8.7 Hz, Δν=159.91 Hz, 4H), 7.52 (dd, J=7.6, 1.8, 1H), 7.36 (td J=7.4, 1.7 Hz, 1H), 6.98 (td, J=7.5, 1.0 Hz, 1H), 6.94 (dd, J=8.4, 0.7 Hz, 2H), 3.95 (s, 6H). ¹³C NMR (100 MHz, CDCl₃) δ 167.05, 160.50, 134.09, 132.88, 131.95, 130.73, 129.99, 129.84, 129.69, 128.76, 120.95, 112.31, 111.14, 93.06, 89.29, 56.26, 52.61. HRMS Calcd C₁₇H₁₄O₃: 266.0943. Found: 266.0945.

4-(2′-Methoxyphenylethynyl)benzoic acid (133). To a 100 mL round bottom flask equipped with a magnetic stirbar was added 132 (0.30 g, 1.16 mmol), LiOH (0.14, 5.82 mmol), methanol (18 mL), methylene chloride (10 mL), and water (6 mL).^{[34]} The reaction mixture was allowed to stir at room temperature for 2 d. The reaction was quenched with water and extracted with methylene chloride (3×). The yellow aqueous phases were combined and acidified to pH 3 whereupon a white solid precipitated. The solid material was collected on a fritted funnel. No further purification was needed. The reaction afforded 0.28 g (97% yield) of the desired material. IR (KBr) 3445.36, 2962.62, 2829.10, 2659.63, 2536.38, 2212.84, 1681.14, 1604.93, 1488.82, 1457.92, 1425.90, 1317.19, 1297.57, 1278.77, 1244.42, 1178.84, 1.098.43, 1016.26, 954.64, 858.43, 757.58, 697.86, 554.07 cm⁻¹. ¹HNMR (400 MHz, d-DMSO) δ 13.00 (br s, 1H), 7.80 (ABq, J=8.2 Hz, Δν=135.77 Hz, 4H), 7.52 (dd, J=7.5, 1.7 Hz, 1H), 7.42 (td, J=7.7, 1.7 Hz, 1H), 7.12 (d, J=8.4 Hz, 1H), 7.00 (td, J=7.4, 0.6 Hz, 1H), 3.33 (s, 3H). ¹³C NMR (100 MHz, d-DMSO) δ 167.59, 160.67, 134.09, 132.20, 131.78, 131.27, 130.43, 127.88, 121.43, 112.32, 111.60, 93.08, 89.81, 56.61. HRMS Calcd C₁₆H₁₂O₃: 252.0786. Found: 252.0782.

### REFERENCES

[1] J. M. Tour, Acc. Chem. Res. 2000, 33, 791-804.
[2] M. A. Reed, J. M. Tour, Sci. Am. 2000, 282(6), 86-93.
[3] Atomic and Molecular Wires, Vol. 341 (Eds.: C. Joachim, S. Roth) NATO Applied Sciences, Kluwer: Boston, 1997.
[4] Molecular Electronics: Science and Technology, Vol. 852 (Eds.: A. Aviram, M. Ratner) Annal. New York Acad. Sci., 1998.
[5] Advances in Chemistry, Series 240, Molecular and Biomolecular Electronics (Ed.: R. R. Birge) American Chemical Society, 1994.
[6] C. Joachim, J. K. Gimzewski, A. Aviram, Nature 2000, 408, 541-548.
[7] D. Goldhaber-Gordon, M. S. Montemerlo, J. C. Love, G. J. Opiteck, J. C. Ellenbogen, Proc. IEEE 1997, 85, 521-540.
[8] A. Aviram, M. A. Ratner, Chem. Phys. Lett. 1974, 29, 277-283.
[9] J. K. Gimzewski, C. Joachim, Science 1999, 283, 1683-1688.
[10] L. A. Bumm, J. J. Arnold, M. T. Cygan, T. D. Dunbar, T. P. Burgin, L. Jones II, D. L. Allara, J. M. Tour, P. S. Weiss, Science 1996, 271, 1705-1707.
[11] M. A. Reed, C. Zhou, C. J. Muller, T. P. Burgin, J. M. Tour, Science 1997, 278, 252-254.
[12] C. Zhou, M. R. Deshpande, M. A. Reed, L. Jones II., J. M. Tour, Appl. Phys. Lett. 1997, 71, 611-613.
[13] J. Chen, M. A. Reed, A. M. Rawlett, J. M. Tour, Science 1999, 268, 1550-1552.
[14] M. A. Reed, J. Chen, A. M. Rawlett, D. W. Price, J. M. Tour, App. Phys. Lett., in press.
[15] (a) S. Takahashi, Y. Kuroyama, K. Sonogashira, N. Hagihara, Synthesis 1980, 627-630. (b) R. D. Stephens, C. E. Castro, J. Org. Chem. 1963, 28, 3313-3315. (c) J. Suffert, R. Ziessel, Tetrahedron Lett. 1991, 32, 757-760. (d) J. Blum, W. Baidossi, Y. Badrieh, R. E. Hoffmann, H. Schumann, J. Org. Chem. 1995, 60, 4738-4742.
[16] D. L. Pearson, J. M. Tour, J. Org. Chem. 1997, 62, 1376-1387.
[17] R. D. Adams, T. Barnard, A. Rawlett, J. M. Tour, Eur. J. Inorg. Chem. 1998, 429-431.
[18] J. M. Seminario, A. G. Zacarias, J. M. Tour, J. Am. Chem. Soc. 1998, 120, 3970-3974.
[19] N. Satyamurthy, J. R. Barrio, G. T. Bida, M. E. Phelps, Tetrahedron Lett. 1990, 31, 4409-4412.
[20] L. Jones II., J. S. Schumm, J. M. Tour, J. Org. Chem. 1997, 62, 1388-1,410.
[21] D. L. Allara, T. D. Dunbar, P. S. Weiss, L. A. Bumm, M. T. Cygan, J. M. Tour, W. A. Reinerth, Y. Yao, M. Kozaki, L. Jones II., Anna. N.Y. Acad. Sci., Molecular Electronics: Science and Technology; Aviram, A.; Ratner, M., Eds.; Ann. N.Y. Acad. Sci., 1998, Vol. 852, pp. 349-370.
[22] (a) R. Brown, W. E. Jones, A. R. Pinder, J. Chem. Soc. 1951, 2123-2125. (b) F. G. Bordwell, W. A. Hewett, J. Org. Chem. 1957, 22, 980-981.
[23] J. M. Tour, M. Kozaki, J. M. Seminario, J. Am. Chem. Soc. 1998, 120, 8486-8493.
[24] (a) G. W. Gribble, R. M. Leese, Synthesis 1977, 172-176. (b) G. W. Gribble, W. J. Kelly, S. E. Emery, Synthesis 1978, 763-765. (c) G. W. Gribble, C. F. Nutaitis, Tetrahedron Lett. 1985, 6023-6026.
[25] M. A. Reed, Proceedings of the IEEE: Special Issue on Nanoelectronics 1999, 87, 652-658.
[26] (a) Y. Yao, J. M. Tour, Macromolecules 1999, 32, 2455-2461. (b) J. J. S. Lamba, J. M. Tour, J. Am. Chem. Soc. 1994, 116, 11723-11736.
[27] G. A. Olah, M. Arvanaghi, L. Ohannesian, Synthesis 1986, 770-772.
[28] M. Moroni, J. Le Moigne, T. A. Pham, J.-Y. Bigot, Macromolecules, 1997, 30, 1964-1972.
[29] J. M. Seminario, A. G. Zacarias, J. M. Tour, J. Am. Chem. Soc. 2000, 122, 3015-3020.
[30] S. Cacchi, G. Fabrizi, L. Moro, J. Org. Chem. 1997, 62, 5327-5332 and references therein.
[31] R. Appel, R. Kleinstück, K.-D. Ziehn, Angew. Chem., Int. Ed. Engl. 1971, 10, 132.
[32] (a) C. P. Collier, E. W. Wong, M. Belohradsky, F. M. Raymo, J. F. Stoddart, P. J. Kuekes, R. S. Williams, J. R. Heath, Science 1999, 285, 391-394. (b) C. P. Collier, G. Mattersteig, E. W. Wong, Y. Luo, K. Beverly, J. Sampaio, F. M. Raymo, J. F. Stoddart, J. R. Heath, Science 2000, 289, 1172-1175. Heath et al, are currently evaluating the efficacy of 91 in their assembled system. (c) R. M. Metzger, B. Chen, U. Hopfner, M. V. Lakshmikantham, D. Vuillaume, T. Kawai, X. Wu, H. Tachibana, T. V. Hughes, H. Sakurai, J. W. Baldwin, C. Hosch, M. P. Cava, L. Brehmer, G. J. Ashwell, J. Am. Chem. Soc. 1997, 119, 10455-10466. (d) R. M. Metzger, Acc. Chem. Res. 1999, 32, 950-957.
[33] B. C. Ranu, D. C. Sarkar, R. Chakraborty, Synth. Comm. 1992, 22, 1095-1099.
[34] E. J. Corey, I. Székely, C. S. Shiner, Tetrahedron Lett. 1977, 3529-3533.
[35] E. Kilic, C. Tuzun, Org. Prep. Proced., Int. 1990, 22(4), 485.
[36] D. S. Wulfman, C. F. Cooper, Synthesis 1978, 924-925.
[37] L. Kaczmarek, B. Nowak, J. Zukowski, P. Borowicz, J. Sepiol, A. Grabowska, J. Mol. Struct. 1991, 248, 189-200.
[38] (a) F. M. Romero, R. Ziessel, Tetrahedron Lett. 1995, 36, 6471-6474. (b) V. Benin, P. Kaszynski, M. Pink, V. G. Young, Jr., J. Org. Chem. 2000, 65, 6388-6397.
[39] B. J. Littler, Y. Ciringh, J. S. Lindsay, J. Org. Chem. 1999, 64, 2864-2872.
[40] For several background procedures that were used or modified for these studies, see: (a)C. H. Lee, J. S. Lindsey, Tetrahedron 1994, 50, 11427-11439. (b) Q. M. Wang, D. W. Bruce Synlett. 1.995, 1267-1268. (c) R. W. Wagner, T. E. Johnson, F. Li, J. S. Lindsey J. Org. Chem. 1995, 60, 5266-5273. (d) J. F. Nierengarten, C. Schall, J. F. Nicoud, Angew. Chem. Int. Ed. Engl. 1998, 37, 1934-1936. (e) A. D. Alder, F. R. Longo, J. D. Finarelli, J. Goldmacher, J. Assour, L. Korsakoff, J. Org. Chem. 1967, 32, 476. (f) R. G. Khoung, L. Jaquinod, K. M. Smith, Chem. Comm. 1997, 1057-1058.
[41] R. C. Jagessar, J. M. Tour, Org. Lett. 2000, 2, 111-113.
[42] W. B. Austin, N. Bilow, W. J. Kellegham, K. S. Y. Lau, J. Org. Chem. 1981, 46, 2280-2286.
[43] J. M. Tour, L. Jones II., D. L. Pearson, J. J. S. Lamba, T. P. Burgin, G. W. Whitesides, D. L. Allara, A. N. Parikh, S. Atre, J. Am. Chem. Soc. 1995, 117, 9529-9534.
[44] Y.-T. Tao, G. D. Hietpas, D. L. Allara, J. Am. Chem. Soc. 1996, 118, 6724-6735.
[45] C. Zhou, M. R. Deshpande, M. A. Reed, L. Jones II., J. M. Tour, Appl. Phys. Lett. 1997, 71, 611-613.
[46] J. M. Seminario, J. M. Tour, in Molecular Electronics. Science and Technology; Vol. 852 (Eds.: A. Aviram, M. Ratner, M.), Ann. N.Y. Acad. Sci., 1998, pp. 68-94.
[47] C. Zhou, “Atomic and Molecular Wires”, Ph.D. thesis, Yale University (1999).
[48] J. Chen, W. Wang, M. A. Reed, A. M. Rawlett, D. W. Price, J. M. Tour, Appl. Phys. Lett. 2000, 77, 1224-1226.
[49] J. M. Seminario, A. G. Zacarias, P. A. Derosa, J. Phys. Chem. A. in press.
[50] J. M. Seminario, A. G. Zacarias, J. M. Tour, J. Am. Chem. Soc. 1999, 121, 411-416.
[51] W. A. Reinerth, J. M. Tour, J. Org. Chem. 1998, 63, 2397-2400.
[52] W. A. Reinerth, T. P. Burgin, T. D. Dunbar, L. A. Bumm, J. J. Arnold, J. J. Jackiw, C. Zhou, M. R. Deshpande, D. L. Allara, P. S. Weiss, M. A. Reed, J. M. Tour, Polym. Mater., Sci. Engin. (Am. Chem. Soc., Div. Polym. Mater.), 1998, 78, 178-179.
[53] J. Chen, L. C. Calvet, M. A. Reed, D. W. Carr, D. S. Grubisha, D. W. Bennett, Chem. Phys. Lett. 1999, 313, 741-748.
[54] (a) P. D. Rao, S. Dhanalekshmi, B. J. Littler, J. S. Lindsey, J. Org. Chem. 2000, 65, 7323-7344. (b) D. T. Gryko, C. Clausen, K. M. Roth, N. Dontha, D. F. Bocian, W. G. Kuhr, J. S. Lindsey, J. Org. Chem. 2000, 65, 7345-7355. (c) D. T. Gryko, F. Zhao, A. A. Yasseri, K. M. Roth, D. F. Bocian, W. G. Kuhr, J. S. Lindsey, J. Org. Chem. 2000, 65, 7356-7362. (d) C. Clausen, D. T. Gryko, R. B. Dabke, N. Dontha, D. F. Bocian, W. G. Kuhr, J. S. Lindsey, J. Org. Chem., 2000, 65, 7363-7370. (e) J. Li, D. Gryko, R. B. Dabke, J. R. Diers, D. F. Bocian, W. G. Kuhr, J. S. Lindsey, J. Org. Chem. 2000, 65, 7379-7390.
[55] N. C. Greenham, R. H. Friend, Solid State Phys. 1995, 49, 1-149.
[56] C. W. Tang, S. A. VanSlyke, Appl. Phys. Lett. 1987, 51, 913-915.
[57] J. H. Burroughes, D. D. C. Bradley, A. R. Brown, R. N. Marks, K. Mackay, R. H. Friend, P. L. Burns, A. B. Holmes, Nature 1990, 347, 539-541.
[58] D. Braun, A. J. Heeger, Appl. Phys. Lett. 1991, 68, 1982-1984.
[59] F. Gamier, R. Hajlaoui, A. Yasser, P. Srivastava, Science 1994, 265, 1684-1686.
[60] G. Yu, K. Pakbaz, A. J. Heeger J. Electron. Mater. 1994, 23, 925-928.
[61] (a) I. H. Campbell, J. D. Kress, R. L. Martin, D. L. Smith, N. N. Barashkov, J. P. Ferraris, Appl. Phys, Lett. 1997, 71, 3528-3530. (b) I. D. Parker, J. Appl. Phys. 1994, 75, 1656-1666.
[62]I. H. Campbell, T. W. Hagler, D. L. Smith, J. P. Ferrais, Phys. Rev. Lett. 1997, 70, 1900-1903.
[63] I. H. Campbell, S. Rubin, T. A. Zawodzinski, J. D. Kress, R. L. Martin, D. L. Smith, N. N. Barashkov, J. P. Ferraris, Phys. Rev. B 1996, 54, 14321-14324.
[64] M. T. Cygan, T. D. Dunbar, J. J. Arnold, L. A. Bumm, N. F. Shedlock, T. P. Burgin, L. Jones II, D. L. Allara, J. M. Tour, P. S. Weiss, J. Am. Chem. Soc. 1998, 120, 2721-2732.
[65] Z. F. Xu, J. S. Moore, Angew. Chem., Int. Ed. Engl. 1993, 32, 1354-1356.
Scheme 1. Synthesis of unfunctionalized wire 4.
Scheme 2. Synthesis of molecular wire 16.
Scheme 3. Synthesis of two-barrier system 22.
Scheme 4. Syntheses of two-terminal molecular wires 24 and 28.
Scheme 5. Synthesis of three-terminal molecular wire 32.
Scheme 6. Synthesis of two-terminal wire with a methylene barrier.
Scheme 7. Synthesis of molecular scale wire 41 with one methylene barrier.
Scheme 8. Synthesis of two-terminal molecular wire 45 with one methylene barrier.
Scheme 9. Synthesis of two-terminal wire 48 with two methylene barriers.
Scheme 10. Synthesis of three-terminal molecular wire 50 with one methylene barrier.
Scheme 11. Syntheses of four-terminal wires 52 and 53, both with one methylene barrier.
Scheme 12. Syntheses of molecular wires 58 and 59, each containing two methylene barriers.
Scheme 13. Synthesis of molecular wire with ethylene barrier.
Scheme 14. Syntheses of one-terminal and two-terminal molecular wires 66 and 67, both containing two ethylene barriers.
Scheme 15. Synthesis of molecular scale device 70 and 71 and compound 73 for cyclic voltammetry experiments.
Scheme 16. Synthesis of molecular device 75.
Scheme 17. Synthesis of mono-nitro molecular device 78.
Scheme 18. Synthesis of mono-amino compound 81 and molecular wire 82.
Scheme 19. Synthesis of two-terminal molecular device 83.
Scheme 20. Synthesis of molecular device 86 with an isonitrile alligator clip.
Scheme 21. Synthesis of compound 91.
Scheme 22. Synthesis of nitro-amine biphenyl compound 95.
Scheme 23. Synthesis of bipyridyl compound 99.
Scheme 24. Syntheses of various porphyrin compounds.
Scheme 25. Syntheses of porphyrin intermediate 110, and porphyrins 111, 112, 113, and 114.
Scheme 26. Synthesis of four-terminal porphyrin 116.
Scheme 27. Syntheses of cyano-containing systems 118 and 120.
Scheme 28. Syntheses of pyridine system 122 and pyrimidine system 124.
Scheme 29. Synthesis of pyridine system 127.
Scheme 30. Syntheses of compounds 130 and 133.

FIG. 1. I(V) plot of 48 at 296 K, which shows NDR. The non-symmetric NDR effect may be due to the differences in the self-assembled versus metal-evaporated contacts on either side of the nanopore.

FIG. 2. Plot of current versus temperature of compounds 134²⁰ (3-ph) and 135⁴³ (2-ph) in the nanopore with a bottom contact (SAM-contact side) of gold and a top contact of titanium. Each nanopore contains ˜1000 molecules.

FIG. 3. I(V) characteristics of a Au-(70)-Au device at 60 K in the nanopore.

FIG. 4. Write, read, and erase sequences for 70 in the nanopore and its use as a one-bit random access memory.

FIG. 5. The mDRAM cell input and output that is constructed from 78 in the nanopore. The mDRAM was built into a circuit that had a transistor and a comparator (as do most commercial solid state DRAMs) and operation was at 300 K.

FIG. 6. Summary of the mNDR and mDRAM results obtained to date in the nanopore cell where σ is the conductance and Q is charge. “Inactive” and “Active” refer to the device properties wherein a large nonlinearity in the I(V) curve results upon application of a voltage.

FIG. 7. Schematic of a molecular device controller where a gate electrode could modulate the overlap in a molecule by preferring the more planar zwitterionic form.

FIG. 8. Illustration of the effect of incorporating a SAM (with a significant dipole moment) between a metal electrode and an organic material used in an organic electronic device (e.g. diode or transistor). The dipole of the monolayer can be used to manipulate the energy separation between the metal Fermi level and the electron polaron levels of the organic (φ^{e}). If is oriented appropriately as in SAM1, the decrease in the energy barrier, relative to the electron polaron levels, will increase electron injection into the device.

FIG. 9. Copper (SAM)/MEH-PPV/A1 diodes demonstrating improvement of charge injection from Cu using the NO₂ terminated SAM, 136. The current in the devices is dominated by hole injection from the Cu contact (the Al electrode is a poor electron injector) so the increased current from the Cu/SAM electrode (compared to the Cu electrode that does not bear a SAM) indicates improved injection from that contact. The MEH-PPV film thickness is 100 nm in both cases.

FIG. 10. Kelvin Probe current vs. substrate bias for a series of Au/SAM electrodes. The zero point of the current is significant. The shift of the zero current to positive bias indicates an increase in the effective work function of the metal electrode by that voltage, i.e. the effective work function of the Au-CN electrode is about 0.35 eV higher than Au. This increase in the work function leads to improved hole injection. Py=122, Bpy=124, CN=118, and NO₂=136

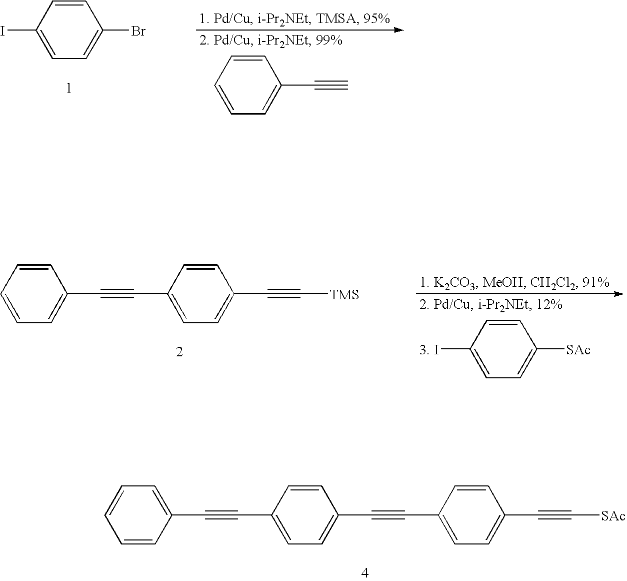

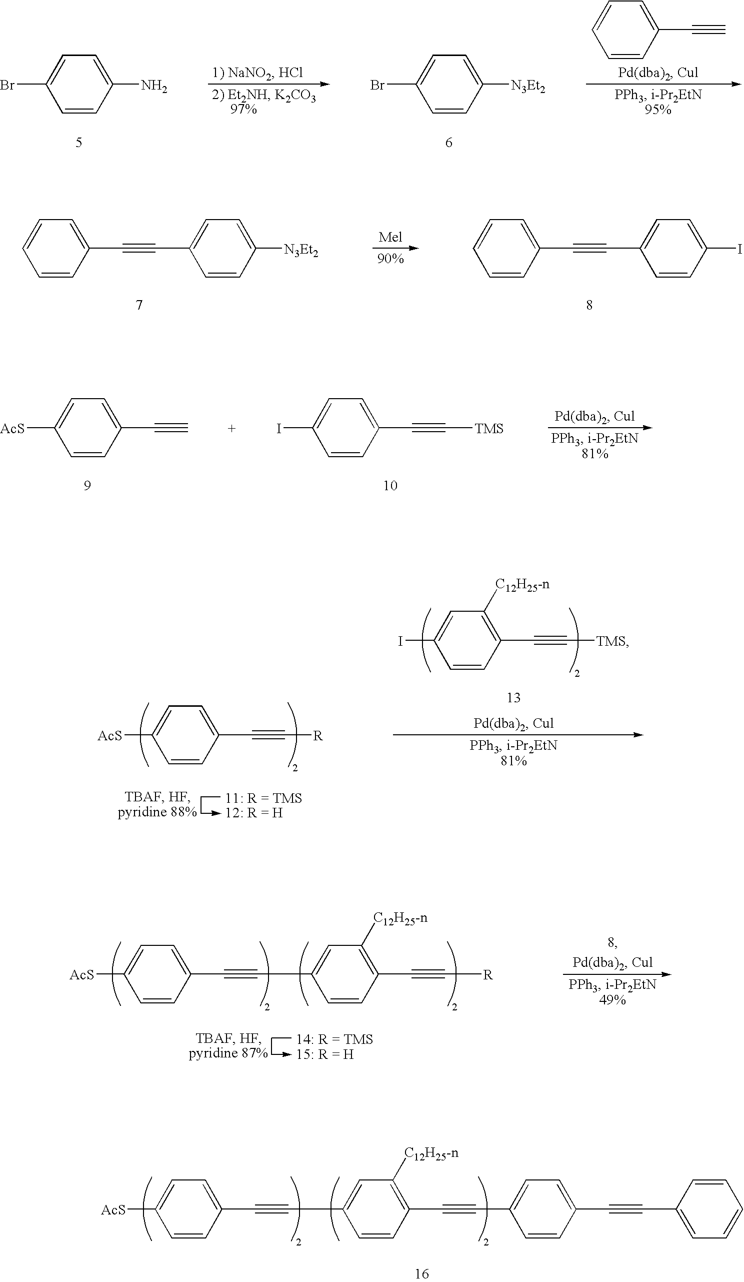

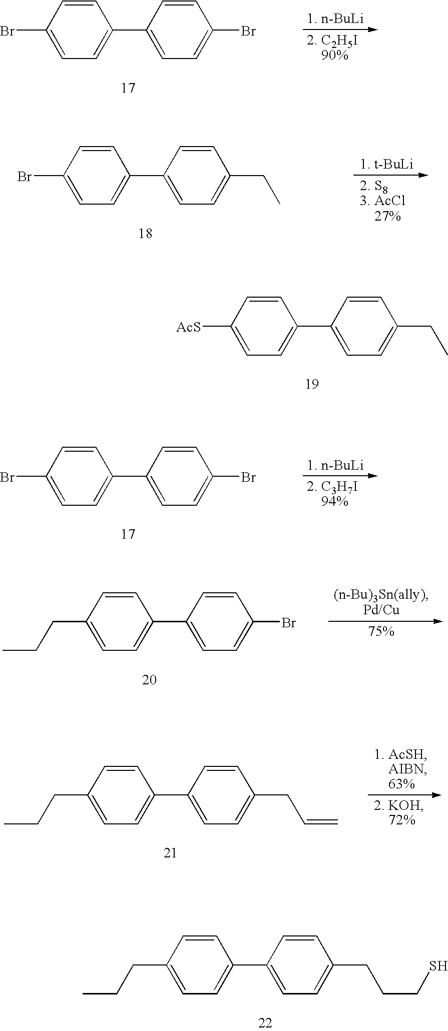

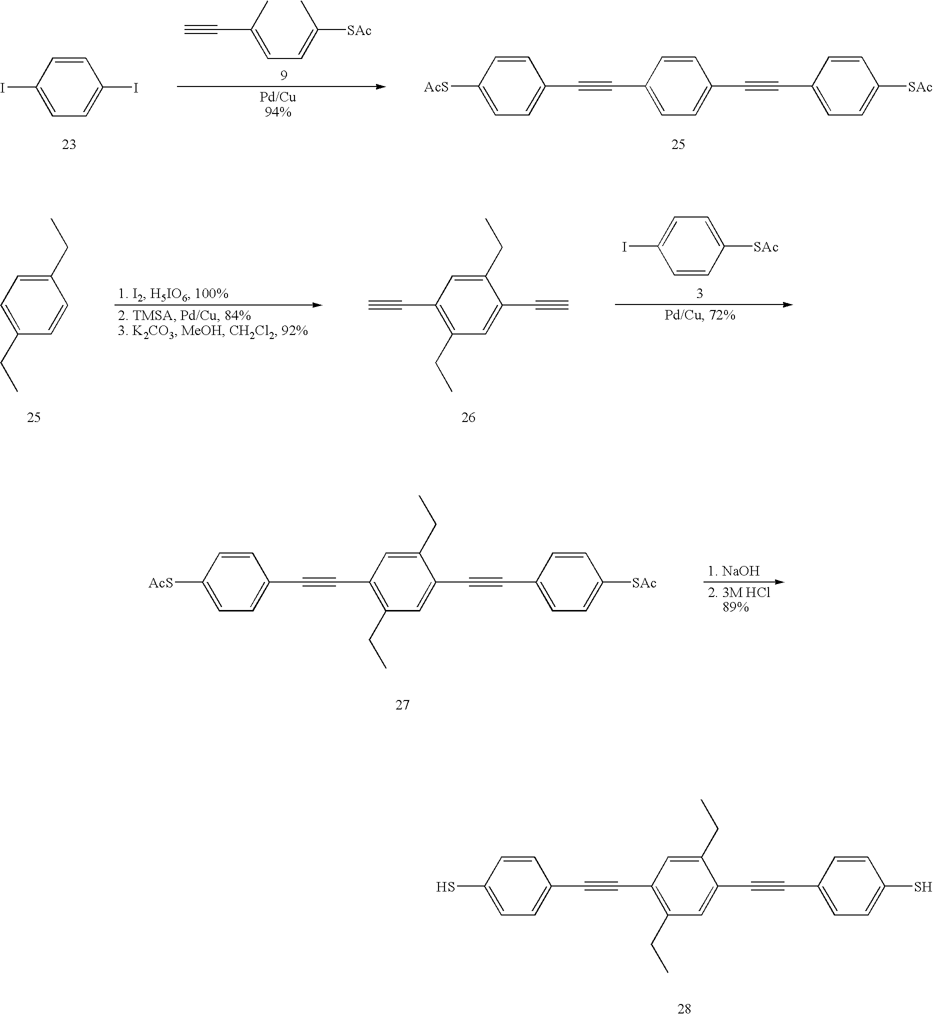

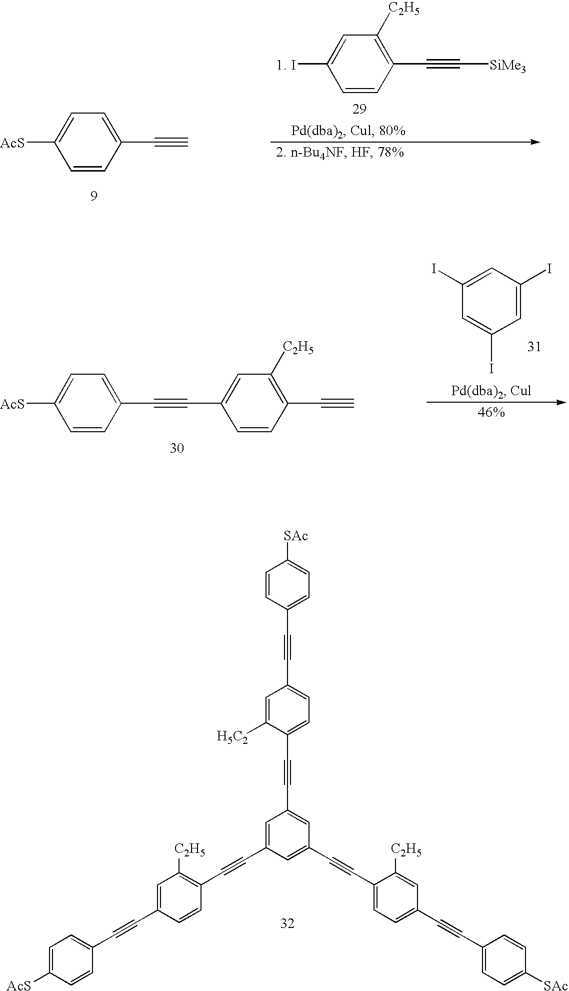

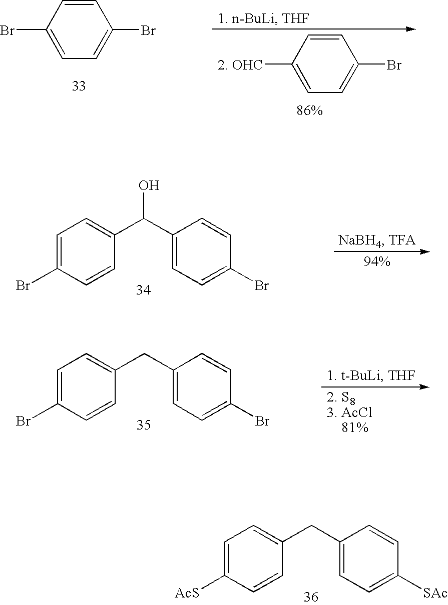

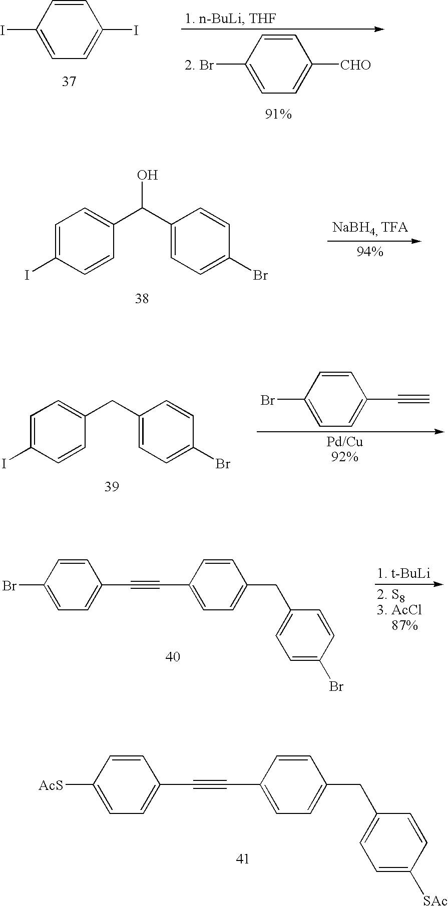

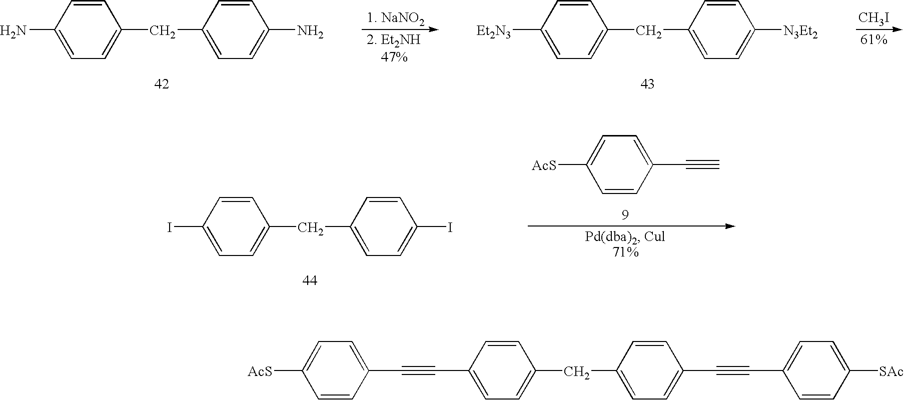

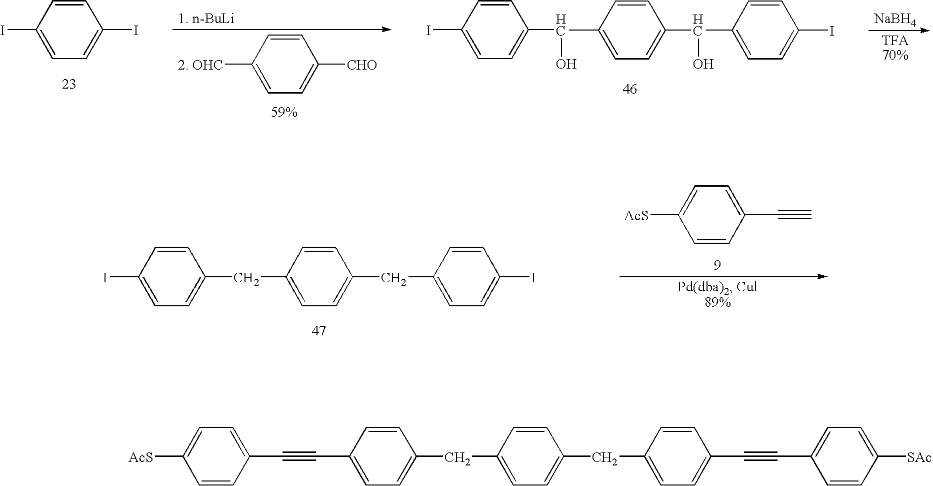

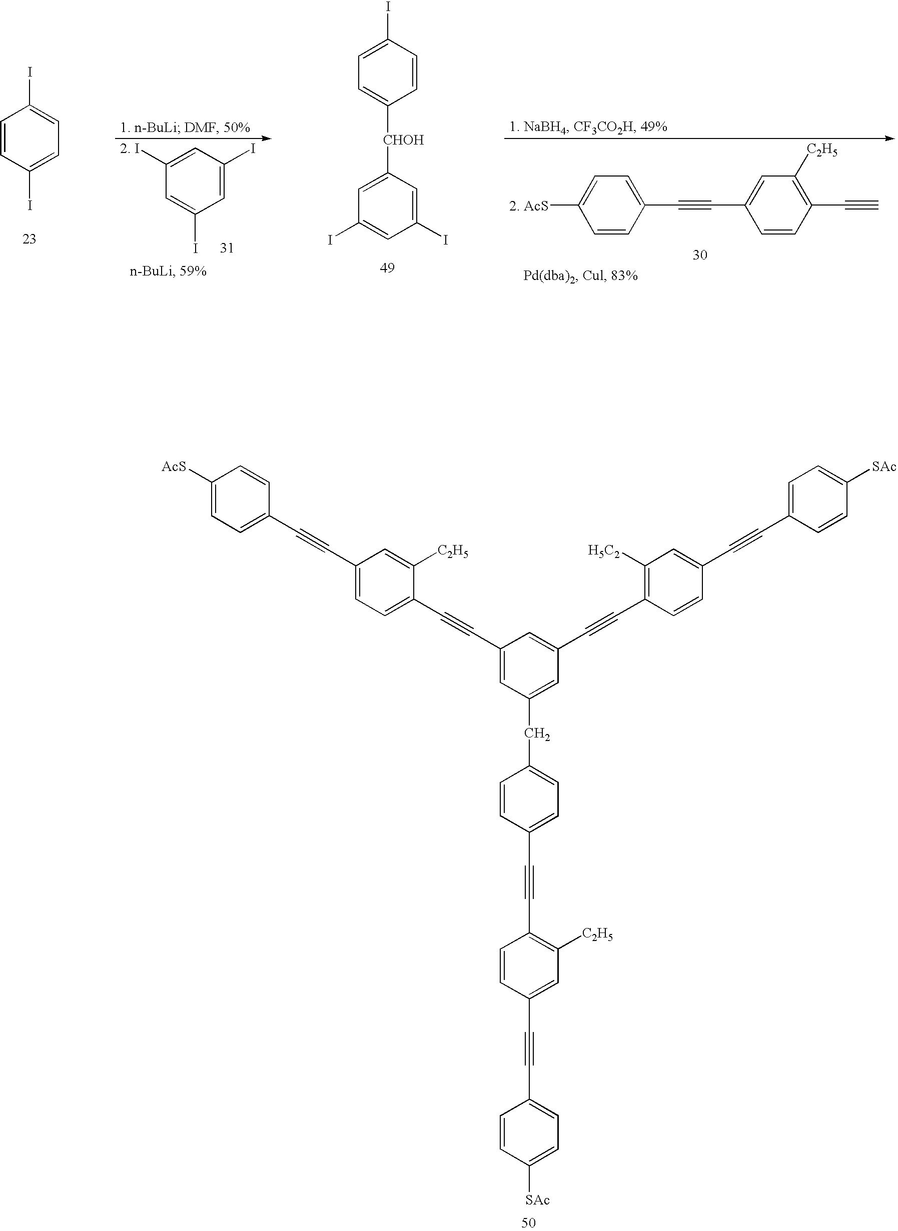

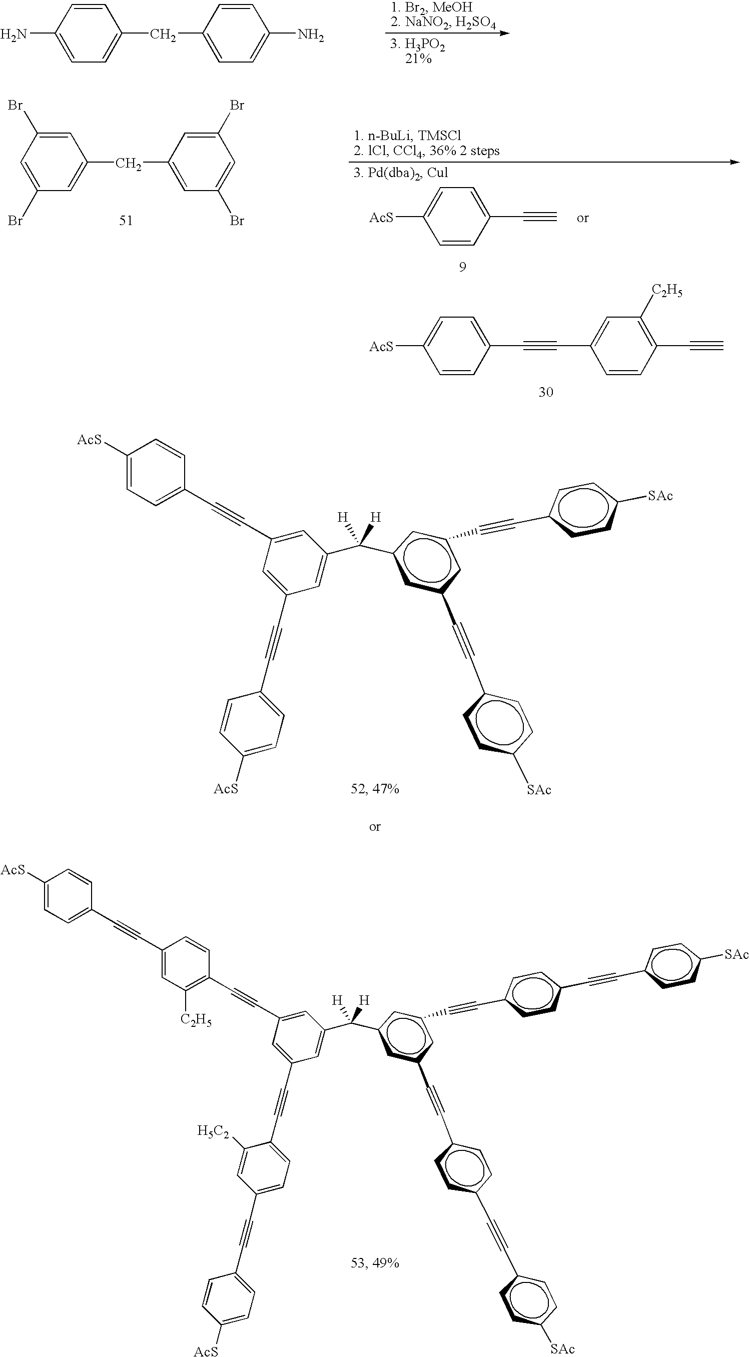

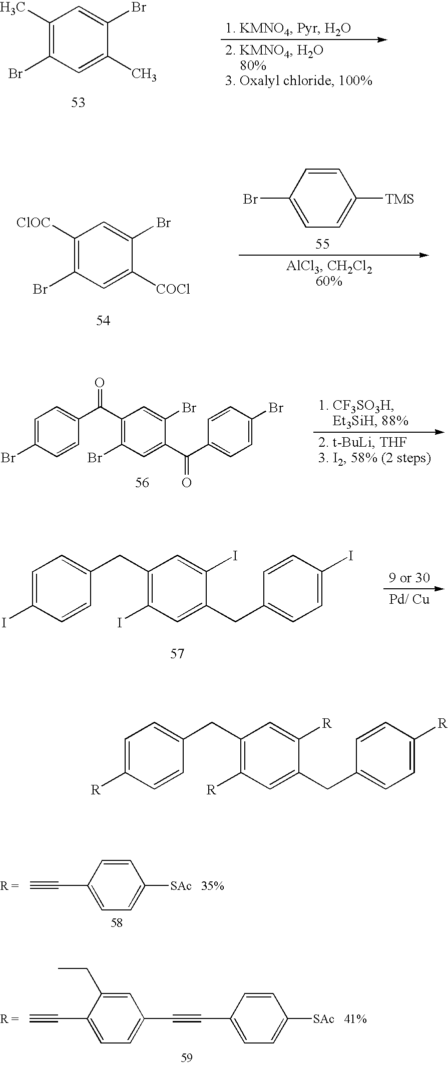

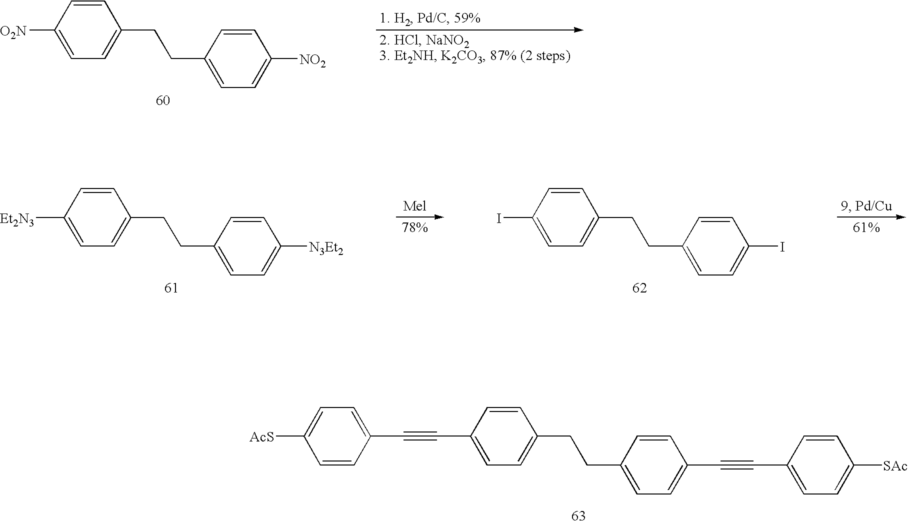

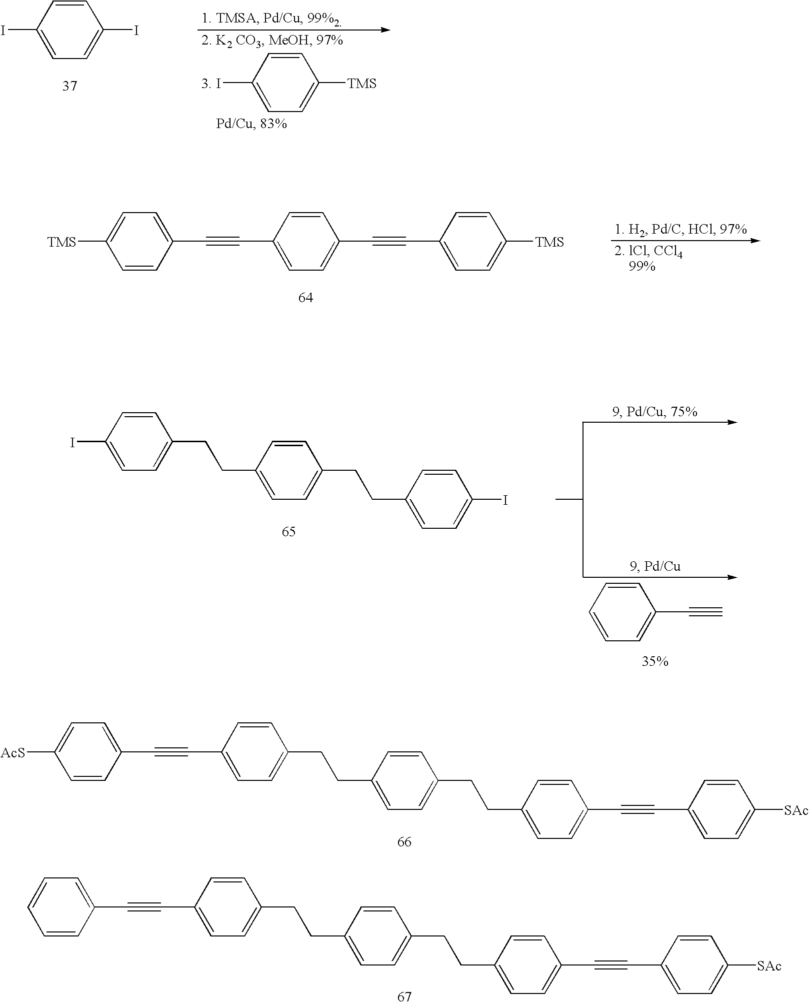

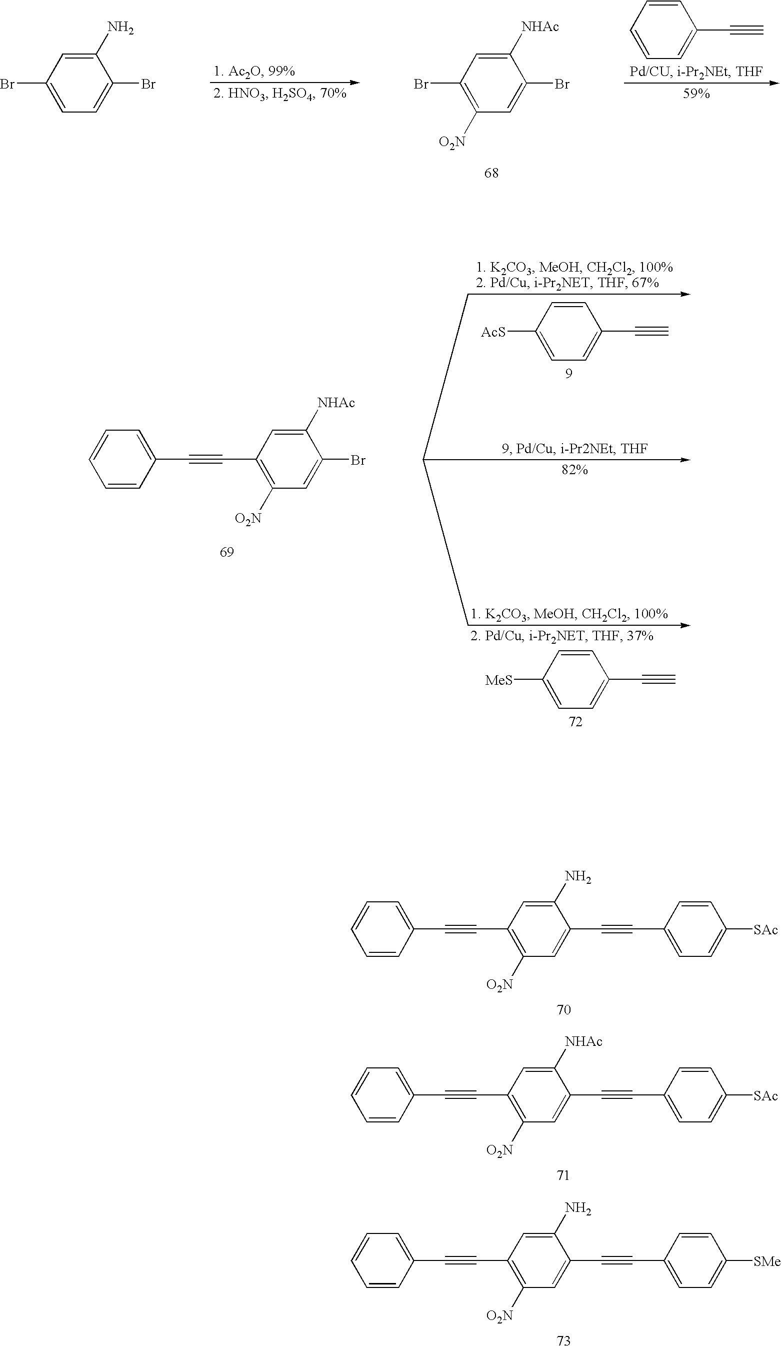

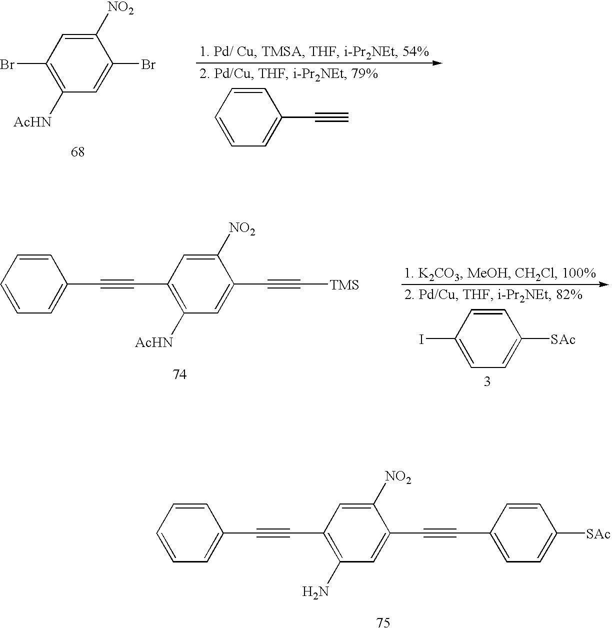

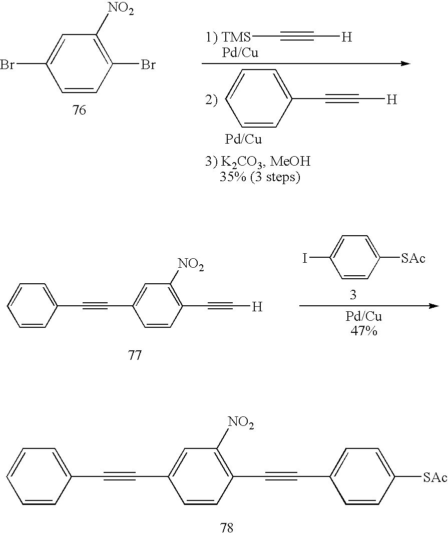

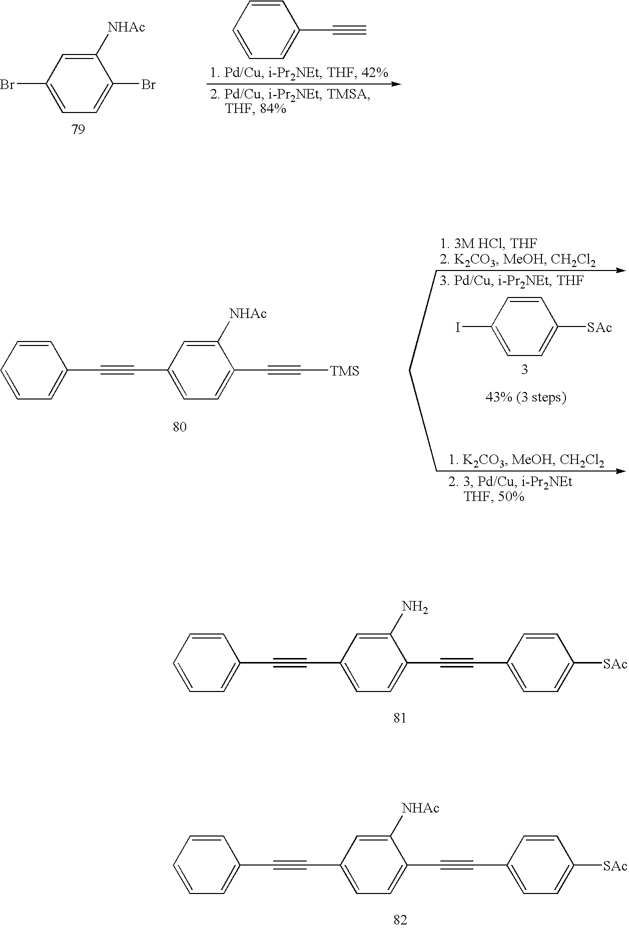

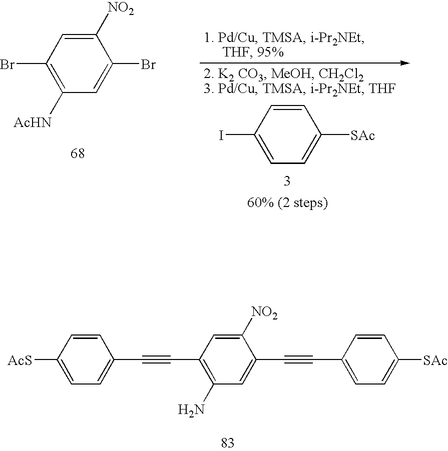

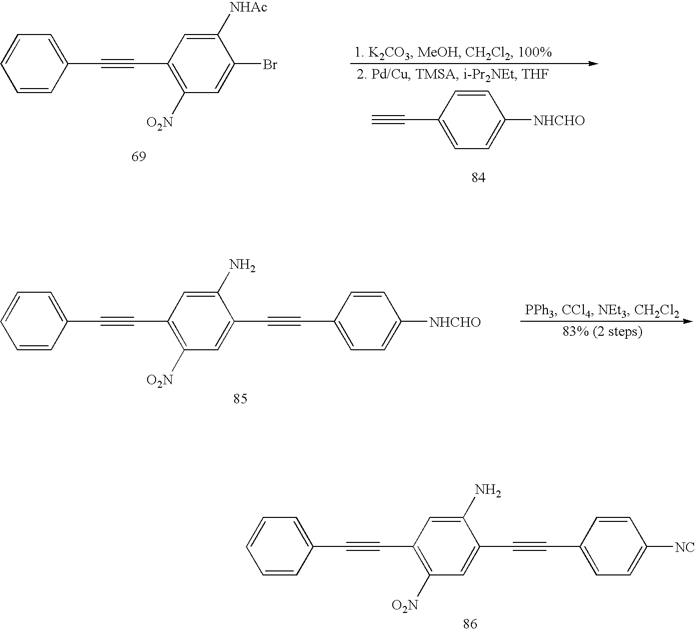

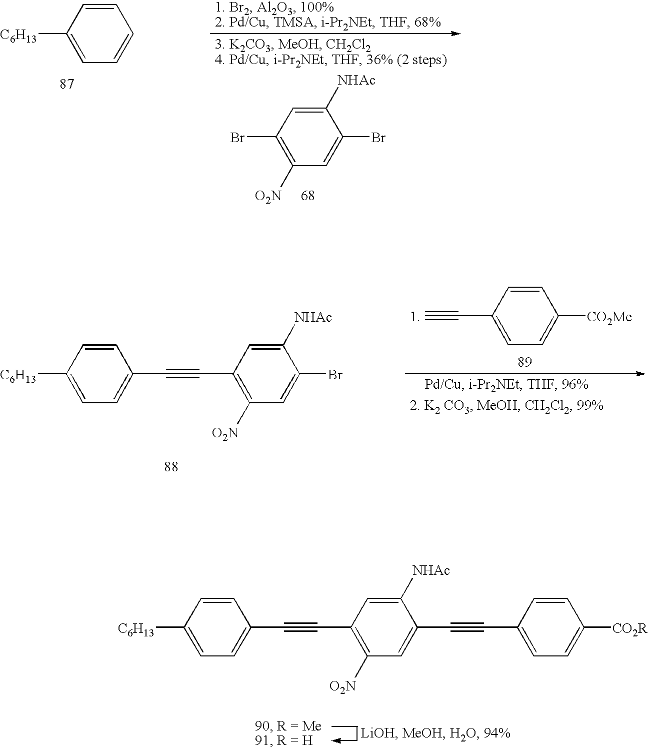

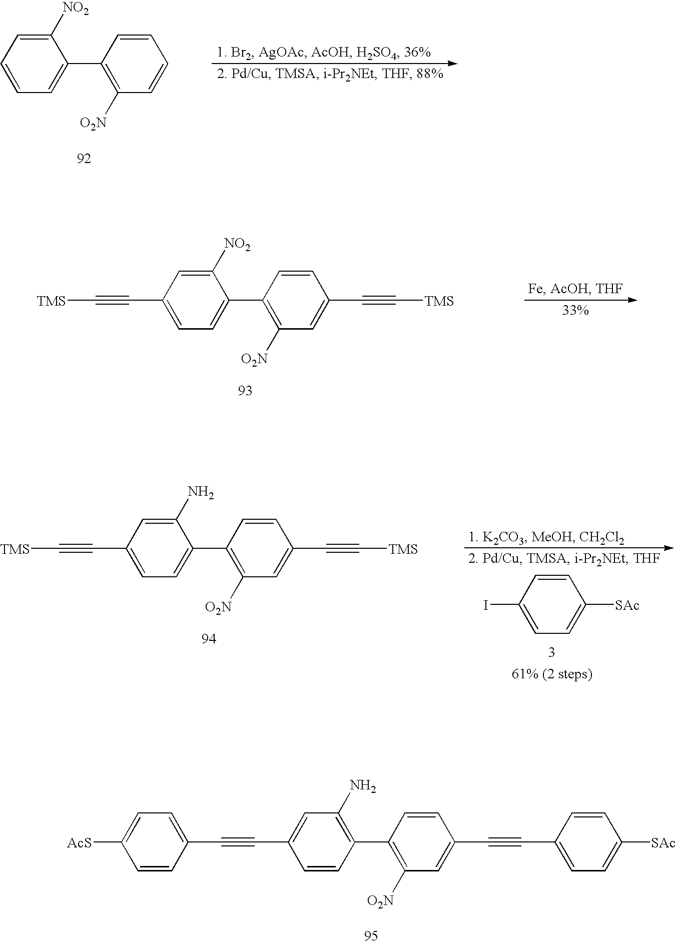

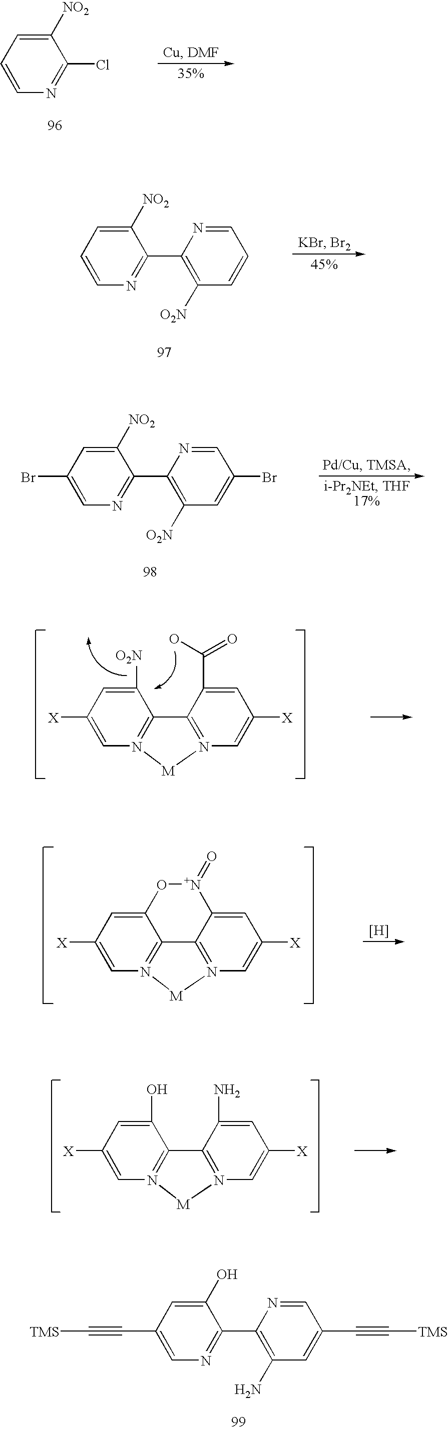

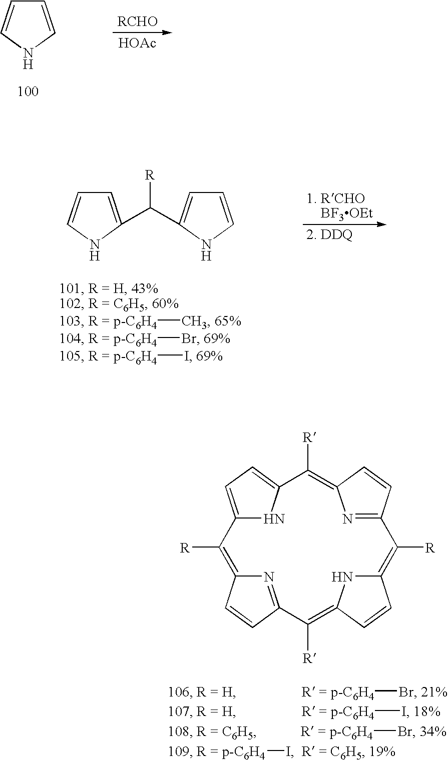

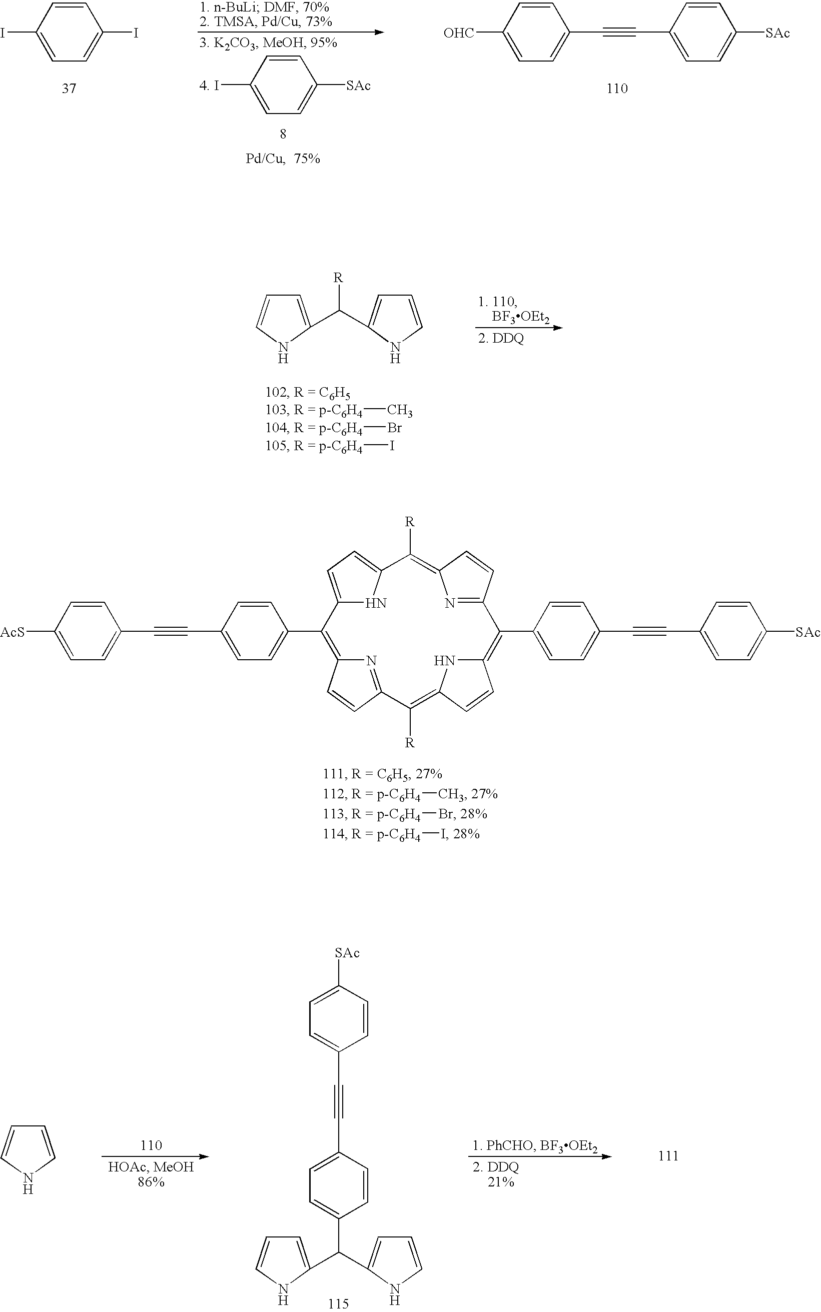

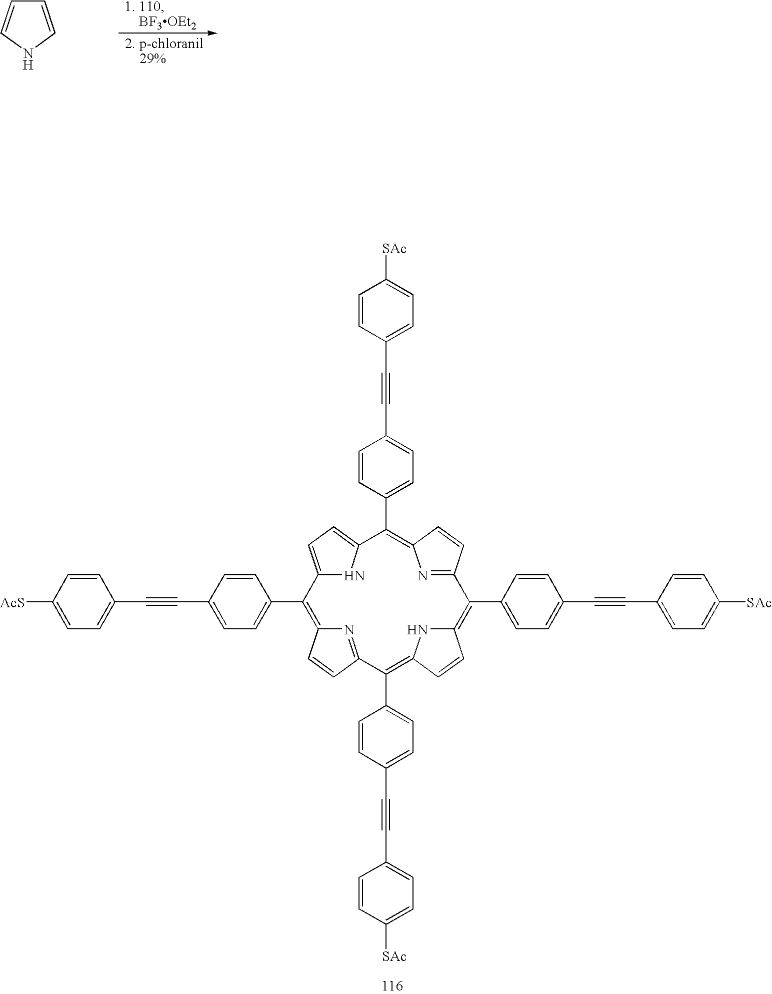

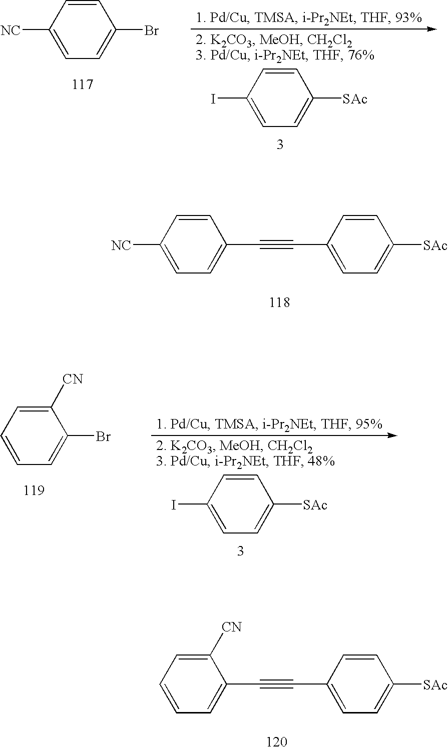

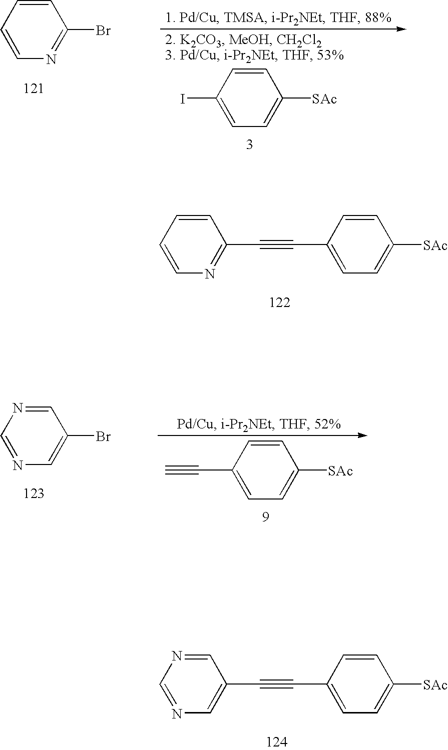

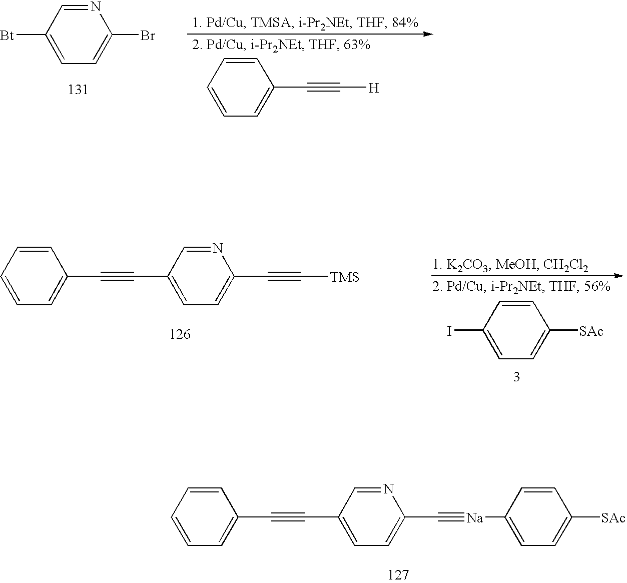

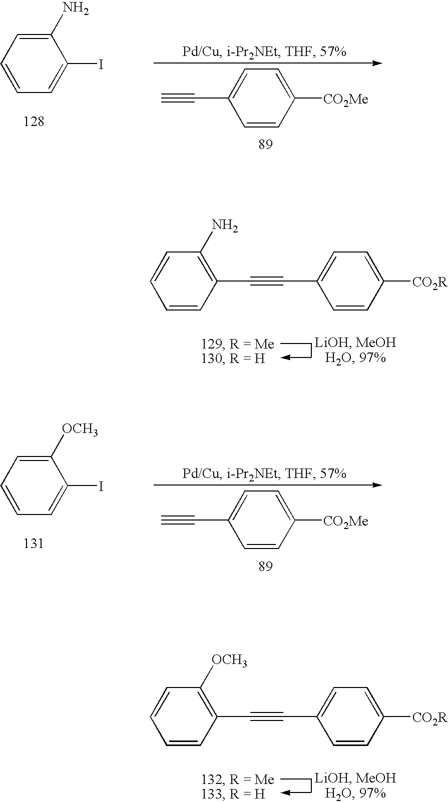

[image]

[image]

[image]

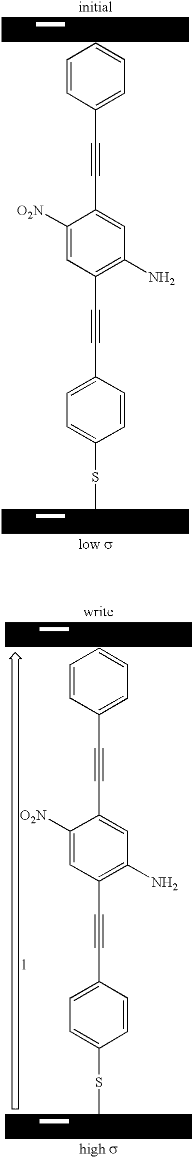

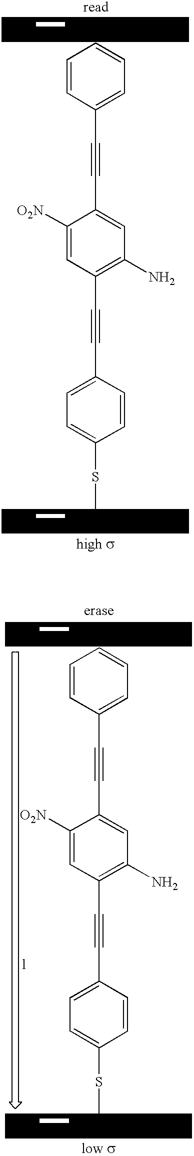

[image]

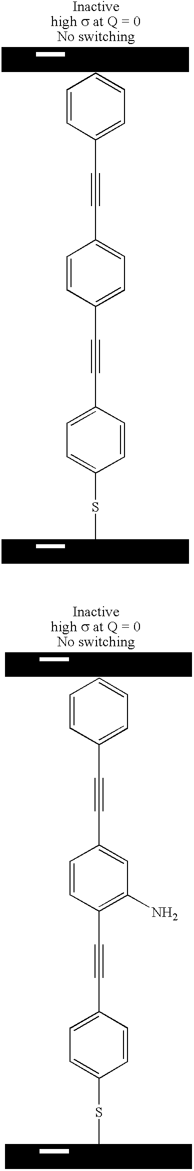

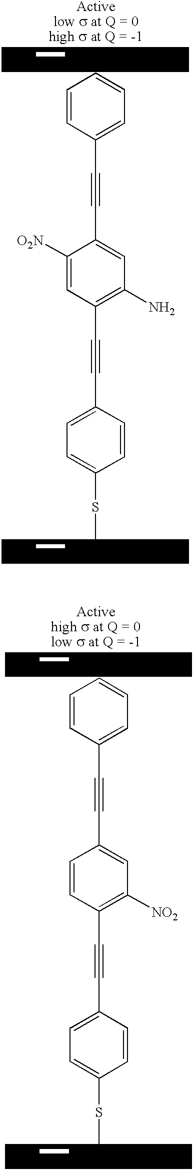

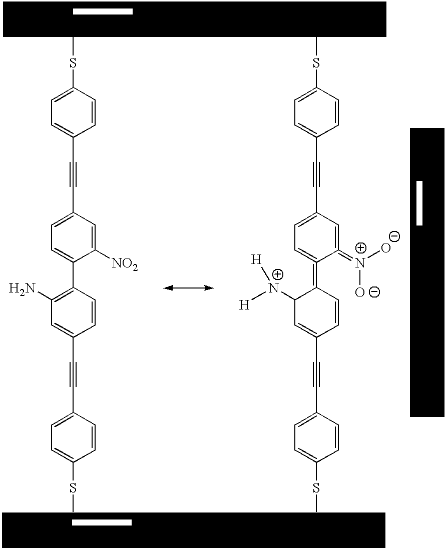

[image]

[image]

[image]

2. One type of molecule used in the MFET of the present invention, as drawn in FIGS. 1 and 2, is of the type wherein the conductance changes based on a drive more toward planarization induced by the preferably normally directed electric field. In FIGS. 1-3, —X—refers to molecular alligator clips of any of the numerous types available. Alternatively, the terminal aryls may simply be connected to the source and drain electrodes, i.e. direct carbon metal contact. The two alligator clips need not be the same. The disclosures of the following references describe alligator clips that may be used in the invention:
(a) Tour, J. M.; Jones, L., II; Pearson, D. L.; Lamba, J. S.; Burgin, T. P.; Whitesides, G. W.; Allara, D. L.; Parikh, A. N.; Atre, S. “Self-Assembled Monolayers and Multilayers of Conjugated Thiols, α,ω-Dithiols, and Thioacetyl-Containing Adsorbates. Understanding Attachments Between Potential Molecular Wires and Gold Surfaces,” J. Am. Chem. Soc. 1995, 117, 9529-9534. (b) Tour, J. M. “Conjugated Macromolecules of Precise Length and Constitution. Organic Synthesis for the Construction of Nanoarchitectures,” Chem. Rev. 1996, 96, 537-553. (c) Jones, L., II; Schumm, J. S.; Tour, J. M. “Rapid Solution and Solid Phase Syntheses of Oligo(1,4-phenylene-ethynylene)s With Thioester Termini: Molecular Scale Wires With Alligator Clips. Derivation of Iterative Reaction Efficiencies on a Polymer Support,” J. Org. Chem. 1997, 62, 1388-1410. (d) Pearson, D. L.; Tour, J. M. “Rapid Syntheses of Oligo(2,5-thiophene-ethynylene)s with Thioester Termini: Potential Molecular Scale Wires With Alligator Clips,” J. Org. Chem. 1997, 62, 1376-1387.

The two resonance forms of the molecule that are shown in FIG. 1 always exist, however, the form on the right is more planar, more conductive (due to more orbital overlap), and more of a contributor when a normally directed field is applied. Therefore, as the normally directed electric field is increased, the current flowing from the source to drain electrodes will increase in proportion to the number of molecules that are in the more planar configuration.

3. A second type of molecule used in the MFET of the present invention, shown in FIG. 3, is of the type that shows negative differential resistance (NDR). Molecules of this type are disclosed in the following references:
(a) Reed, M. M.; Chen, J.; Rawlett, A. M.; Tour, J. M. “Observation of a Large On-Off Ratio and Negative Differential Resistance in an Electronic Molecular Switch,” Filed Provisional Patent Sep. 20, 1999, Filed U.S. Non-Provisional Patent on Apr. 19, 2000 entitled “Molecular Scale Electronic Devices”. (b) Reed, M. A.; Bennett, D. W.; Chen, J.; Grubisha, D. S.; Rawlett, A. M.; Tour, J. M.; Zhou, C. “Prospects for Molecular Scale Devices” (A Molecular Current-Storage Memory), Provisional Patent Filed Sep. 30, 1999, −Filed U.S. Non-Provisional Patent on Apr. 19, 2000 entitled “Molecular Scale Electronic Devices”, Chen, J.; Reed, M. A.; Rawlett, A. M.; Tour, J. M. “Observation of a Large On-Off Ratio and Negative Differential Resistance in an Electronic Molecular Switch,” Science 1999, 286, 1550-1552.
   Alternatively, this second molecule may be of a type showing memory, as described in Reed, M. A.; Chen, J.; Rawlett, A. M.; Price, D. W.; Tour, J. M. “Molecular Random Access Memories”, App. Phys. Lett. 2000, 78, 3735-3737.

In this way, the electric field would make the molecule more (or less electrophilic), thereby causing it to gain (or lose) an electron, and thereby dramatically modifying its conductivity. Depending on the molecular structure, the applied field may lessen, or increase conductivity flowing from the source to the drain electrode.

4. Large conductivity changes have been demonstrated in the molecules: 2′-amino-4,4′-diethynylphenyl-5′-nitro-1-benzenethiolate and 4,4′-diethynylphenyl-2′-nitro-1-benzenethiolate using 2-terminal systems. Chen, J.; Wang, W.; Reed, M. A.; Rawlett, A. M.; Price, D. W.; Tour, J. M.; “Room-Temperature Negative Differential Resistance in Nanoscale Molecular Junctions”, Appl. Phys. Lett. 2000, 77, 1224-1226. These two molecules undergo large conductivity changes when gaining or losing electrons. But with these molecules being used in an MEET in accordance with this invention, the sudden gain or loss of electrons may be induced by the control electrode while a constant voltage is being applied between the source and drain electrodes. Additional molecules exhibiting such large changes in conductivity or lesser but still acceptable changes in conductivity have already been synthesized. The largest effect is expected in molecules, such as those listed in FIG. 4(a), having a heteroatomic group branching off of the main chain, from a location other than the molecule ends, thereby affording an intense dipole that is not parallel to the conductive axis of the molecule. However, even molecules like those listed in FIG. 4(b) which do not have a heteroatomic group branching off of the main chain are polarizable enough for this effect to occur. Specifically, the π electron cloud of these latter molecules will be affected by the field of the control electrode, thereby changing the conformation along the source-to-drain axis. and exhibit changes in conductivity due to a change in conformation or charge state are shown in FIG. 4.

The lists of molecules in FIGS. 4(a) and 4(b) are meant to serve as a guide for the purpose of providing examples and are not meant to be a comprehensive list of molecules that could be used in the MFETs of the present invention. Given the large degree of flexibility that can be obtained during molecular synthesis, we expect that new classes of molecules that exhibit the conductivity and other properties required for MFETs devices will be developed by those skilled in the art. Appropriate conductive molecules will have a high degree of unsaturated or n electron density between the source and the drain. Additionally, such molecules will be polarizable. As a result, the field induced by the control electrode will have an influence on the conductance of these molecules between the source and the drain.

5. While the input and output characteristics of the device may differ considerably depending on the choice of active molecular components, all MFETs will exhibit a family of output curves where the magnitude of the drain-to-source current, IDS, depends on the value of the voltage applied to the control electrode, and hence the strength of the directed field. As noted above, it is preferred that the field be directed normally to the molecule or molecules disposed between the source and drain electrodes. In an alternative embodiment, the field may be varied from the normal orientation toward but short of a parallel orientation, with the magnitude of the drain-to-source current decreasing as the orientation varies from the normal. In the limit of a single-molecule MFET, the family of curves reduces to a single on-off transition at a drain-to-source voltage, V_{DS}, that can be modulated by the magnitude and o the angle of the applied electric field.

Such input and output characteristics are shown in FIG. 5, which are plotted for a MEET that is fabricated from a monolayer of molecules similar to those in FIG. 1. These molecules exhibit an increase in conductivity as they undergo a change in their conformation from a non-planar to planar form. In a two terminal device, the parallel-directed applied electric field due to V_{DS} induces this conformational change, which is observed by a sharp increase in I_{DS} at a specific value of V_{DS}. In the MFET where voltage is applied to the control electrode to produce a normally-directed electric field, this will result in an increase in the fraction of molecules that undergo the non-planar to planar conformational change for any value of V_{DS}. This in turn will result in output characteristics where I_{DS} effectively turns on at lower values of V_{DS} with increasing values of applied control voltage, V_{C}. The resulting output characteristics will be similar to those exhibited by triode vacuum tubes and can be utilized in electronic applications involving memory and logic. Moreover, it is possible to design molecules where the change in conformation or charge state will result in MFETs that have output characteristics more similar to conventional semiconductor transistors.

6. There are many alternatives that are well suited for practical implementation of devices with the geometry shown in FIGS. 1-3. These include top-down lithographically defined structures as well as structures that use bottom-up synthetic approaches that integrate the molecules into or onto nanometer-scale components such as metallic nanowires or carbon nanotubes. In this and the following example, we will provide process flows that could be implemented as drawn or with modifications that could be incorporated by someone skilled in the art of nanofabrication and/or nanoparticle synthesis.

An example of a top-down fabrication process that utilizes semiconductor manufacturing principles such as lithography, metal deposition, and dielectric deposition to define the MFET device structure on planar (or nearly planar) substrates of arbitrary composition (silicon, compound semiconductors, glass, plastic, ceramic, etc.) is outlined in FIG. 6. Because the lengths of the molecules are on the order of 1-3 nm, the normal directed field penetration between the source and drain contacts is very small (on the order of angstroms). The control electrode should be in contact with the dielectric surrounding the molecules and located adjacent to the length of the molecule. The dielectric must have good insulating properties. Small deviations in this will result in near-normal electric fields and will also induce molecule conformation or changing, but to a lesser extent than normally-directed electric fields.

In order to fabricate a lithographically defined planar structure where the control electrode is in very close proximity to the control dielectric, the control electrode may be defined using a self-aligned metal deposition process. The process flow would be as follows:

(1) Define the bottom source metal contact using metal etch or liftoff process on an insulating substrate. Nanometer-scale dimensions can be achieved via optical, x-ray, or electron-beam lithography. Metal liftoff will be implemented using single or double layer photoresist with a re-entrant profile. Metal etch will be implemented using a soft or hard mask followed by wet chemical or dry plasma etching. The source metal must be selected to be compatible with the molecule self-assembly process.

(2) Deposit a dielectric such as silicon dioxide or silicon nitride to define the molecular active areas of the device. The deposition process must be compatible with maintaining the integrity of the underlying metal for following molecule self-assembly process.

(3) Define a small pore aligned to the bottom source electrode using lithographic techniques. Remove the dielectric in the pore openings using wet chemical or dry plasma etching. Dry chemistries will be required to define nanometer-scale pores. The pore etch chemistry must be compatible with the molecule self-assembly processes.

(4) Deposit the molecular monolayer in the pore using an appropriate molecule self-assembly technique. Examples include directed self-assembly and LB assembly.

(5) Deposit the drain metal at room temperature or reduced temperatures via physical or chemical vapor deposition techniques (thermal, electron beam, sputtering, etc.). The thickness of the metal should be sufficient to permit a self-aligned control contact to be defined.

(6) Define drain contact using lithography and wet or dry etch of the drain contact metal. The drain contact must overlap the molecule pore layer.

(7) Remove the dielectric using a wet or dry isotropic etch to undercut the dielectric below the drain contact metal.

(8) Deposit the control electrode metal using physical or chemical vapor deposition processes. The process must be designed to provide an electrical open circuit between the drain and control electrode contact. The control electrode can be defined prior to metal deposition using a metal liftoff process or following metal deposition using a metal etch process.

7. An example of a bottom-up fabrication process that utilizes a template replication to synthesize metal-molecule-metal nanowires that can be integrated into electronic, optoelectronic, and microelectromechanical circuits using directed assembly techniques is outlined in FIG. 7. The same constraints on the active molecular area and the control electrode that were described also apply when considering this synthetic technique. The process flow would be as follows:
(1) Grow insulating dielectric tubules in mesoporous templates with pore diameters that range from 15 nm to 300 nm in diameter. These tubules can be grown using sol-gel or chemical vapor deposition processes. The templates must be selected to provide the mechanical rigidity to withstand the dielectric deposition process and to minimize impurity contamination of the dielectric. The mesoporous templates should also have a high pore density.

(2) Deposit the source metal inside the dielectric tubules/mesoporous template using electro- or electroless deposition techniques. The source metal must be selected to be compatible with the molecule self-assembly. Annealing the metal in a vacuum furnace or rapid thermal annealing system may also be required to produce single crystal metal wires that will provide low-defect density self assembled monolayers.

(3) Deposit the molecular monolayer in the pore using a molecule self-assembly technique that is compatible with this synthetic approach, such as that described in “Template Synthesis of Metal Nanowires Containing Monolayer Molecular Junctions”, Jeremiah K. N. Mbindyo, Thomas E. Mallouk, Irena Kratochvilova, Baharak Razavi, Theresa S. Mayer, and Thomas N. Jackson, to appear in the Journal of American Cancer Society.

(4) Deposit the drain metal inside the dielectric tubules/mesoporous template and on top of the molecular monolayer using electro- or electroless deposition techniques.

(5) Release the insulated metal-molecule-metal nanowires from the mesoporous membrane by chemical etching and suspend the nanowires in a dielectric medium that is compatible with directed self-assembly techniques.

(6) Place the nanowires onto an arbitrary substrate using fluidic, electrofluidic, capillary forces, etc. directed assembly techniques and integrate the control electrode using lithographically defined electrodes or through assembly of a second layer of crossing nanowires.

While the present invention is described above in connection with preferred or illustrative embodiments, these embodiments are not intended to be exhaustive or limiting of the invention. Rather, the invention is intended to cover all alternative, modifications and equivalents included within its spirit and scope, as defined by the appended claims.

1. An electronic device comprising:
two contacts;
a monolayer of a single conductive molecule or group of molecules forming a conductive path between the contacts, the molecule or molecule being capable of undergoing an increase or decrease in conductance in response to the application of an electric field in a direction not parallel to the molecule or molecules, and
means for producing an electric field in a direction not parallel to the molecule or molecules.

2. A method of fabricating an electronic device having a source and a drain contact, a monolayer of a single conductive molecule or group of molecules forming a conductive path between the contacts, the molecule or molecule being capable of undergoing an increase or decrease in conductance in response to the application of an electric field in a direction not parallel to the molecule or molecules, and means for producing an electric field in a direction not parallel to the molecule or molecules comprising:
defining a bottom source metal contact using metal etch or liftoff process on an insulating substrate;
depositing a dielectric on the bottom source metal contact to define the molecular active areas of the device;
defining a small pore aligned to the bottom source, and removing the dielectric in the pore openings;
depositing a molecular monolayer in the pore using an appropriate molecule self-assembly technique;
depositing a drain metal contact;
defining the drain contact overlapping the molecule pore layer using lithography and wet or dry etch of the drain contact metal;
removing the dielectric using a wet or dry isotropic etch to undercut the dielectric below the drain contact metal; and
depositing a control electrode metal using physical or chemical vapor deposition processes, with an electrical open circuit between the drain and control electrode contact;

3. A method of fabricating an electronic device having a source and a drain contact, a monolayer of a single conductive molecule or group of molecules forming a conductive path between the contacts, the molecule or molecule being capable of undergoing an increase or decrease in conductance in response to the application of an electric field in a direction not parallel to the molecule or molecules, and means for producing an electric field in a direction not parallel to the molecule or molecules comprising:
growing insulating dielectric tubules in mesoporous templates with pore diameters that range from 15 nm to 300 nm in diameter;
depositing a source metal inside the dielectric tubules/mesoporous template;
depositing a molecular monolayer in the pore using a compatible molecule self-assembly technique;
depositing drain metal inside the dielectric tubules/mesoporous template and on top of the molecular monolayer;
releasing the insulated metal-molecule-metal nanowires from the mesoporous membrane;
placing the resulting nanowires onto an appropriate substrate; and
integrating the control electrode.
